(19) United States
(12) Patent Application Publication
(10) Pub. No.: US 2012/0208347 A1
(43) Pub. Date: Aug. 16, 2012

(54) THREE-DIMENSIONAL SEMICONDUCTOR MEMORY DEVICES AND METHODS OF FABRICATING THE SAME

(75) Inventors: Sung-Min Hwang, Seoul (KR); Kwangmin Park, Seoul (KR); Woonkyung Lee, Seongnam-si (KR); Jintaek Park, Hwaseong-si (KR); Byong-byun Jang, Suwon-si (KR); Jumi Yun, Pocheon-si (KR)

(73) Assignee: SAMSUNG ELECTRONICS CO., LTD., Suwon-si (KR)

(21) Appl. No.: 13/367,792

(22) Filed: Feb. 7, 2012

(30) Foreign Application Priority Data
Feb. 11, 2011 (KR) 10-2011-0012553
May 9, 2011 (KR) 10-2011-0043618

(51) Int. Cl. H01L 21/762

(52) U.S. Cl. 438/430; 438/424; 257/E21.546

(57) ABSTRACT

Methods of fabricating a three-dimensional semiconductor device are provided. Methods may include forming a stack structure including first layers and second layers alternately stacked on a substrate, patterning the stack structure to form at least one isolation trench, forming channel structures penetrating the stack structure and being spaced apart from the isolation trench, and forming upper interconnection lines on the stack structure to connect the channel structures to each other. An isolation trench may be formed prior to formation of the channel structures.

### CROSS-REFERENCE TO RELATED APPLICATIONS

This U.S. non-provisional patent application claims priority under 35 U.S.C. §119 to Korean Patent Application Nos. 10-2011-0012553 and 10-2011-0043618, filed on Feb. 11, 2011 and May 9, 2011, respectively, the disclosures of which are hereby incorporated by reference in their entireties.

### BACKGROUND

1. Technical Field

The present disclosure relates to semiconductor devices and methods of fabricating the same and, more particularly, to three-dimensional semiconductor devices and methods of fabricating the same.

2. Description of Related Art

Semiconductor devices are becoming more highly integrated to meet the requirements of customers, e.g., in order to provide high performance and low cost. The integration density of the semiconductor devices is a factor that may directly influence the cost of the semiconductor devices. Thus, semiconductor devices have been continuously scaled down. In two-dimensional semiconductor memory devices, i.e., planar semiconductor memory devices, the integration density may be mainly determined by a planar area that a unit memory cell occupies. Accordingly, the integration density of two-dimensional semiconductor memory devices may be significantly limited by the level of technology for forming fine and small patterns. In addition, implementing fine patterns in two-dimensional semiconductor memory devices may result in increasing manufacturing costs and/or high priced apparatuses. Therefore, there may be some limitations in increasing the integration density of two-dimensional semiconductor devices.

Recently, three-dimensional semiconductor devices including memory cells arranged in a three-dimensional array have been proposed to overcome the above limitations. Nevertheless, new processes which are capable of reducing bit cost and realizing reliable products are still required for successful mass production of three-dimensional semiconductor devices, such as three-dimensional memory devices.

### SUMMARY

Exemplary embodiments in accordance with principles of inventive concepts may provide methods of fabricating three-dimensional semiconductor devices, such as three-dimensional semiconductor memory devices, and three-dimensional semiconductor devices, such as semiconductor memory devices, fabricated thereby.

In an exemplary embodiment in accordance with principles of inventive concepts, a method comprises forming a stack structure including first and second layers alternately stacked on a substrate, patterning the stack structure to form at least one isolation trench, forming channel structures penetrating the stack structure and being spaced apart from the isolation trench, and forming upper interconnection lines on the stack structure to connect the channel structures to each other. In an exemplary embodiment in accordance with inventive concepts, an isolation trench may be formed prior to formation of channel structures.

In an exemplary embodiment in accordance with principles of inventive concepts, each of the channel structures may include a semiconductor layer, and an isolation trench may be formed prior to formation of the semiconductor layer.

In an exemplary embodiment in accordance with principles of inventive concepts, the isolation trench may be formed to penetrate the stack structure and to expose a substrate.

In an exemplary embodiment in accordance with principles of inventive concepts, the isolation trench may be formed to split the stack structure into a plurality of sub-stack structures that are spaced apart from each other in a horizontal direction parallel with a top surface of the substrate.

In an exemplary embodiment in accordance with principles of inventive concepts, the isolation trench may be formed to expose a substrate, and a first impurity region may be formed in the substrate under the isolation trench.

In an exemplary embodiment in accordance with principles of inventive concepts, a method may comprise forming a first structure in an isolation trench. First structure may extend along the isolation trench.

In an exemplary embodiment in accordance with principles of inventive concepts, forming a first structure may include forming a first insulation pattern in the isolation trench, and the first isolation pattern may be formed of a material having an etch selectivity with respect to the second layers.

In an exemplary embodiment in accordance with principles of inventive concepts, forming a first structure may include forming a first conductive pattern in the isolation trench.

In an exemplary embodiment in accordance with principles of inventive concepts, forming channel structures may include forming channel holes penetrating the stack structure, and forming a semiconductor layer in the channel holes. The isolation trench and the channel holes may be simultaneously formed using the same etching process.

In another exemplary embodiment in accordance with principles of inventive concepts, the three-dimensional semiconductor device may comprise a stack structure including a plurality of electrodes sequentially stacked on a substrate, upper interconnection lines disposed on the stack structure, channel structures penetrating the stack structure to electrically connect the upper interconnection lines to the substrate, and at least one first structure penetrating at least one of the electrodes and crossing the upper interconnection lines. A portion of the substrate under first structure may have the same conductivity type as portions of the substrate under the channel structures.

In an exemplary embodiment in accordance with principles of inventive concepts, a three-dimensional semiconductor device may further comprise a data storage layer between a stack structure and channel structures. The data storage layer may extend to intervene between first structure and the stack structure.

In an exemplary embodiment in accordance with principles of inventive concepts, a three-dimensional semiconductor device may further comprise a buried insulation layer between channel structures, and a second impurity region in the substrate under the buried insulation layer. The second impurity region may have a different conductivity type from the substrate.

In an exemplary embodiment in accordance with principles of inventive concepts, a three-dimensional semiconductor device may further comprise a first impurity region in the substrate under first structure. First structure may be provided in an isolation trench penetrating at least one of the electrodes, and first structure may include a first insulation pattern in the isolation trench and a conductive pattern penetrating the first insulation pattern to be electrically connected to the first impurity region.

In an exemplary embodiment in accordance with principles of inventive concepts, the channel structures may be arrayed in a plurality of rows parallel with first structure. The stack structure may include step-shaped pads formed at an edge thereof, and the at least one first structure may be disposed between a row of the channel structure closest to the step-shaped pads and the step-shaped pads.

In an exemplary embodiment in accordance with principles of inventive concepts, a three-dimensional semiconductor device may further comprise a peripheral circuit region disposed at one side of the stack structure. The channel structures may be arrayed in a plurality of rows parallel with first structure, and first structure may be disposed between a row of the channel structure closest to the peripheral circuit region and the peripheral circuit region.

In an exemplary embodiment in accordance with principles of inventive concepts, an electronic device includes a plurality of sub-stack structures formed within a cell array region, each including electronic circuitry, formed on a substrate and an electrical interconnection between circuitry in one sub-stack and circuitry in another sub-stack.

In an exemplary embodiment in accordance with principles of inventive concepts, sub-stacks of an electronic device include electrodes sequentially stacked on a substrate each sub-stack is separated from other sub-stacks by an isolation trench that extends at least half a distance from the top of the sub-stack to the substrate upon which the sub-stacks are formed.

In an exemplary embodiment in accordance with principles of inventive concepts, sub-stacks of an electronic device include memory circuitry.

In an exemplary embodiment in accordance with principles of inventive concepts, sub-stacks of an electronic device include memory circuitry.

In an exemplary embodiment in accordance with principles of inventive concepts, sub-stacks of an electronic device include flash memory circuitry.

In an exemplary embodiment in accordance with principles of inventive concepts, sub-stacks of an electronic device include flash memory circuitry and electrical interconnections between sub-stacks include bit lines.

In an exemplary embodiment in accordance with principles of inventive concepts, the electronic device further comprises: upper interconnection lines on the sub-stack structures; channel structures penetrating the sub-stack structures, the channel structures electrically connecting upper interconnection lines to the substrate; and at least one first structure penetrating at least one of the electrodes and crossing the upper interconnection lines; wherein a portion of the substrate under the at least one first structure has a same conductivity type as portions of the substrate under the channel structures.

### BRIEF DESCRIPTION OF THE DRAWINGS

The above and other features and advantages of the disclosure will become more apparent in view of the attached drawings and accompanying detailed description.

FIG. 1 is an equivalent circuit diagram illustrating of a portion of a three-dimensional semiconductor device according to an exemplary embodiment in accordance with the principles of inventive concepts.

FIGS. 2 to 11 are perspective views illustrating a three-dimensional semiconductor device according to an exemplary embodiment in accordance with the principles of inventive concepts and a method of fabricating the same.

FIGS. 12 to 15 are perspective views illustrating a three-dimensional semiconductor device according to an exemplary embodiment in accordance with the principles of inventive concepts and a method of fabricating the same.

FIGS. 16 to 18 are perspective views illustrating a three-dimensional semiconductor device according to an exemplary embodiment in accordance with the principles of inventive concepts and a method of fabricating the same.

FIGS. 19 and 20 are perspective views illustrating a three-dimensional semiconductor device according to an exemplary embodiment in accordance with the principles of inventive concepts and a method of fabricating the same.

FIGS. 21 to 26 are perspective views illustrating a three-dimensional semiconductor device according to an exemplary embodiment in accordance with the principles of inventive concepts and a method of fabricating the same.

FIGS. 27 and 28 are perspective views illustrating a three-dimensional semiconductor device according to an exemplary embodiment in accordance with the principles of inventive concepts and a method of fabricating the same.

FIGS. 29 to 32 are perspective views illustrating a three-dimensional semiconductor device according to an exemplary embodiment in accordance with the principles of inventive concepts and a method of fabricating the same.

FIGS. 33 to 37 are perspective views illustrating a three-dimensional semiconductor device according to an exemplary embodiment in accordance with the principles of inventive concepts and a method of fabricating the same.

FIGS. 38 to 43 are perspective views illustrating a three-dimensional semiconductor device according to an exemplary embodiment in accordance with the principles of inventive concepts and a method of fabricating the same.

FIG. 44 is a perspective view illustrating a three-dimensional semiconductor device according to an exemplary embodiment in accordance with the principles of inventive concepts and a method of fabricating the same.

FIGS. 45 and 46 are perspective views illustrating a three-dimensional semiconductor device according to an exemplary embodiment in accordance with the principles of inventive concepts and a method of fabricating the same.

FIGS. 47 to 63 are plan views and cross sectional views illustrating a three-dimensional semiconductor device according to an exemplary embodiment in accordance with the principles of inventive concepts and a method of fabricating the same.

FIGS. 64 to 67 are plan views illustrating three-dimensional semiconductor devices according to some exemplary embodiment in accordance with the principles of inventive concepts.

FIGS. 68 to 72 are layout diagrams illustrating three-dimensional semiconductor devices according to some exemplary embodiments in accordance with the principles of inventive concepts.

FIGS. 73 to 75 are perspective views illustrating data storage layers of three-dimensional semiconductor devices according to some exemplary embodiments in accordance with the principles of inventive concepts.

FIG. 76 is a schematic block diagram illustrating an example of electronic systems including semiconductor devices according to some exemplary embodiments in accordance with the principles of inventive concepts.

FIG. 77 is a schematic block diagram illustrating an example of memory cards including semiconductor devices according to some exemplary embodiments in accordance with the principles of inventive concepts.

FIG. 78 is a schematic block diagram illustrating an example of information processing systems including semiconductor devices according to some exemplary embodiments in accordance with the principles of inventive concepts.

### DETAILED DESCRIPTION OF THE EMBODIMENTS

The terminology used herein is for the purpose of describing particular embodiments and is not intended to be limiting of the inventive concepts. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various limitations, elements, components, regions, layers and/or sections, these limitations, elements, components, regions, layers and/or sections should not be limited by these terms. These terms are only used to distinguish one limitation, element, component, region, layer or section from another limitation, element, component, region, layer or section. Thus, a first limitation, element, component, region, layer or section discussed below could be termed a second limitation, element, component, region, layer or section without departing from the teachings of the present application.

It will be further understood that when an element is referred to as being “on” or “connected” or “coupled” to another element, it can be directly on or above, or connected or coupled to, the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap. Descriptions may make relate directions or orientations to coordinate systems (e.g., in the y-axis direction). Those references are made for the ease of illustration only and are not meant to restrict the scope of inventive subject matter in any way.

Although claimed subject matter will be described in terms of certain embodiments, other embodiments, including embodiments that do not provide all of the benefits and features set forth herein, are also within the scope of this invention. Various structural, logical, and process step changes may be made without departing from the spirit or scope of the invention.

Unless otherwise defined, all terms (including technical and scientific terms) used herein have the same meaning as commonly understood by one of ordinary skill in the art to which these embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

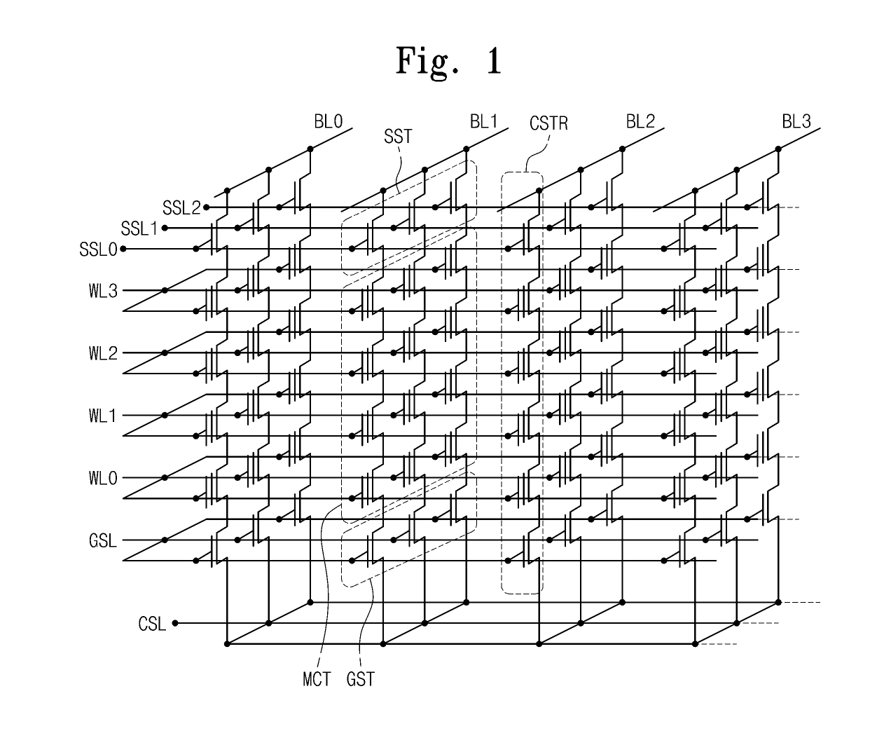

FIG. 1 is an equivalent circuit diagram illustrating of a portion of a three-dimensional semiconductor device according to an exemplary embodiment in accordance with principles of inventive concepts.

Referring to FIG. 1, a three-dimensional semiconductor device according to an exemplary embodiment in accordance with principles of inventive concepts may include common source lines CSL, bit lines BL0 to BL3, and cell strings CSTR between the source lines CSL and the bit lines BL0-BL3.

The bit lines BL0 to BL3 are two-dimensionally arrayed, and some of the plurality of cell strings CSTR may be electrically connected in parallel to each of the bit lines BL0 to BL3. Each of the cell strings CSTR may be electrically connected to any one of the common source lines CSL. In an exemplary embodiment in accordance with principles of inventive concepts, the common source lines CSL may be two-dimensionally arrayed. The common source lines CSL may be electrically connected to each other and may be simultaneously controlled to have the same electrical bias, for example, the same voltage. Alternatively, the common source lines CSL may be isolated from each other and may be independently controlled.

Each of the cell strings CSTR may be configured to include a ground selection transistor GST connected to one of the common source lines CSL, a string selection transistor SST connected to one of the bit lines BL0 to BL3, and a plurality of memory cell transistors MCT disposed between the ground selection transistor GST and the string selection transistor SST. The ground selection transistor GST, the plurality of memory cell transistors MCT and the string selection transistor SST constituting each of the cell strings CSTR may be serially connected to each other.

In an exemplary embodiment in accordance with principles of inventive concepts, each of the common source lines CSL may be electrically connected to some of sources of the ground selection transistors GST. In addition, gate electrodes of the ground selection transistors GST may extend to form ground selection lines GSL, and gate electrodes of the string selection transistors SST may extend to form string selection lines SSL. Further, gate electrodes of the memory cell transistors MCT may extend to form word lines WL to WL3. The ground selection lines GSL, the string selection lines SSL and the word lines WL0 to WL3 may be disposed between the common source lines CSL and the bit lines BL0 to BL3. Each of the memory cell transistors MCT may act as a data storage element.

The memory cell transistors MCT constituting any one of the cell strings CSTR may be located at different levels from each other. Thus, the word lines WL0 to WL3 connected to the memory cell transistors MCT of each cell string CSTR may also be located at different levels from each other. Further, the plurality of word lines WL0 connected to the plurality of cell strings CSTR may be located at the same level, and the plurality of word lines WL1 connected to the plurality of cell strings CSTR may be located at the same level. Similarly, the plurality of word lines WL2 connected to the plurality of cell strings CSTR may be located at the same level, and the plurality of word lines WL3 connected to the plurality of cell strings CSTR may be located at the same level.

The plurality of word lines WL0, WL1, WL2 or WL3, which are located at substantially the same level from the common source lines CSL, may be electrically connected to each other to have the same electrical potential. Alternately, even though the word lines WL0, WL1, WL2 or WL3 are located at the same level, the word lines WL0, WL1, WL2 or WL3 may be electrically isolated from each other and may be independently controlled to have different biases.

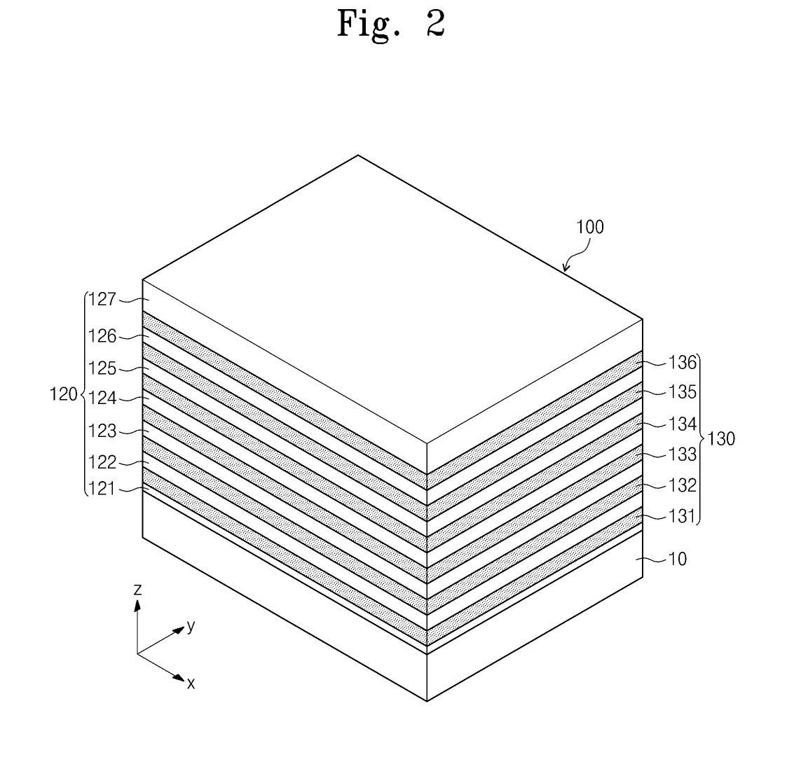

FIGS. 2 to 11 are perspective views illustrating a three-dimensional semiconductor device according to an exemplary embodiment in accordance with principles of inventive concepts and a method of fabricating the same.

Referring to FIG. 2, a stack structure 100 may be formed on a substrate 10. Substrate 10 may include one of a semiconductor substrate, an insulation substrate, a semiconductor substrate covered with an insulation layer, or a conductive substrate covered with an insulation layer. In an exemplary embodiment in accordance with principles of inventive concepts, substrate 10 may be a silicon wafer. For example, substrate 10 may be a silicon wafer lightly doped with p-type impurities.

Forming stack structure 100 may include alternately stacking first layer and second layers on substrate 10. The first layers may correspond to sacrificial layers 130 (131, 132, 133, 134, 135 and 136), and the second layers may correspond to insulation layers 120 (121, 122, 123, 124, 125, 126 and 127). The insulation layers 120 and sacrificial layers 130 may be alternately and repeatedly stacked, as illustrated in FIG. 2. Hereinafter, it will be understood that the term “stack structure” used herein should be interpreted as including resultants that sacrificial layers 130 and/or the insulation layers 120 are modified or replaced with other layers by subsequent processes.

Sacrificial layers 130 may be formed of a material having an etch selectivity with respect to the insulation layers 120 and vice versa. That is, when sacrificial layers 130 are etched using a predetermined etch recipe, an etch rate of the insulation layers 120 may be relatively lower than that of sacrificial layers 130. The etch selectivity may be expressed as a ratio of etch rates of two different materials exposed to a specific etch recipe. In an exemplary embodiment in accordance with principles of inventive concepts, the insulation layers 120 may be formed of a material having an etch selectivity within the range of from about 1:10 to about 1:200 (more definitely, from about 1:30 to about 1:100) with respect to sacrificial layers 130. For example, the insulation layers 120 may be formed of at least one of a silicon oxide layer and a silicon nitride layer, and sacrificial layers 130 may be formed of a material selected from the group consisting of a silicon layer, a silicon oxide layer, a silicon carbide layer and a silicon nitride layer, but different from the insulation layers 120. For the purpose of ease and convenience in explanation, exemplary embodiment in accordance with principles of inventive concepts will be described hereinafter under the assumption that the insulation layers 120 include a silicon oxide layer and sacrificial layers 130 include a silicon nitride layer.

At least one of the insulation layers 120 may have a different thickness from the others. In an exemplary embodiment in accordance with principles of inventive concepts, the lowermost insulation layer 121 may be formed to be thinner than the other insulation layers 122, 123, 124, 124, 125, 126 and 127, and the uppermost insulation layer 127 may be formed to be thicker than the other insulation layers 121, 122, 123, 124, 124, 125 and 126. However, the thickness of each of the insulation layers 120 is not limited to the above descriptions. That is, the insulation layers 120 and sacrificial layers 130 may be modified to have various thicknesses. Further, the number of the layers 120 and 130 constituting stack structure 100 may also be changed according to a design purpose.

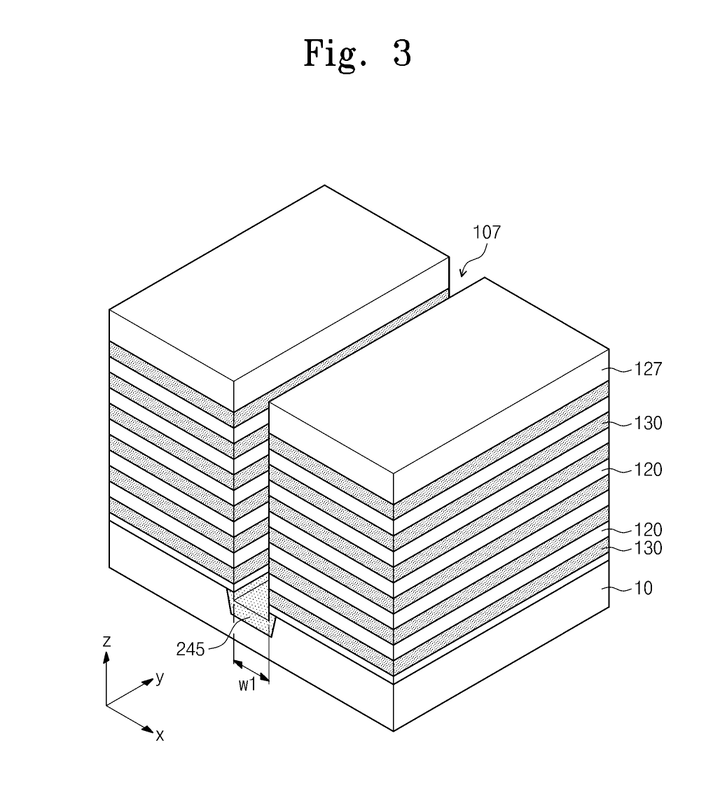

Referring to FIG. 3, stack structure 100 may be patterned to form at least one isolation trench 107. Isolation trench 107 may be formed to extend in a y-axis direction. In an exemplary embodiment in accordance with principles of inventive concepts, isolation trench 107 may expose substrate 10. That is, the at least one isolation trench 107 may extend from the top of stack structure 100 to substrate 10, thereby splitting stack structure 100 into a plurality of sub-stack structures.

The process of forming isolation trench 107 may include forming a mask pattern having an opening on stack structure 100, anisotropically etching stack structure 100 using the mask pattern as an etch mask, and removing the mask pattern. In an exemplary embodiment in accordance with principles of inventive concepts, the isolation trench 107 may be relatively deep, compared with a width thereof Isolation trench 107 may be formed so that a sidewall of isolation trench 107 may have a sloped profile. For example, the width of isolation trench 107 may be gradually reduced toward substrate 10. In an exemplary embodiment in accordance with principles of inventive concepts, the width of isolation trench 107 (e.g., a distance along an x-axis direction) may denote a bottom width w1 of isolation trench 107, which corresponds to a minimum width thereof.

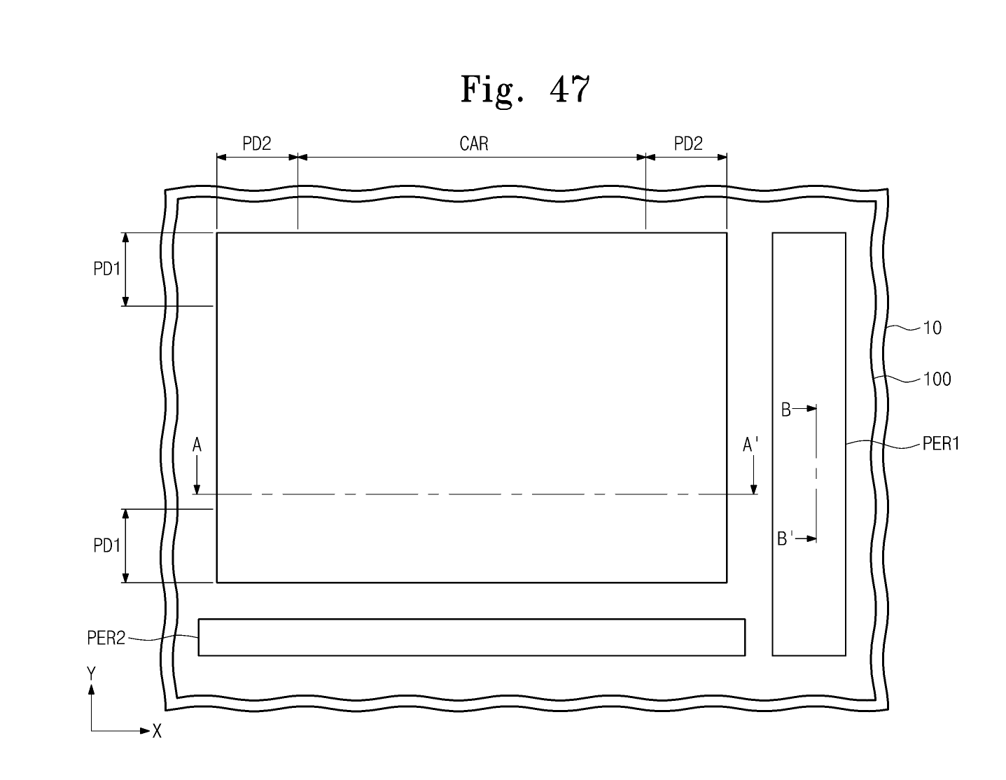

Isolation trench 107 may be formed to expose substrate 10 and substrate 10 may be recessed during formation of isolation trench 107. Formation of a recess in substrate 10 may be due, for example, to an over-etch step of the anisotropic etching process of forming isolation trench 107. The array and/or disposition of isolation trench 107 will be described in detail hereinafter with reference to FIGS. 47 to 67 and FIGS. 68 to 71.

If stack structure 100 may be formed to include heterogeneous layers vertically stacked, internal physical stress may be generated in stack structure 100. The internal physical stress may be due to a difference between thermal expansion (or contraction) coefficients of the heterogeneous layers. The internal physical stress may result in deformation of stack structure 100 in a subsequent thermal process, e.g., formation of a semiconductor layer in a channel hole performed at a relatively high temperature. For example, a silicon nitride layer may have a thermal contraction coefficient which is greater than that of a silicon oxide layer. Thus, a physical stress may be generated between the insulation layers 120 and sacrificial layers 130 constituting stack structure 100 at a high temperature. As the height of stack structure 100 increases, the physical stress generated in stack structure 100 due to differences in coefficients of expansion and/or contraction may also increase.

According to an exemplary embodiment, the anisotropical etching process of forming isolation trench 107 may split stack structure 100 into a plurality of sub-stack structures before thermal processes are performed. The sub-stack structures may have a relatively small size as compared with the initial stack structure 100. Thus, even though the subsequent thermal processes are applied to the substrate including the sub-stack structures, the physical stresses generated in the sub-stack structures may be substantially reduced, thereby preventing deformation of the sub-stack structures during high-temperature processing.

In an exemplary embodiment, a first impurity region 245 may be formed in substrate 10 under isolation trench 107. First impurity region 245 may extend in the y-axis direction, the same direction as isolation trench 107. First impurity region 245 may be formed prior to formation of stack structure 100, or after formation of isolation trench 107, for example. First impurity region 245 may correspond to a region for applying a voltage to substrate 10 and, therefore, may be formed to have the same conductivity type as substrate 10. If a P-type well may be formed in substrate 10 adjacent to stack structure 100, first impurity region 245 may be formed in the P-type well and may be formed to have the P-type. An impurity concentration of first impurity region 245 may be higher than that of substrate 10 or the P-type well, for example. First impurity region 245 may be formed using an ion implantation process that employs the sub-stack structures as ion implantation masks, for example.

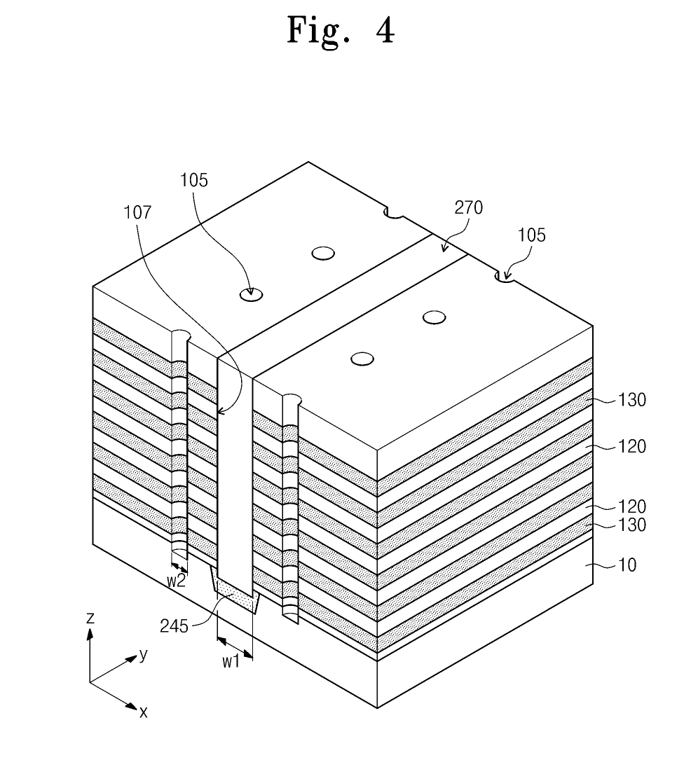

Referring to FIG. 4, a first insulation pattern 270 may be formed in isolation trench 107. First insulation pattern 270 may be formed to contact sidewalls of trench 107 which are composed of sidewalls of the insulation layers 120 and sacrificial layers 130. First insulation pattern 270 may be formed of a material having an etch selectivity with respect to sacrificial layers 130. First insulation pattern 270 may be formed of the same material as the insulation layers 120, for example. In an exemplary embodiment in accordance with principles of inventive concepts, if sacrificial layers 130 are formed of a silicon nitride layer, first insulation pattern 270 may be formed of a silicon oxide layer. Forming first insulation pattern 270 may include forming an insulation layer in isolation trench 107 and on the sub-stack structures, and planarizing the insulation layer to expose the sub-stack structures.

A plurality of channel holes 105 may be formed to penetrate sub-stack structures. In an exemplary embodiment in accordance with principles of inventive concepts, channel holes 105 may be formed to have a cylindrical shape and to, therefore, have a circular shape when viewed from a plan view. The depth of a channel hole 105 may be at least five times greater than a width thereof. Channel holes 105 may be two-dimensionally arrayed in a plan view parallel with an x-y plane. That is, channel holes 105 may be arrayed along the x-axis direction and along the y-axis direction crossing the x-axis direction. Channel holes 105 may be formed to be spaced apart from each other.

Channel holes 105 may be fondled to a depth that is sufficient to expose substrate 10. In an exemplary embodiment in accordance with principles of inventive concepts, channel holes 105 may be formed after forming first insulation pattern 270. A diameter w2 of channel holes 105 in the x-axis direction may be less than the width w1 of isolation trench 107. The width w1 of isolation trench 107 may be formed to be relatively great in order to accommodate the formation of contact plugs therein in a subsequent process.

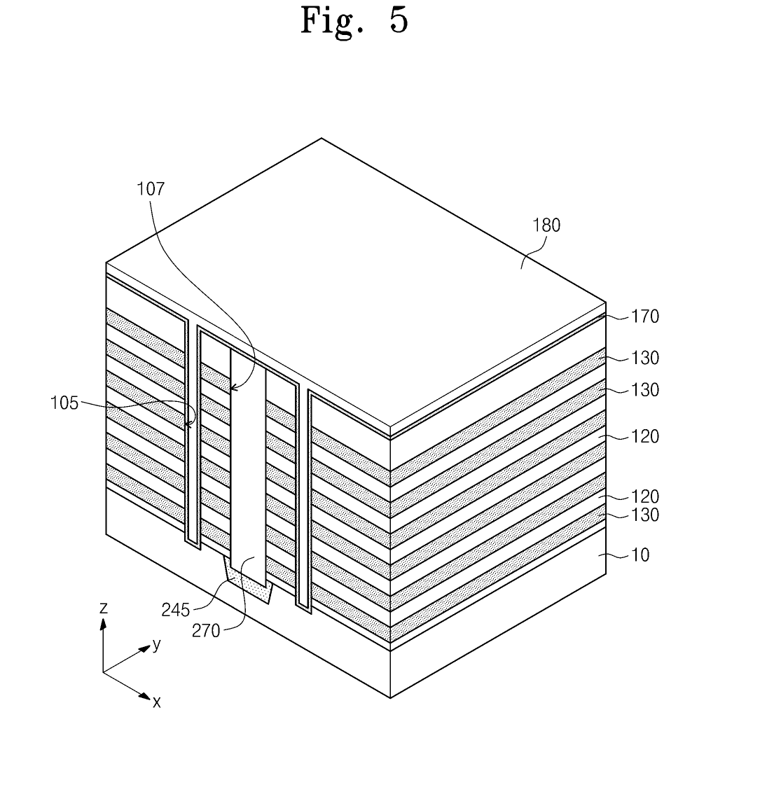

Referring to FIG. 5, a semiconductor layer 170 may be conformally formed on a substrate, including the tops of sub-stacks, insulation pattern 270, and the interiors of channel holes 105, for example. Semiconductor layer 170 may be formed of a polysilicon layer using an atomic layer deposition (ALD) process or a chemical vapor deposition (CVD) process. Semiconductor layer 170 may be formed to a thickness within the range of from about 0.02 times to about 0.2 times the width of channel holes 105, for example. In an exemplary embodiment in accordance with principles of inventive concepts, semiconductor layer 170 may include one of an organic semiconductor layer and a carbon nano-structure. Semiconductor layer 170 may be formed not to fill channel holes 105, but to coat the interiors of channel holes 105, leaving space within channel holes 105 for formation of other materials, such as a filling layer 180, within, in subsequent steps.

As described above, semiconductor layer 170 may be formed in relatively higher temperature than other processes. The high temperature process may tend to deform a stack structure 100. However, according to the present embodiment, isolation trench 107 may split stack structure 100 into a plurality of sub-stack structures prior to the high temperature process of forming semiconductor layer 170. Because isolation trench 107 reduces the size of the areas over which differences in coefficients of expansion or contraction generate shearing and or other potentially damaging forces isolation trench 107 may relieve the stress generated in the sub-stack structures and may prevent temperature-induced deformation sub-stack structures.

A filling layer 180 may be formed on semiconductor layer 170. Filling layer 180 may be formed to fill channel holes 105. Filling layer 180 may be formed of an insulation material, for example, silicon oxide. Filling layer 180 may be formed using a spin on glass (SOG) technique, for example. In an exemplary embodiment in accordance with principles of inventive concepts, prior to formation of semiconductor layer 170, an annealing process may be applied to the substrate including semiconductor layer 170. The annealing process may employ a hydrogen containing gas or a deuterium containing gas as an ambient gas. A plurality of crystalline defects in semiconductor layer 170 may be cured by hydrogen atoms produced during an annealing process.

In other exemplary embodiments in accordance with principles of inventive concepts, semiconductor layer 170 may be formed to fill channel holes 105. In such embodiments, the process of forming filling layer 180 may be omitted.

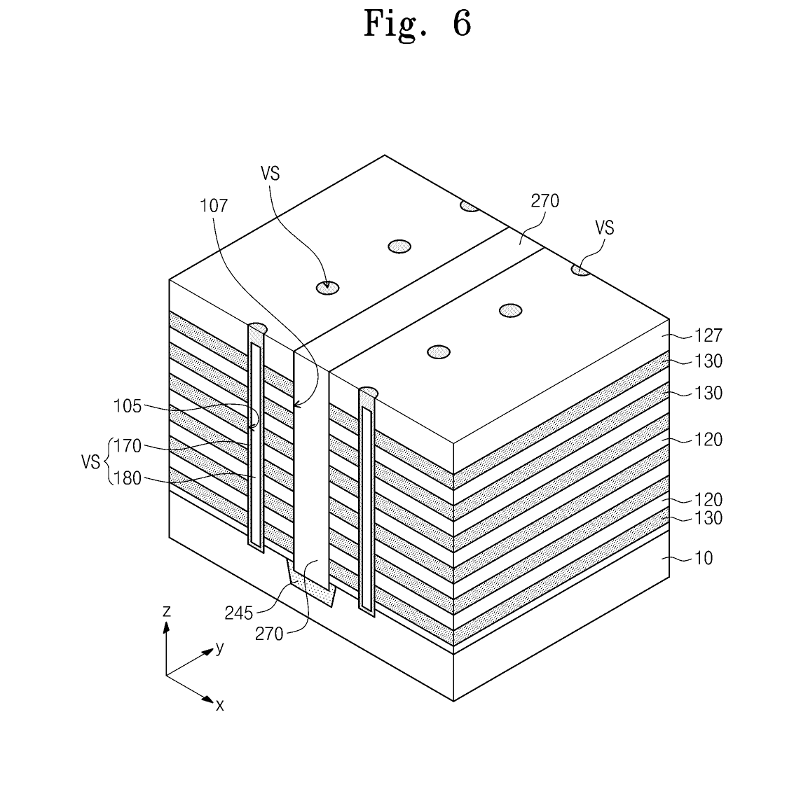

Referring to FIG. 6, filling layer 180 and semiconductor layer 170 may be planarized to form channel structures VS in respective ones of channel holes 105. Each of the channel structures VS may include a semiconductor layer 170 and a filling layer 180 defined in each of channel holes 105, as previously described.

Upper portions of the filling layers 180 in channel holes 105 may be removed to form recessed regions. Semiconductor patterns may be formed in respective ones of the recessed regions. Hereinafter, it will be understood that semiconductor layer 170 includes a semiconductor pattern.

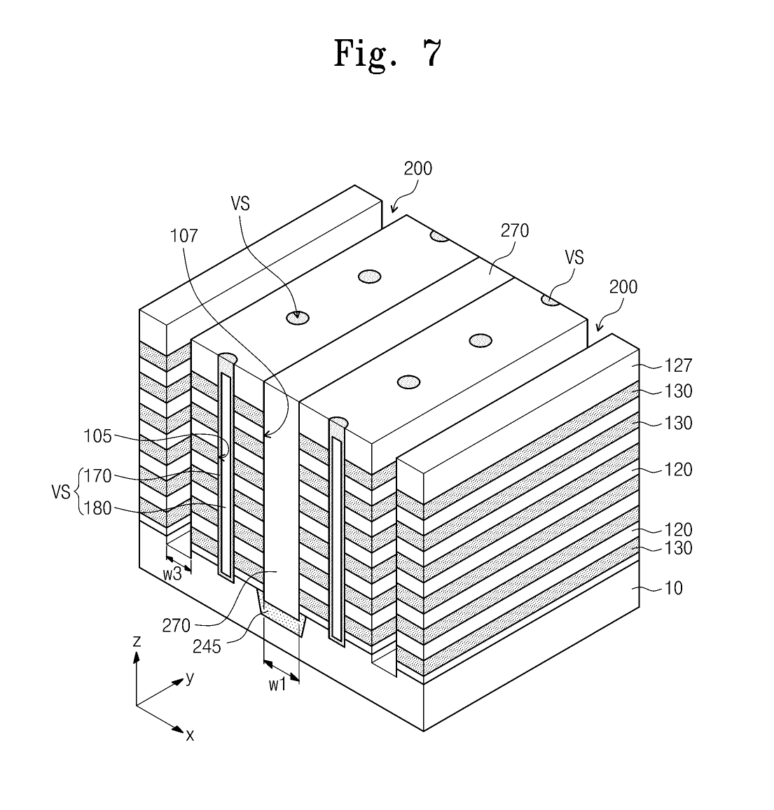

Referring to FIG. 7, sub-stack structures may be patterned to form first trenches 200 exposing substrate 10. Each of first trenches 200 may be formed between a pair of adjacent channel structures VS which are arrayed in the x-axis direction. First trenches 200 may extend in the y-axis direction. First trenches 200 be formed outside a combination of first insulation pattern 270 and channel structures VS adjacent thereto, as illustrated in FIG. 7. In other exemplary embodiments in accordance with principles of inventive concepts, first trenches 200 may be formed between first insulation pattern 270 and channel structures VS adjacent thereto. Unlike isolation trench 107, first trenches 200 may be formed after forming semiconductor layer 170.

Substrate 10 under first trenches 200 may be recessed during the process of forming first trenches by over-etching first trenches 200, for example. In an exemplary embodiment in accordance with principles of inventive concepts, a width w3 of first trenches 200 in the x-axis direction may be less than the width w1 of isolation trench 107.

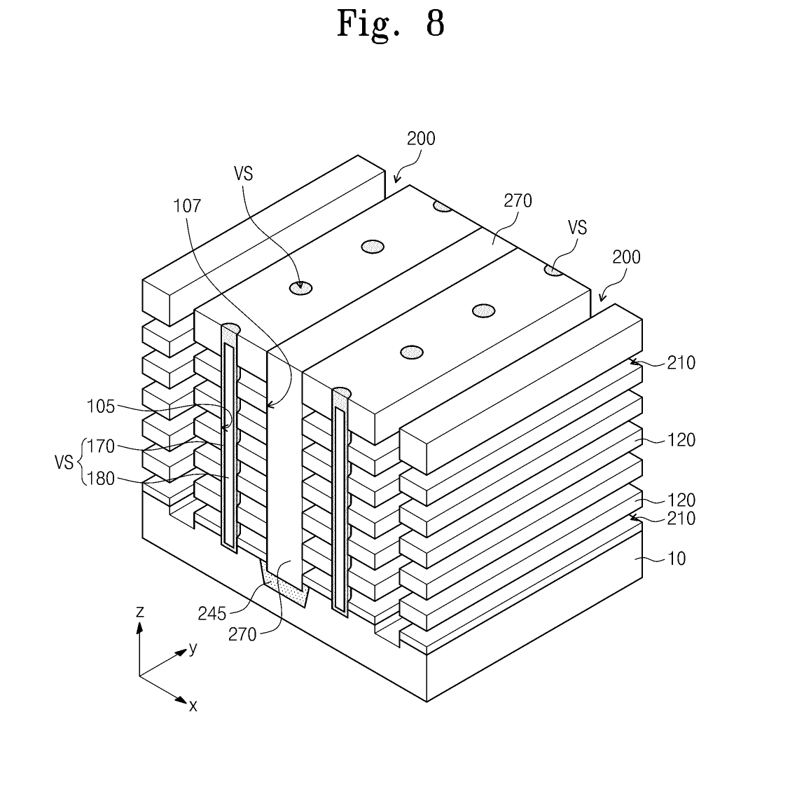

Referring to FIG. 8, sacrificial layers 130 exposed by first trenches 200 may be selectively removed to form recessed regions 210. Recessed regions 210 may correspond to gap regions laterally extending from first trenches 200 and may expose sidewalls of semiconductor layer 170. That is, recessed regions 210 may correspond to empty spaces between the insulation layers 120 which are vertically stacked.

Recessed regions 210 may be formed by laterally etching sacrificial layers 130 using an etch recipe having an etch selectivity with respect to the insulation layers 120 and the semiconductor layers 170. For example, when sacrificial layers 130 are formed of a silicon nitride layer and the insulation layers 120 are formed of a silicon oxide layer, sacrificial layers 130 may be selectively removed using an etchant containing a phosphoric acid solution.

Portions of sacrificial layers 130 between the channel structures VS and first insulation pattern 270 may be etched by the etchant that passes through recessed regions 210 between the channel structures VS arrayed and separated in the y-axis direction. That is, while sacrificial layers 130 may be selectively removed, the etchant supplied into first trenches 200 may pass through the regions between the channel structures VS arrayed in the y-axis direction and may reach the sidewalls of first insulation pattern 270. Thus, sacrificial layers 130 between the channel structures VS and first insulation pattern 270 may also be completely removed. As described above, sacrificial layers 130 may be formed of a material having an etch selectivity with respect to first insulation pattern 270. Accordingly, first insulation pattern 270 may still remains even though sacrificial layers 130 are removed to form recessed regions 210.

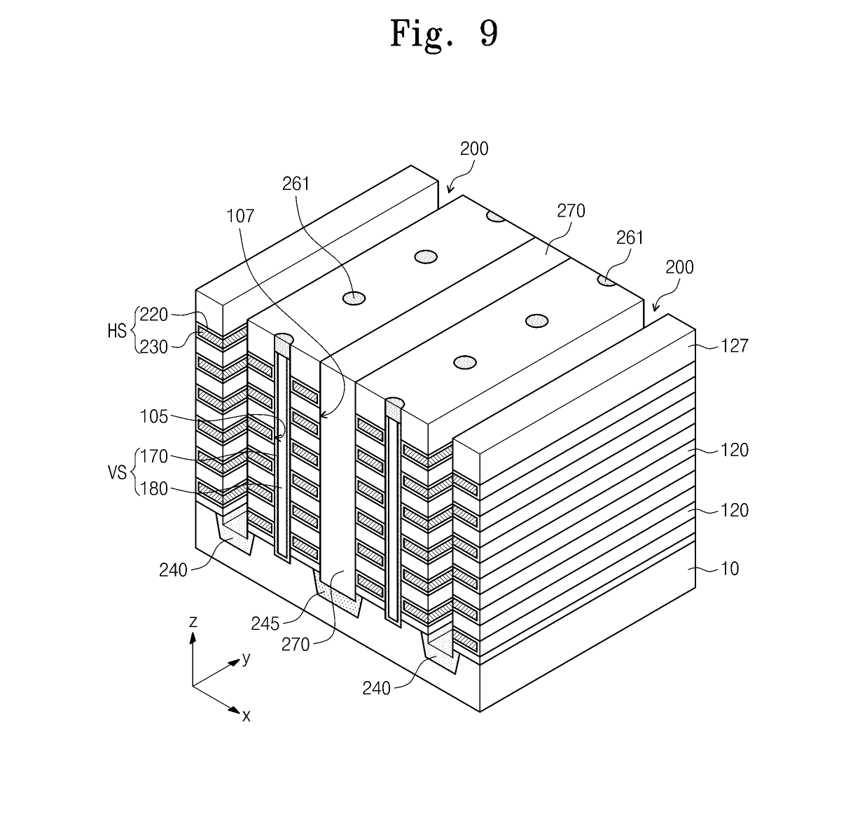

Referring to FIG. 9, electrode structures HS may be formed in respective ones of recessed regions 210. Each of the electrode structures HS may include a data storage layer 220 covering an inner surface of each recessed region 210 and an electrode pattern 230 filling the recessed region 210 surrounded by data storage layer 220.

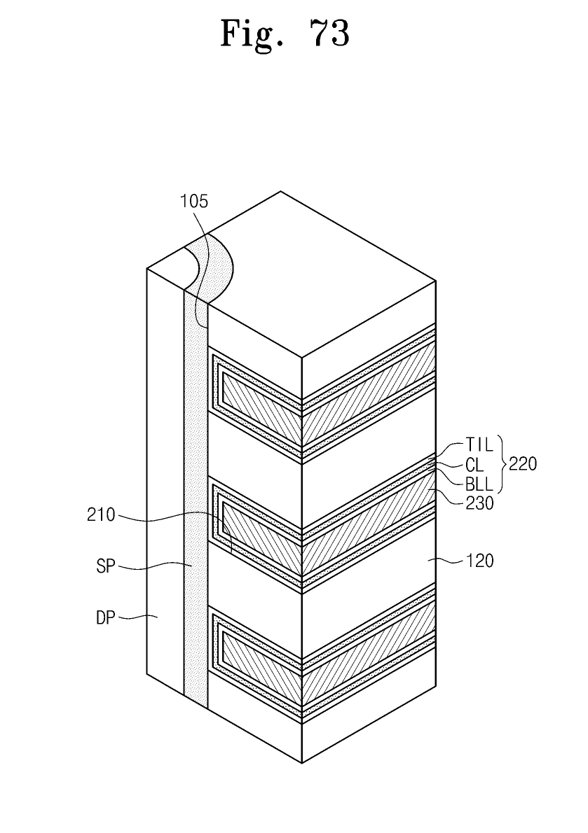

The process of forming electrode patterns HS may include sequentially forming a data storage layer and a conductive layer on the substrate including recessed regions 210, and removing the conductive layer in first trenches 200 to leave portions of the conductive layer in respective ones of recessed regions 210. The data storage layers 220 and electrode patterns 230 may also fill recessed regions 210 between first insulation pattern 270 and channel structures VS through the spaces between the channel structures VS arrayed in the y-axis direction. The configurations of data storage layers 220 will be described hereinafter with reference to FIGS. 73 to 75.

The conductive layer may be formed to fill recessed regions 210 surrounded by the data storage layer. First trenches 200 may be completely or partially filled with the conductive layer. The conductive layer may be formed to include at least one of a doped silicon layer, a metal layer, a metal nitride layer or a metal silicide layer. For example, the conductive layer may include a tantalum nitride layer or a tungsten layer. In an exemplary embodiment in accordance with principles of inventive concepts, conductive layer may be conformally formed along inner surfaces of first trenches 200. In this case, the electrode patterns HS may be formed by isotropically etching the conductive layer in first trenches 200. Alternatively, the conductive layer may be formed to completely fill first trenches 200. In this case, the electrode patterns HS may be formed by anisotropically etching the conductive layer in first trenches 200.

According to an embodiment for fabricating a flash memory device, after forming the electrode patterns HS, second impurity regions 240 may be formed in substrate 10. The second impurity regions 240 may be formed in substrate 10 under first trenches 200 using an ion implantation process, for example. The second impurity regions 240 may be formed to have a different conductivity type from that of substrate 10.

In an exemplary embodiment in accordance with principles of inventive concepts, second impurity regions 240 may be electrically connected to each other, thereby having the same electrical potential. In other exemplary embodiments, the second impurity regions 240 may be electrically isolated from each other and have different electrical potentials. In other exemplary embodiments, second impurity regions 240 may include a plurality of source groups, and each of the source groups may include some of the second impurity regions 240. In this case, the plurality of source groups may be electrically isolated from each other and have different electrical potentials.

Third impurity regions 261 may be formed in respective ones of upper portions of the channel structures VS. The third impurity regions 261 may be formed to have a different conductivity type from substrate 10. In an exemplary embodiment in accordance with principles of inventive concepts, the second and third impurity regions 240 and 261 may be simultaneously formed using the same process.

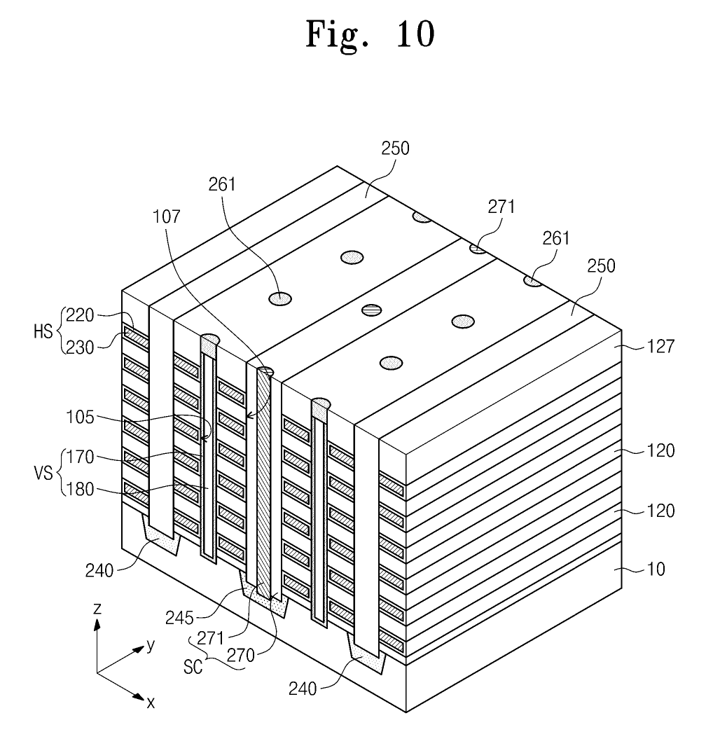

Referring to FIG. 10, buried insulation layers 250 may be formed in respective ones of first trenches 200. Forming buried insulation layers 250 may include forming an insulation layer on a substrate including second impurity regions 240 and planarizing the insulation layer to expose a top surface of the uppermost insulation layer 127. Buried insulation layers 250 may be formed of at least one of a silicon oxide layer, a silicon nitride layer and a silicon oxynitride layer, for example. The planarization process may be performed using a chemical mechanical polishing (CMP) process or an etch-back process, for example.

Data storage layer 220 may be formed prior to formation of buried insulation layers 250. Thus, data storage layer 220 may not extend between electrode patterns 230 and buried insulation layers 250. That is, each of buried insulation layers 250 may be in direct contact with the electrode patterns 230 adjacent thereto. Because data storage layer 220 may be formed after formation of first insulation pattern 270, data storage layer 220 may be formed to intervene between the electrode patterns 230 and first insulation pattern 270.

Contact plugs 271 may be formed in first insulation pattern 270. Contact plugs 271 may penetrate first insulation pattern 270 and may be electrically connected to first impurity region 245. Contact plugs 271 may be formed of a metal layer such as a titanium layer or a tungsten layer, for example. Forming contact plugs 271 may include etching first insulation pattern 270 to form contact holes exposing first impurity region 245, forming a metal layer filling the contact holes, and planarizing the metal layer to expose first insulation pattern 270. Contact plugs 271 may have ohmic contact with substrate 10 through first impurity region 245. The configuration of contact plugs 271 is not limited to the shape illustrated in FIG. 10. That is, contact plugs 271 may be embodied in many different forms if contact plugs 271 can be electrically connected to first impurity regions 245. First insulation pattern 270 and contact plugs 271 therein may constitute a first structure SC.

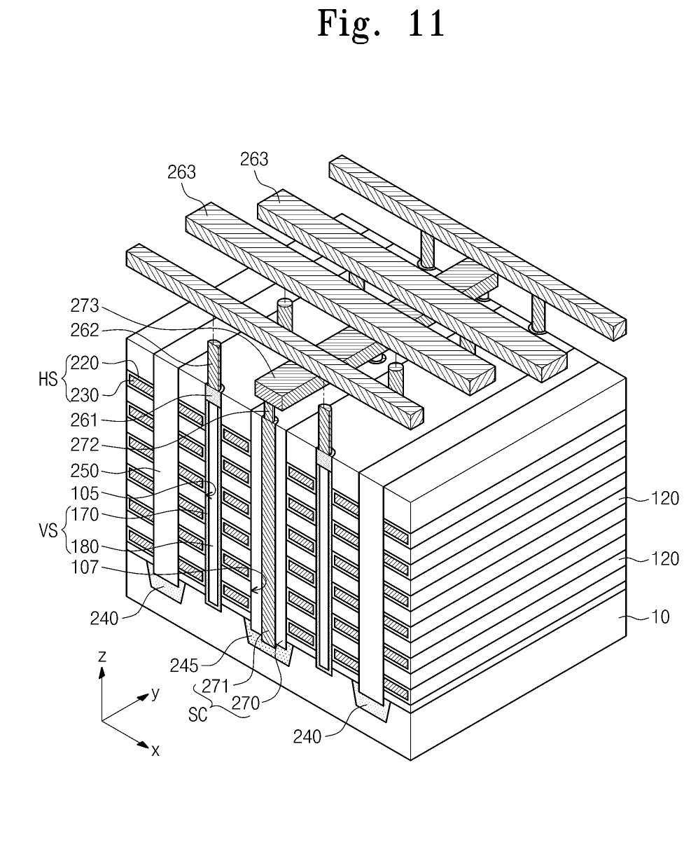

Referring to FIG. 11, first upper interconnections 263 and second upper interconnections 273 may be formed on the substrate including contact plugs 271. Each of the first upper interconnections 263 may be formed to electrically connect the channel structures VS, which are arrayed in a column parallel with the x-axis direction, to each other. Each of the second upper interconnections 273 may be formed to electrically connect contact plugs 271, which are arrayed in a row parallel with the y-axis direction, to each other. According to an embodiment relating to a NAND flash memory device, the first upper interconnections 263 may be used as bit lines which are electrically connected to drain regions of a plurality of cell strings. Each of the second upper interconnections 273 may extend along isolation trench 107, and the first upper interconnections 263 may extend to cross the second upper interconnections 273. In an exemplary embodiment in accordance with principles of inventive concepts, the second upper interconnections 273 may be located at a lower level than the first upper interconnections 263. The second upper interconnections 273 may be electrically insulated from the first upper interconnections 263 by an interlayer insulation layer (not shown). The first upper interconnections 263 may be electrically connected to the channel structures VS through first upper plugs 262, and each of the second upper interconnections 273 may be electrically connected to first structure SC through second upper plugs 272.

A three-dimensional semiconductor device according to an exemplary embodiment in accordance with principles of inventive concepts will be described in more detail with reference again to FIG. 11. Such a three-dimensional semiconductor device may include first structure SC that crosses the first upper interconnections 263 and extends to intervene between channel structures VS.

First structure SC may electrically connect first impurity region 245 to second upper interconnection 273. If a predetermined voltage is applied to second upper interconnection 273, the predetermined voltage may be applied to substrate 10 through contact plugs 271 and first impurity region 245.

A portion of substrate 10 directly under first structure SC may have the same conductivity type as portions of substrate 10 directly under the channel structures VS. For example, first impurity region 245 disposed under first structure SC may be heavily doped with P-type impurities, and substrate 10 under the channel structures VS may be lightly doped with the P-type impurities.

Portions of substrate 10 directly under buried insulation layers 250 may have a different conductivity type from substrate 10 directly under the channel structures VS. For example, the second impurity regions 240 disposed under buried insulation layers 250 may be heavily doped with N-type impurities, and substrate 10 under the channel structures VS may be lightly doped with the P-type impurities.

In exemplary embodiments in accordance with principles of inventive concepts, each of the data storage layers 220 may extend to intervene between electrode pattern 230 and first structure SC. In the same embodiments, each of the data storage layers 220 may not extend to intervene between the electrode pattern 230 and first structure SC, for example.

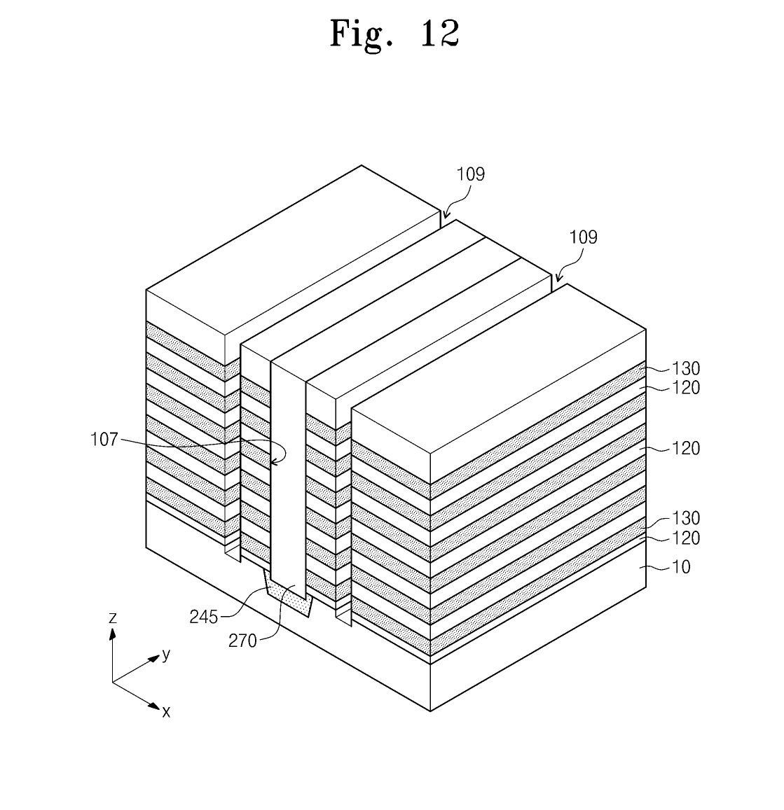

FIGS. 12 to 15 are perspective views illustrating a three-dimensional semiconductor device according to an exemplary embodiment in accordance with principles of inventive concepts and a method of fabricating the same. For the purpose of ease and convenience in explanation, the descriptions to the same components as illustrated in the previous embodiment will be omitted or mentioned briefly.

Referring to FIG. 12, after formation of first insulation pattern 270 illustrated in FIGS. 3 and 4, second trenches 109 may be formed in the sub-stack structures. Second trenches 109 may extend in the y-axis direction to be parallel with first insulation pattern 270. Second trenches 109 may be formed to expose substrate 10. In an exemplary embodiment in accordance with principles of inventive concepts, a depth (a distance along the z-axis direction) and a length (a distance along the y-axis direction) of each of second trenches 109 may be over five times a width (a distance along the x-axis direction) thereof.

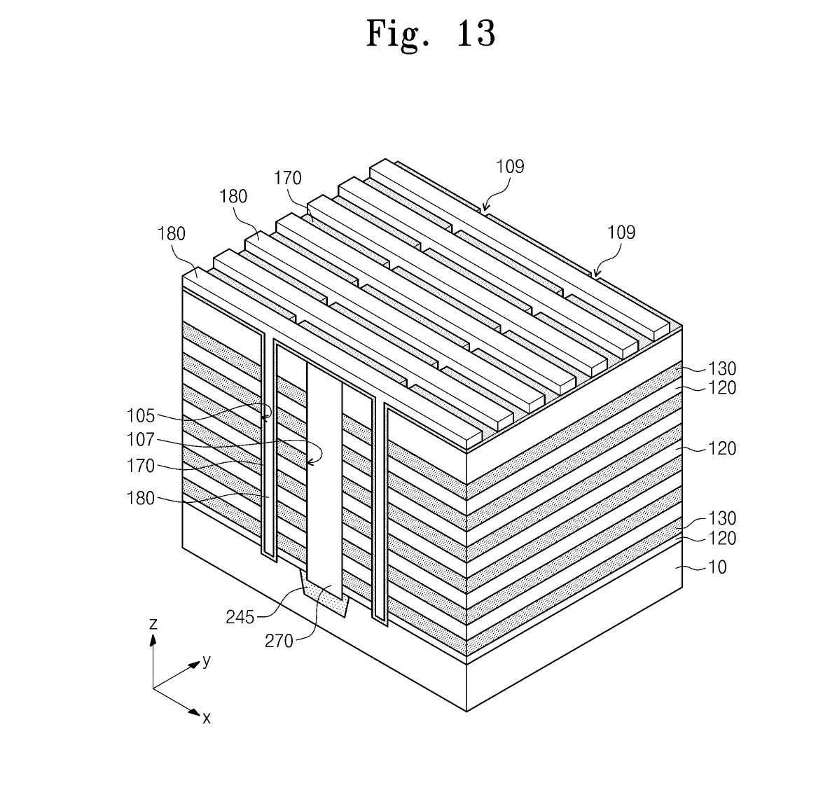

Referring to FIG. 13, a semiconductor layer 170 and a filling layer 180 may be sequentially formed on substrate 10 including second trenches 109. Filling layer 180 may be patterned to expose semiconductor layer 170 and to form a plurality of filling layer patterns extending in the x-direction. The filling layer patterns may be spaced apart from each other in the y-direction. Filling layer 180 may be patterned using an etching process exhibiting an etch selectivity with respect to semiconductor layer 170.

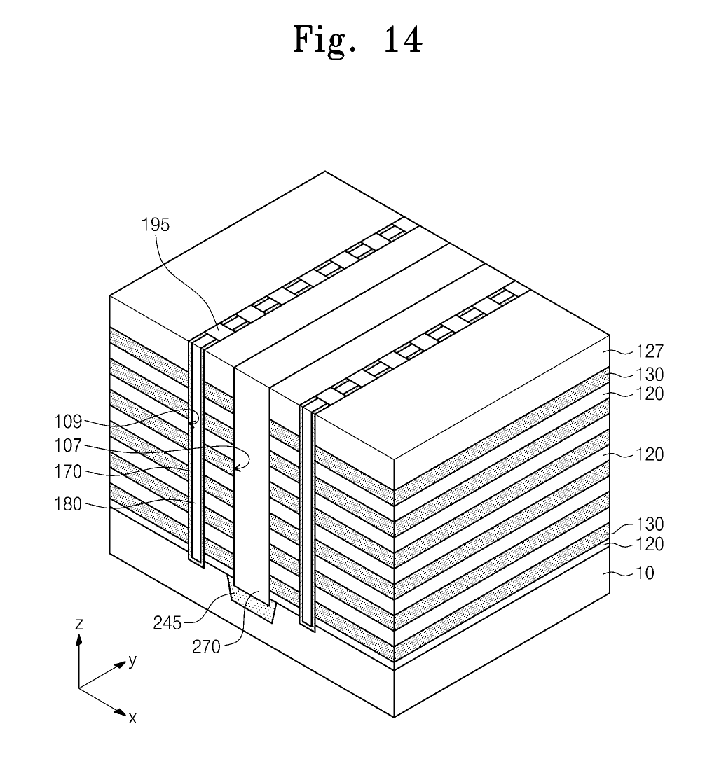

Referring to FIG. 14, semiconductor layer 170 exposed by filling layer patterns 180 may be etched to split semiconductor layer 170 into a plurality of semiconductor patterns which are separated from each other in the y-axis direction. Semiconductor layer 170 may be etched using filling layer patterns 180 as etch masks. After formation of the semiconductor patterns, portions of second trenches 109 may be exposed. String isolation layers 195 may be formed to fill second trenches 109 between the patterned semiconductor layers 170. String isolation layers 195 may be formed of at least one of insulation materials having an etch selectivity with respect to sacrificial layers 130. In an exemplary embodiment in accordance with principles of inventive concepts, string isolation layers 195 may be formed of a silicon oxide layer. After formation of string isolation layers 195, filling layer patterns 180 and semiconductor layer 170 may be planarized to expose the uppermost insulation layer 127.

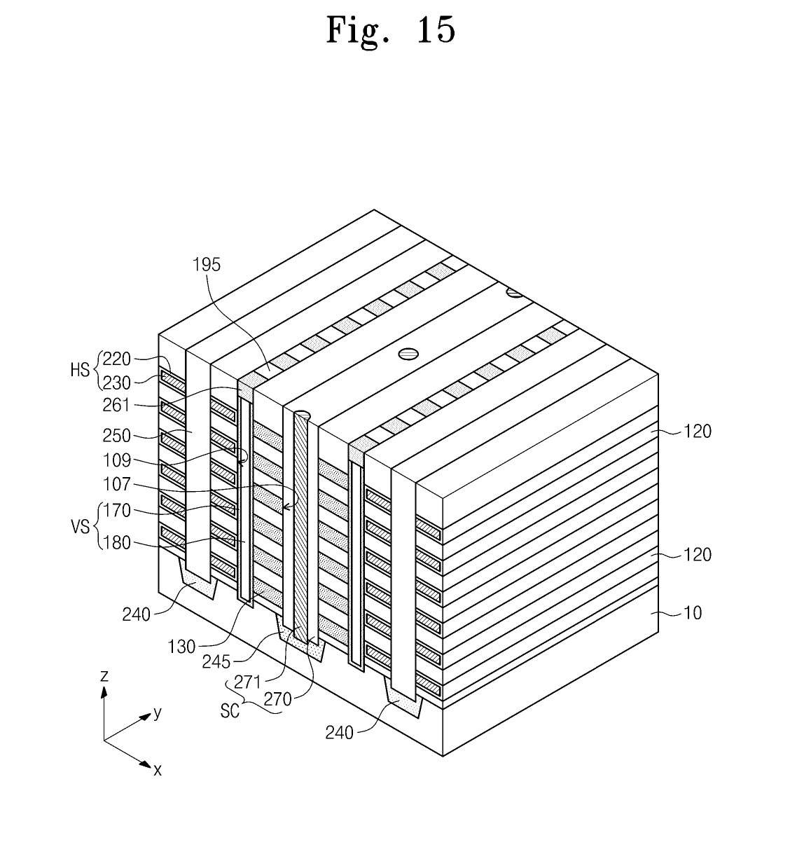

Referring to FIG. 15, the same processes as described with reference to FIGS. 7 to 10 may be performed after formation of string isolation layers 195. Channel structures VS may be formed to penetrate the sub-stack structures, and electrode structures HS may be formed to extend in the y-axis direction. Each of the electrode structures HS may be formed to include a data storage layer 220 and an electrode pattern 230 surrounded by data storage layer 220. Third impurity regions 261 may be formed in respective ones of upper portions of the channel structures VS, and second impurity regions 240 may be formed in substrate 10 under buried insulation layers 250 extending in the y-axis direction. Contact plugs 271 may be formed to penetrate first insulation pattern 270. First insulation pattern 270 and contact plugs 271 therein may constitute a first structure SC.

Sacrificial layers 130 between first structure SC and string isolation layers 195 as well as between first structure SC and the channel structures VS may remain even after the electrode structures HS are formed. That is, while sacrificial layers 130 are removed to from recessed regions 210 (see FIG. 8), the etchant supplied into the first trenches (200 of FIG. 8) may not reach first insulation pattern 270 because of the presence of string isolation layers 195 and the channel structures VS. Thus, even after the electrode structures HS are formed, first insulation pattern 270 may be still surrounded by portions of sacrificial layers 130. In other exemplary embodiments in accordance with principles of inventive concepts, if first trenches 200 are formed between first structure SC and the channel structures VS, sacrificial layers 130 may be completely removed during formation of recessed regions 210. Subsequently, upper plugs (not shown) and upper interconnections may be foamed using the same processes as described with reference to FIG. 11.

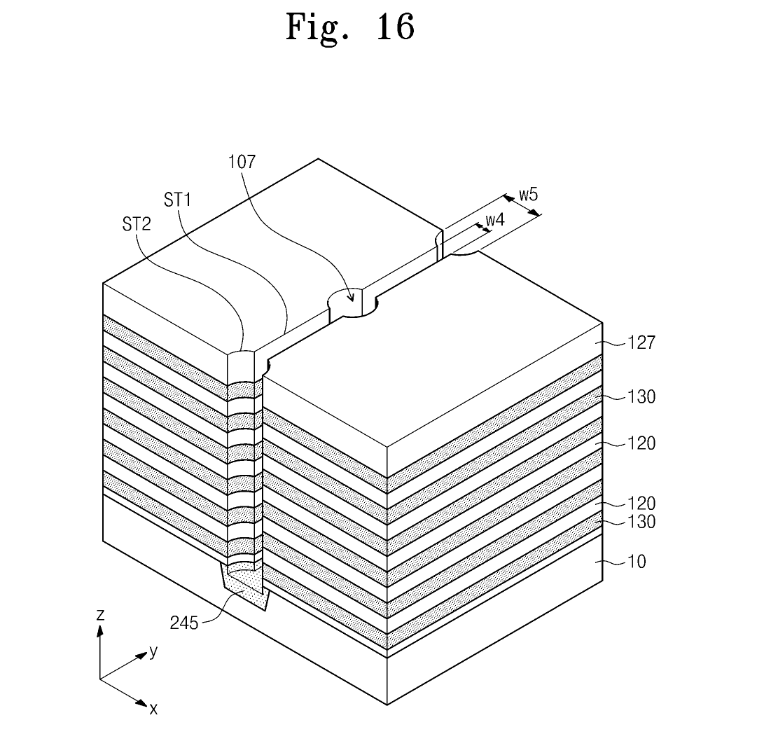

FIGS. 16 to 18 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 16, a stack structure 100 may be formed on a substrate 10 using the same processes as described with reference to FIG. 2. Stack structure 100 may be patterned to form isolation trench 107 that penetrates stack structure 100 and extends in the y-axis direction. A width (a distance along the x-axis direction) of isolation trench 107 may vary according to a position in the y-axis direction. In an exemplary embodiment in accordance with principles of inventive concepts, isolation trench 107 may include first trench regions ST1 having a width w4 and second trench regions ST2 having a width w5 greater than the width w4. Second trench regions ST2 may be spaced apart from each other and may be arrayed in the y-axis direction, and each of first trench regions ST1 may be disposed between the pair of adjacent second trench regions ST2. Second trench regions ST2 may be formed to provide regions in which contact plugs formed in a subsequent process are located. A first impurity region 245 may be formed in substrate 10 under isolation trench 107.

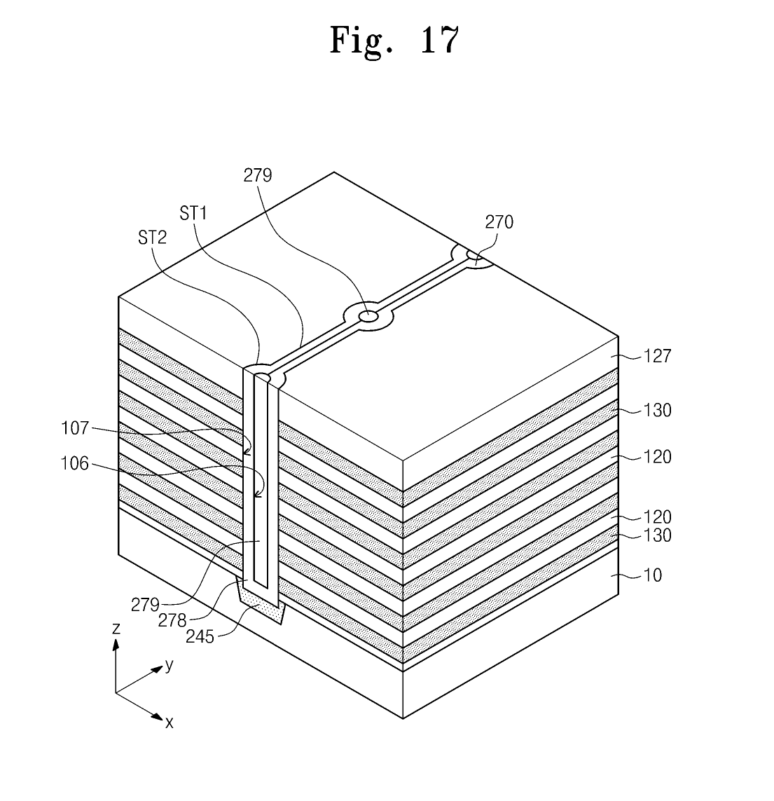

Referring to FIG. 17, a first pattern 278 may be formed to partially fill isolation trench 107. In an exemplary embodiment in accordance with principles of inventive concepts, first pattern 278 may be formed to completely fill first trench regions ST1 and to partially fill second trench regions ST2. That is, first pattern 278 may be formed to a thickness that corresponds to at least half of the width w4 of first trench regions ST1. As a result, first trench regions ST1 may be completely filled with first pattern 278, and second trench regions ST2 may be partially filled with first pattern 278. That is, vertical gaps 106, for example, vertical holes surrounded by first pattern 278 may be formed in respective ones of second trench regions ST2. Second patterns 279 may be formed in respective ones of the vertical gaps 106.

In an exemplary embodiment in accordance with principles of inventive concepts, first pattern 278 may be formed of an insulation layer, and second patterns 279 may also be formed of an insulation layer. In the event that the first and second patterns 278 and 279 are formed of insulation layers, first pattern 278 may be formed of a material having a lower contraction coefficient or a higher expansion coefficient than second patterns 279 when heated. That is, first pattern 278 may be less contracted or greater expanded than second patterns 279 in a subsequent thermal process for forming a semiconductor layer. In an exemplary embodiment in accordance with principles of inventive concepts, first pattern 278 may include at least one of a medium temperature oxide (MTO) layer formed using a chemical vapor deposition (CVD) process, an oxide layer formed using an atomic layer deposition (ALD) process and a high density plasma (HDP) oxide layer. Second patterns 279 may be formed of a different material layer from first pattern 278. Second patterns 279 may be formed of a material which is relatively contracted at a high temperature. For example, second patterns 279 may be formed of at least one of an undoped silicate glass (USG) layer, a tetra-ethyl-ortho-silicate (TEOS) layer, a boro-silicate-glass (BSG) layer and a boro-phospho-silicate-glass (BPSG) layer.

First pattern 278 may have a lower deposition rate than second patterns 279. First pattern 278 may be less contracted or rather more expanded than second patterns 279 at a high temperature. Thus, a tensile stress applied to stack structure 100 may be compensated in a subsequent thermal process. Further, first pattern 278 may be formed to have a relatively denser structure than second patterns 279. Thus, first pattern 278 may suppress a dishing phenomenon which can be generated in a subsequent planarization process.

In other embodiment, first pattern 278 and second patterns 279 may be formed of the same material. That is, first pattern 278 and second patterns 279 may be formed using a single deposition process.

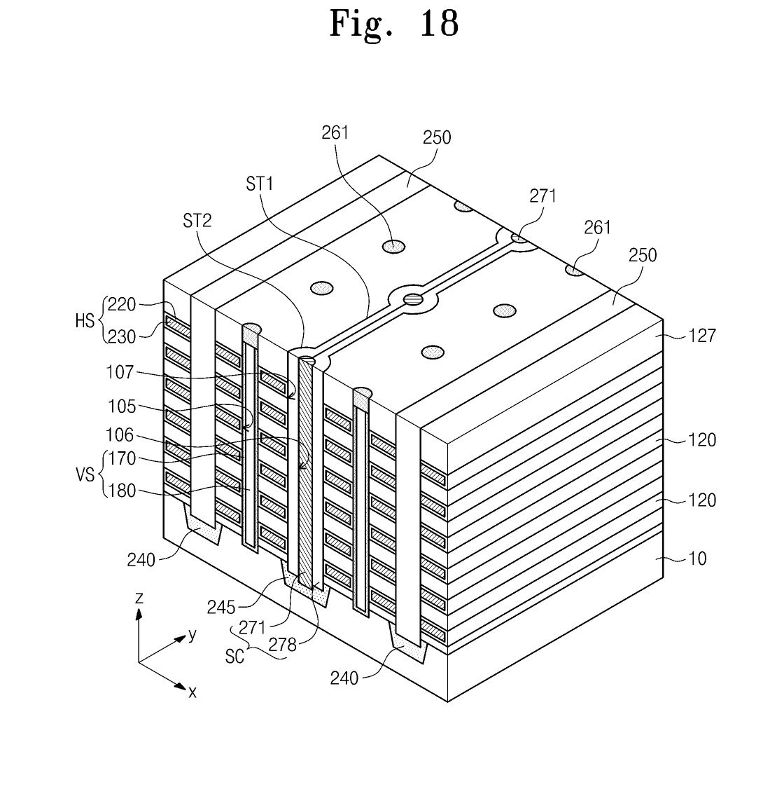

Referring to FIG. 18, the processes described with reference to FIGS. 5 to 10 may be applied to the substrate including the first and second patterns 278 and 279, thereby forming channel structures VS penetrating stack structure 100, electrode structures HS including data storage layers 220 and electrode patterns 230, and buried insulation layers 250. That is, the electrode structures HS may be formed to extend in the y-axis direction. Further, third impurity regions 261 may be formed in respective ones of upper portions of the channel structures VS, and second impurity regions 240 may be formed in the substrate under buried insulation layers 250.

Contact plugs 271 may be formed to penetrate respective ones of second trench regions ST2. Contact plugs 271 and first pattern 278 may constitute a first structure SC. Each of contact plugs 271 may be formed to include at least one of a metal layer, a conductive metal nitride layer and a semiconductor layer. Forming contact plugs 271 may include etching at least portions of respective ones of second patterns 279 illustrated in FIG. 17 to expose first impurity region 245. Contact plugs 271 may be formed in respective ones of second trench regions ST2 having a width which is relatively greater than that of first trench regions ST1. According to the present exemplary embodiment, first trench regions ST1 may be formed to have a relatively narrow width while second trench regions ST2 may be formed to have a relatively wide width. Thus, the integration density of the three-dimensional semiconductor device can be increased without any reduction of process margin in formation of the contact plugs penetrating second trench regions ST2. In another embodiment, the process of forming second patterns 279 may be omitted. For example, after formation of first pattern 278, portions of first pattern 278 under the vertical gaps 106 may be selectively removed to expose first impurity region 245 and contact plugs 271 may be formed in the vertical gaps 106 without formation of second patterns 279.

In still another exemplary embodiment, first pattern 278 and/or second patterns 279 may be formed of a semiconductor material or a conductive material. For example, first pattern 278 and/or second patterns 279 may be formed of a undoped polysilicon layer or a P-type polysilicon layer. In the event that first pattern 278 and/or second patterns 279 may be formed of a conductive layer, the process of forming contact plugs 271 may be omitted.

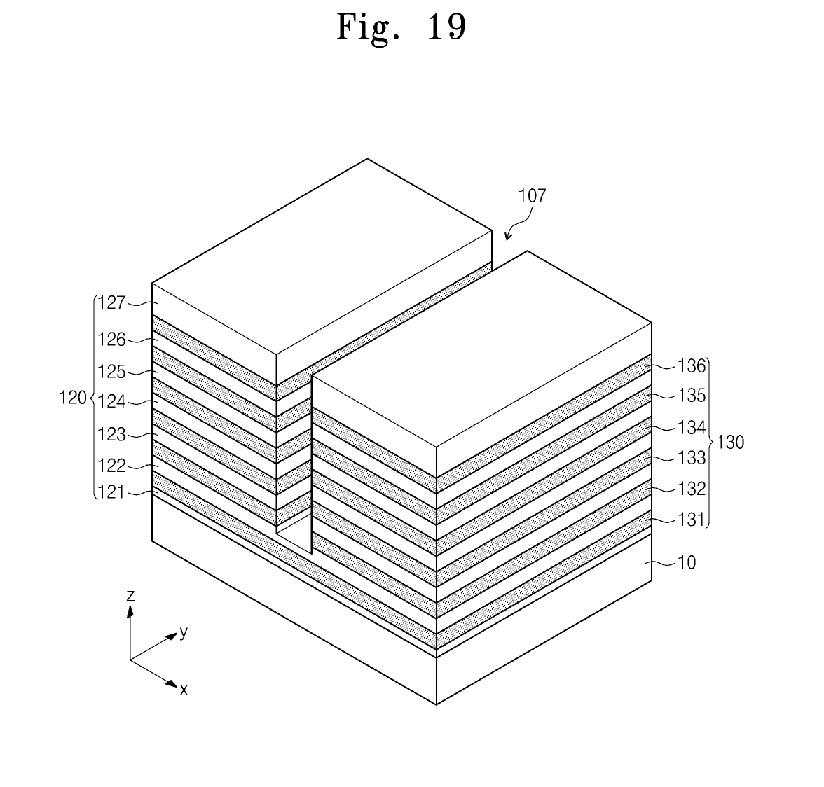

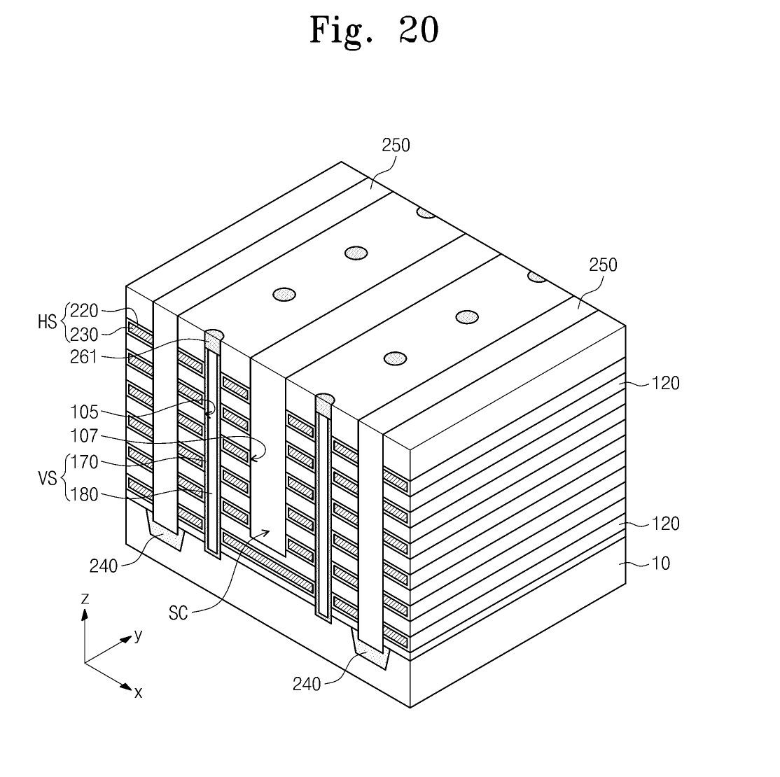

FIGS. 19 and 20 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 19, a stack structure 100 may be formed on a substrate 10 using the same processes as described with reference to FIG. 2. An isolation trench 107 may be formed in stack structure 100. Isolation trench 107 may be formed by partially etching stack structure 100. In this exemplary embodiment, isolation trench 107 may not completely penetrate stack structure 100. That is, in this embodiment, isolation trench 107 may not expose substrate 10. More particularly, in this exemplary embodiment, isolation trench 107 may not split first sacrificial layer 131 and second insulation layer 122. Isolation trench 107 may be formed to have a sufficient depth to relieve an internal stress that can be generated during formation of stack structure 100. In an exemplary embodiment in accordance with principles of inventive concepts, isolation trench 107 may be formed to a depth which is equal to or greater than half a thickness (a height along the z-axis direction) of stack structure 100, or, in other words, at least half a distance between.

Referring to FIG. 20, the same processes as described with reference to FIGS. 4 to 10 may be applied to the resultant where isolation trench 107 is formed. As a result, a first structure SC, electrode structures HS and channel structures VS may be formed in stack structure 100. A horizontal cross sectional area (e.g., a planar area) of the electrode structure HS formed between first structure SC and substrate 10 may be greater than that of each of the electrode structures HS formed between first structure SC and the channel structures VS. That is, the electrode structure HS under first structure SC may not be split by first structure SC. First structure SC may be formed of an insulation material, and may not include any contact plugs therein, unlike the embodiment illustrated in FIG. 15.

According to the present embodiment, the internal stress in stack structure 100 may be alleviated prior to a high temperature process, for example, a process of forming semiconductor layers 170 constituting the channel structures VS. Thus, deformation of stack structure 100 may be prevented.

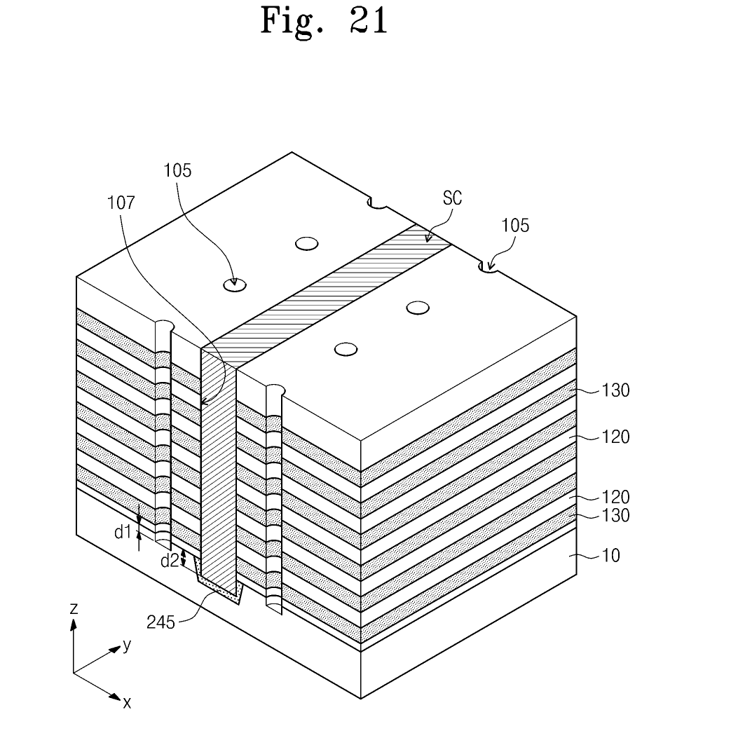

FIGS. 21 to 26 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 21, a stack structure 100, a first impurity region 245 and an isolation trench 107 may be formed on a substrate 10 using the same processes as described with reference to FIGS. 2 and 3, and first structure SC may be formed in isolation trench 107. After formation of isolation trench 107, first impurity region 245 may be formed in substrate 10 under isolation trench 107. First impurity region 245 may extend in the y-axis direction to be parallel with isolation trench 107. First impurity region 245 may correspond to a pick up region to apply an electrical signal, for example, a voltage signal to substrate 10.

First structure SC may include a conductive pattern. The conductive pattern may be formed of at least of a metal material and a semiconductor material. In an exemplary embodiment in accordance with principles of inventive concepts, isolation trench 107 may be completely filled with the conductive pattern. In this case, the conductive pattern may be formed to directly contact sidewalls of sacrificial layers 130 and the insulation layers 120 exposed by isolation trench 107. When a three-dimensional semiconductor device according to the present embodiment operates, a certain voltage may be applied to substrate 10 through first structure SC including the conductive pattern.

Channel holes 105 may be formed to penetrate stack structure 100 after formation of first structure SC. A depth D2 by which first structure SC extends into substrate 10 may be greater than a depth D1 by which channel holes 105 extend into substrate 10. That is, isolation trench 107 may be formed to be deeper than channel holes 105. If isolation trench 107 is deeper than channel holes 105, first structure SC in isolation trench 107 may more stably support first structure SC while sacrificial layers 130 are removed. Thus, subsequent processes may be stably performed.

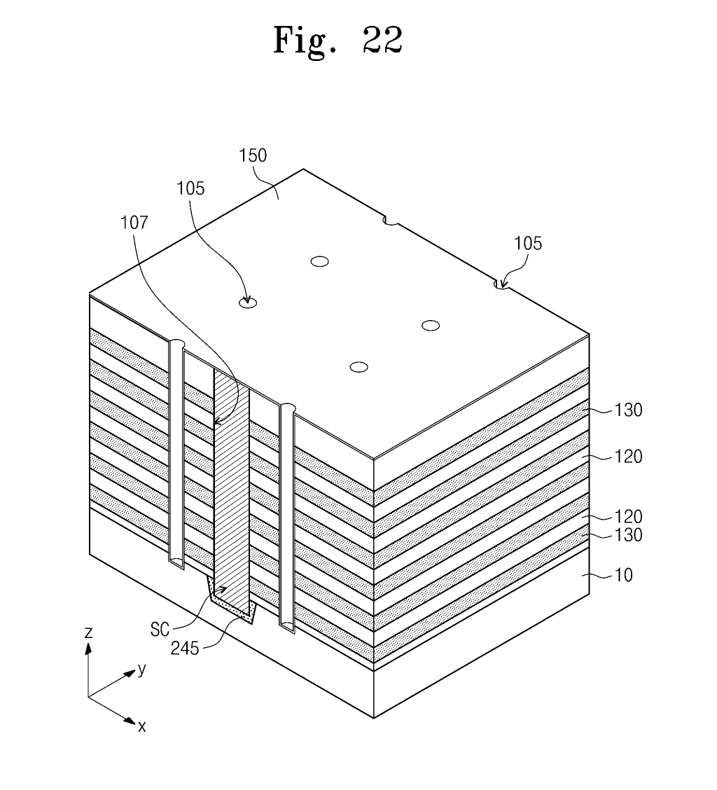

Referring to FIG. 22, a first data storage layer 150 may be formed on the substrate including channel holes 105. First data storage layer 150 may be conformally formed along inner surfaces of channel holes 105. First data storage layer 150 may be formed to include a single layer or a plurality of layers. For example, first data storage layer 150 may include at least one of a plurality of films which are used as memory elements of charge trap type nonvolatile memory devices.

Various embodiments relating to first data storage layer 150 will be described in detail with reference to FIGS. 73 to 75.

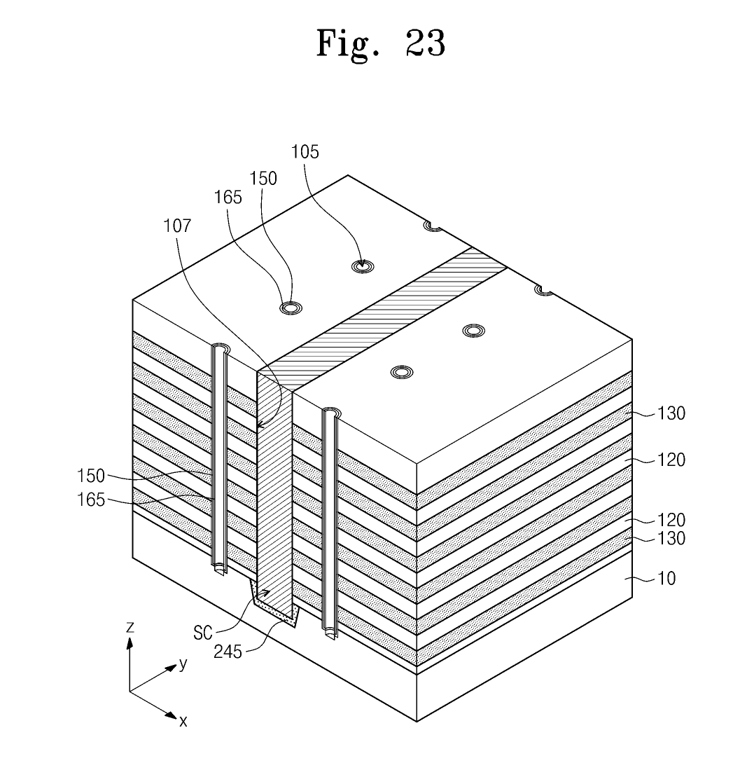

Referring to FIG. 23, spacers 165 may be formed on sidewalls of the first data storage layers 150 in channel holes 105. Forming spacers 165 may include conformally forming a semiconductor layer (not shown) on first data storage layer 150 and anisotropically etching the semiconductor layer and first data storage layer 150 to expose portions of substrate 10 under channel holes 105. Thus, first data storage layer 150 may be separated into a plurality of patterns remaining in respective ones of channel holes 105, and spacers 165 may be formed on the sidewalls of the first data storage layers 150 in channel holes 105. Substrate 10 under channel holes 105 may be recessed due to an over-etch step of the anisotropic etching process of forming spacers 165, as illustrated in FIG. 23.

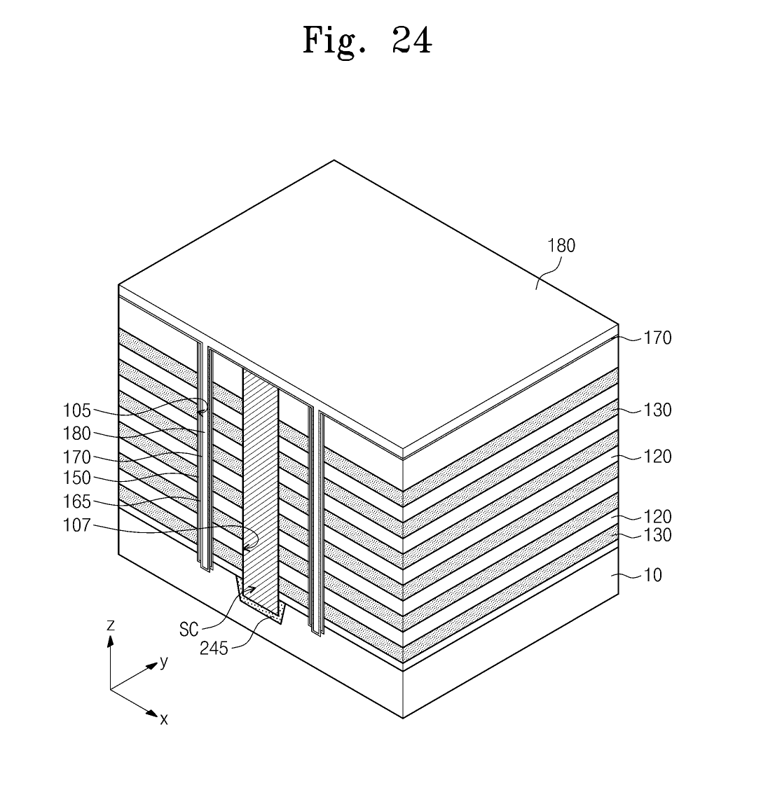

Referring to FIG. 24, a semiconductor layer 170 and a filling layer 180 may be sequentially formed on the substrate including spacers 165. Semiconductor layer 170 may be formed of a polysilicon layer using an atomic layer deposition (ALD) process or a chemical vapor deposition (CVD) process. In an exemplary embodiment in accordance with principles of inventive concepts, semiconductor layer 170 may be conformally formed not to completely fill channel holes 105 surrounded by spacers 165 or first data storage layer 150. Filling layer 180 may be formed to fill channel holes 105 surrounded by semiconductor layer 170. Alternatively, semiconductor layer 170 may be formed to completely fill channel holes 105. In this case, the process of forming filling layer 180 may be omitted.

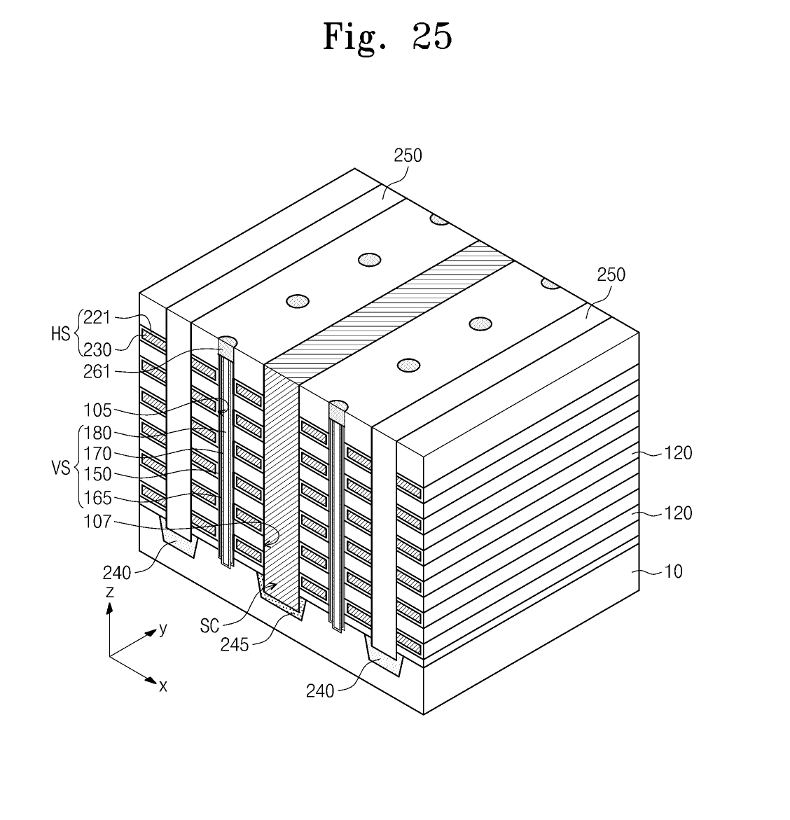

Referring to FIG. 25, the processes described with reference to FIGS. 7 may be applied to the substrate including filling layer 180 or semiconductor layer 170, thereby forming channel structures VS penetrating stack structure 100 and electrode structures HS extending in the y-axis direction. Each of the channel structures VS may include first data storage layer 150, the spacer 165 in first storage layer 150, semiconductor layer 170 in the spacer 165, and filling layer 180 in semiconductor layer 170. Each of the electrode structures HS may include a second data storage layer 221 and an electrode pattern 230. The second data storage layer 221 may be foamed of a single layer or a plurality of layers, for example. The configuration of second data storage layer 221 will be described in detail with reference to FIGS. 73 to 75.

Second impurity regions 240 may be formed in substrate 10 under buried insulation layers 250 that penetrate stack structure 100 and extend in the y-axis direction, and third impurity regions 261 may be formed in upper portions of the channel structures VS. In an exemplary embodiment in accordance with principles of inventive concepts, the second and third impurity regions 240 and 261 may be heavily doped with N-type impurities.

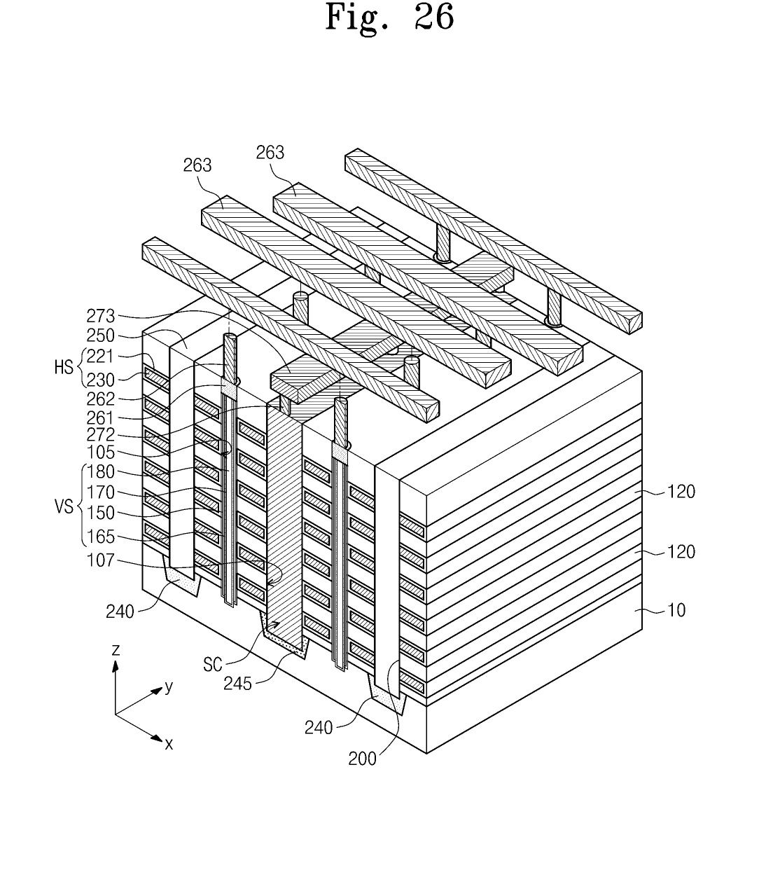

Referring to FIG. 26, first upper interconnections 263 and a second upper interconnection 273 may be formed on the substrate including the impurity regions 240 and 261 as well as buried insulation layers 250. Each of the first upper interconnections 263 may electrically connect the channel structures VS arrayed in a column parallel with the x-axis direction to each other, and the second upper interconnection 273 may be disposed on first structure SC to extend in the y-axis direction. That is, second upper interconnection 273 may extend along isolation trench 107 and may extend to cross first upper interconnections 263. The first upper interconnections 263 may be electrically connected to the channel structures VS through first upper plugs 262, and second upper interconnection 273 may be electrically connected to first structure SC through second upper plugs 272.

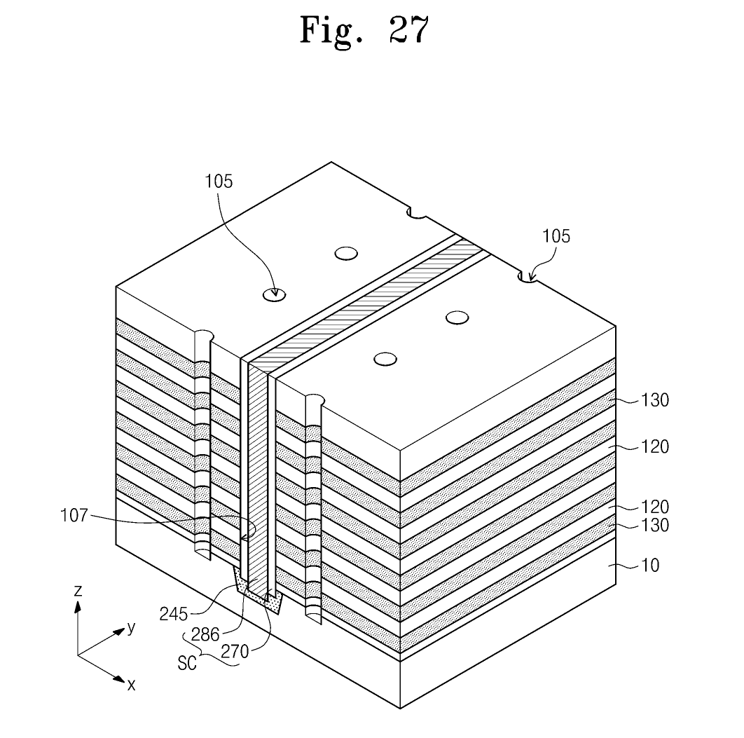

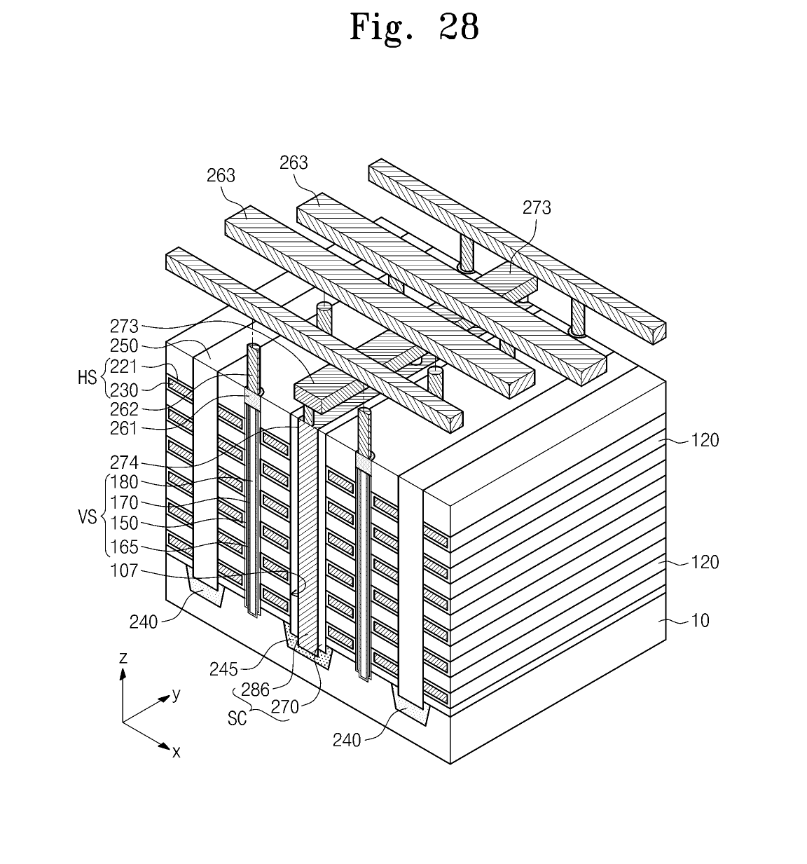

FIGS. 27 and 28 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 27, a stack structure 100 may be formed on a substrate 10 using the same processes as described with reference to FIG. 2. An isolation trench 107 may be then formed to penetrate stack structure 100 and to expose substrate 10. A first impurity region 245 may be formed in substrate 10 under isolation trench 107.

A first insulation pattern 270 may be formed in isolation trench 107, and a first conductive pattern 286 may be formed to penetrate first insulation pattern 270 and to contact substrate 10, for example. Forming first insulation pattern 270 and the first conductive pattern 286 may include conformally forming an insulation layer in isolation trench 107, anisotropically etching the insulation layer to expose substrate 10 (e.g., first impurity region 245) under isolation trench 107, and filling isolation trench 107 with a conductive material. First insulation pattern 270 may be formed of a material having an etch selectivity with respect to sacrificial layers 130. In an exemplary embodiment in accordance with principles of inventive concepts, a thickness of first insulation pattern 270 may be more than quarter a width (a distance along the x-axis direction) of isolation trench 107. First insulation pattern 270 and the first conductive pattern 286 may constitute a first structure SC.

The first conductive pattern 286 may completely fill isolation trench 107 surrounded by first insulation pattern 270. The first conductive pattern 286 may be formed to include at least one of a polysilicon layer and a metal layer. The first conductive pattern 286 and first insulation pattern 270 may be formed using a planarization process. Channel holes 105 may be formed to penetrate stack structure 100. Channel holes 105 may expose substrate 10.

Referring to FIG. 28, the processes described with reference to FIGS. 22 to 26 may be applied to the substrate including channel holes 105. According to the present embodiment, first structure SC may include first insulation pattern 270 and the first conductive pattern 286, and the first conductive pattern 286 may be spaced apart from the second data storage layers 221 constituting the electrode structures HS by first insulation pattern 270.

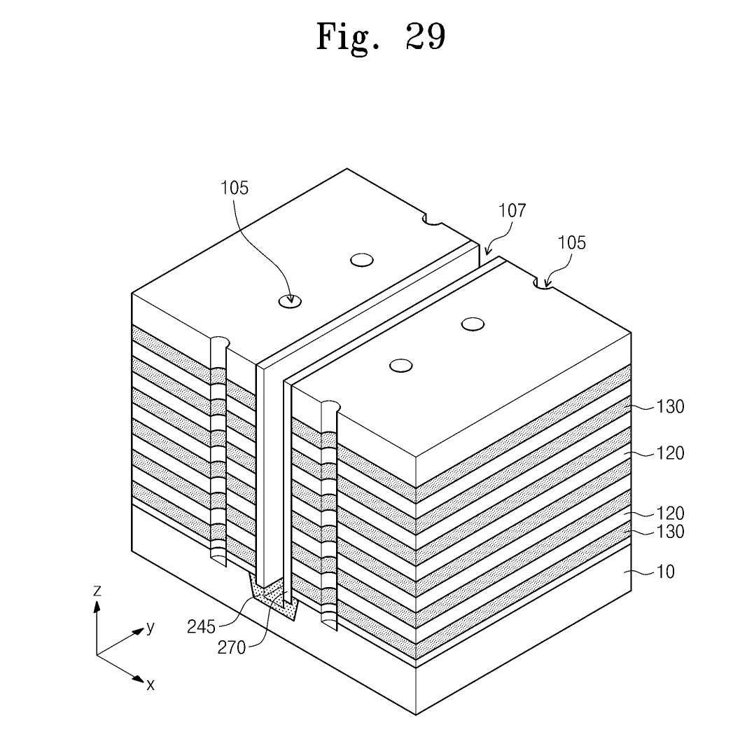

FIGS. 29 to 32 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 29, a stack structure 100 may be formed on a substrate 10 using the same processes as described with reference to FIG. 2. An isolation trench 107 may be then formed to penetrate stack structure 100 and to expose substrate 10. Isolation trench 107 may be formed to extend in the y-axis direction. A first impurity region 245 may be formed in substrate 10 under isolation trench 107. A first insulation pattern 270 may be conformally formed in isolation trench 107. First insulation pattern 270 on a bottom surface of isolation trench 107 may be removed using a spacer etching process to expose substrate 10 (e.g., first impurity region 245) under isolation trench 107. Channel holes 105 may be formed to penetrate stack structure 100. Channel holes 105 may expose substrate 10. In an exemplary embodiment in accordance with principles of inventive concepts, channel holes 105 may be formed after formation of first insulation pattern 270.

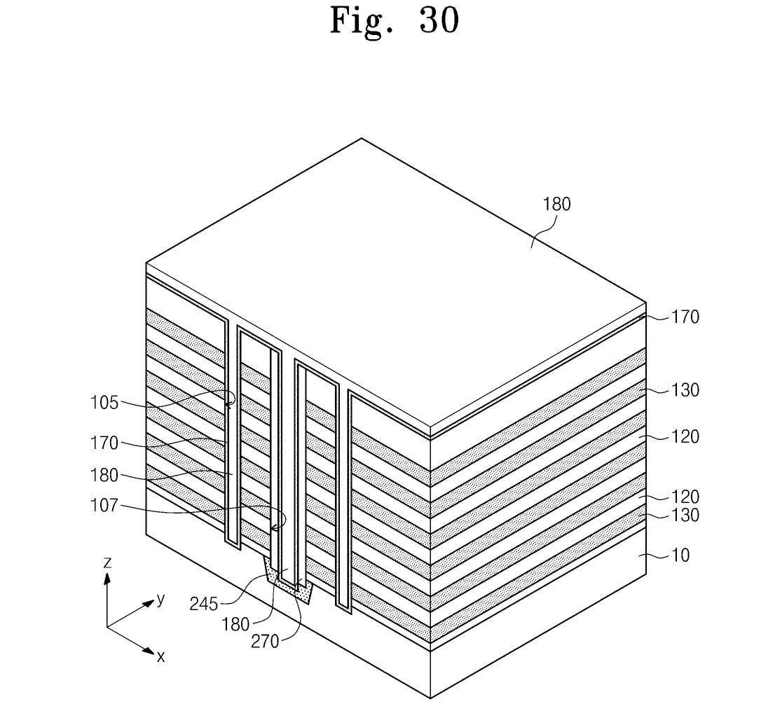

Referring to FIG. 30, a semiconductor layer 170 and a filling layer 180 may be sequentially formed on the resultant where channel holes 105 are formed. Semiconductor layer 170 may be conformally formed in channel holes 105 and in isolation trench 107, and filling layer 180 may be formed to fill channel holes 105 and in isolation trench 107. Semiconductor layer 170 and filling layer 180 may be formed to cover the sidewall of first insulation pattern 270 in isolation trench 107. Semiconductor layer 170 may be electrically connected to first impurity region 245.

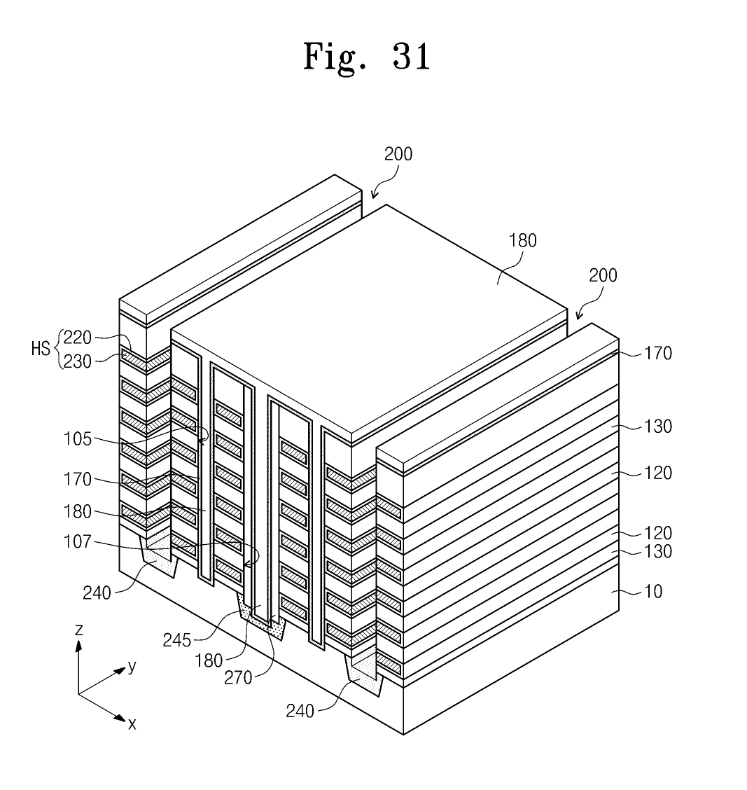

Referring to FIG. 31, filling layer 180, semiconductor layer 170 and stack structure 100 may be patterned to form first trenches 200, and sacrificial layers 130 may be replaced with electrode structures HS. Each of the electrode structures HS may include a data storage layer 220 and an electrode pattern 230. Second impurity regions 240 may be formed in substrate 10 under first trenches 200. The second impurity regions 240 may be doped with impurities having a different conductivity type from that of substrate 10.

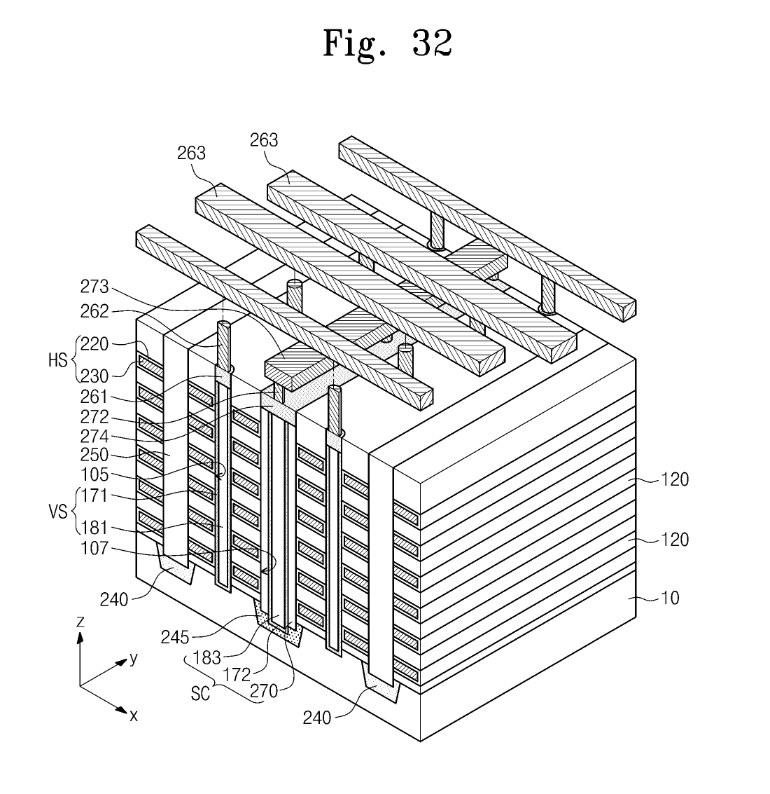

Referring to FIG. 32, buried insulation layers 250 may be formed to fill respective ones of first trenches 200. Buried insulation layers 250 may be formed using a planarization process. During the planarization process, filling layer 180 and semiconductor layer 170 on stack structure 100 may be removed to expose a top surface of stack structure 100. As a result, channel structures VS may be formed in respective ones of channel holes 105, and a first structure SC may be formed in isolation trench 107. Each of the channel structures VS may include a semiconductor pattern 171 and a filling pattern 181, and first structure SC may include a first insulation pattern 270, a first conductive pattern 172 and a second insulation pattern 183.

A fourth impurity region 274 may be formed in an upper portion of first structure SC, and third impurity regions 261 may be formed in respective ones of upper portions of the channel structures VS. The third and fourth impurity regions 261 and 274 may be formed, for example, by removing upper portions of filing patterns 181 and second insulation patterns 183 to form recessed regions, filling the recessed regions with semiconductor material patterns, and doping the semiconductor material patterns with impurity ions.

The fourth impurity region 274 may be doped with impurity ions having the same conductivity type as substrate 10, and the third impurity regions 261 may be doped with impurity ions having a different conductivity type from that of substrate 10, for example. When the third impurity regions 261 have a different conductivity type from the fourth impurity region 274, the third and fourth impurity regions 261 and 274 may be formed using a plurality of separate ion implantation processes. Subsequently, first upper interconnections 263 and a second upper interconnection 273 may be formed on the substrate including the third and fourth impurity regions 261 and 274. The first upper interconnections 263 may be electrically connected to the channel structures VS through first upper plugs 262, and the second upper interconnection 273 may be electrically connected to first structure SC through second upper plugs 272.

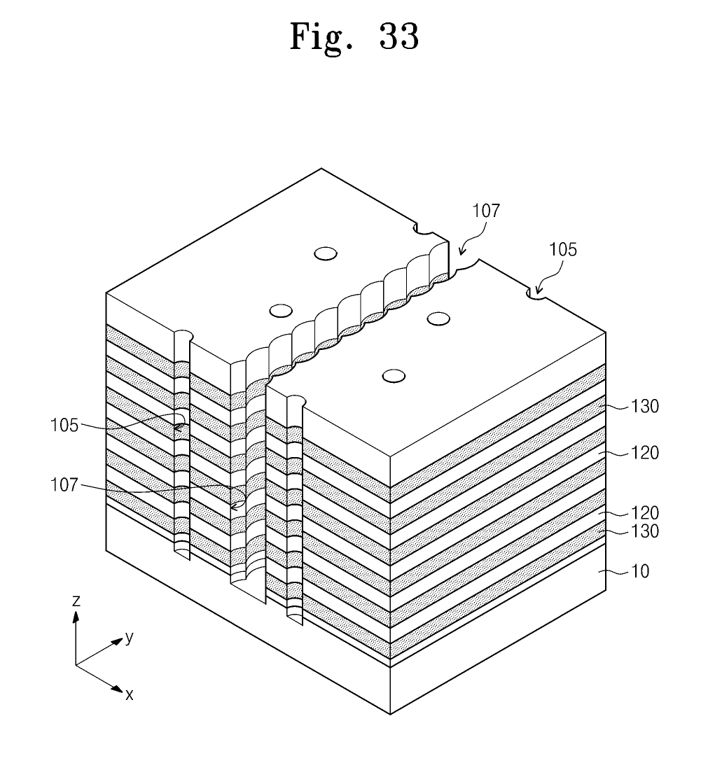

FIGS. 33 to 37 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 33, a stack structure 100 may be formed on a substrate 10 using the same processes as described with reference to FIG. 2. An isolation trench 107 and channel holes 105 may be then formed in stack structure 100. In the present, isolation trench 107 and channel holes 105 may be simultaneously formed. That is, isolation trench 107 and channel holes 105 may be formed using a single step of patterning process. When isolation trench 107 and channel holes 105 may be simultaneously formed, a depth of isolation trench 107 may be substantially equal to that of channel holes 105. Isolation trench 107 and channel holes 105 may be formed to expose substrate 10.

Isolation trench 107 may have a shape that a plurality of circles are arrayed in the y-axis direction and portions of the circles overlaps with each other when viewed from a plan view. Channel holes 105 may be arrayed in a plurality of rows which are parallel with the y-direction. Channel holes 105 in each row may be arrayed zigzag along the y-axis direction and may be spaced apart from each other. In an exemplary embodiment in accordance with principles of inventive concepts, channel holes 105 arrayed in each row may include even-numbered channel holes 105 and odd-numbered channel holes 105, and the even-numbered channel holes 105 may be shifted by a predetermined distance in the x-axis direction from a straight line in which the odd-numbered channel holes 105 are arrayed. Thus, distances between isolation trench 107 and the pair of adjacent channel holes 105 arrayed in the y-axis direction may be different from each other. Accordingly, the above array of channel holes 105 may increase the integration density of the memory cell array region in terms of a planar area.

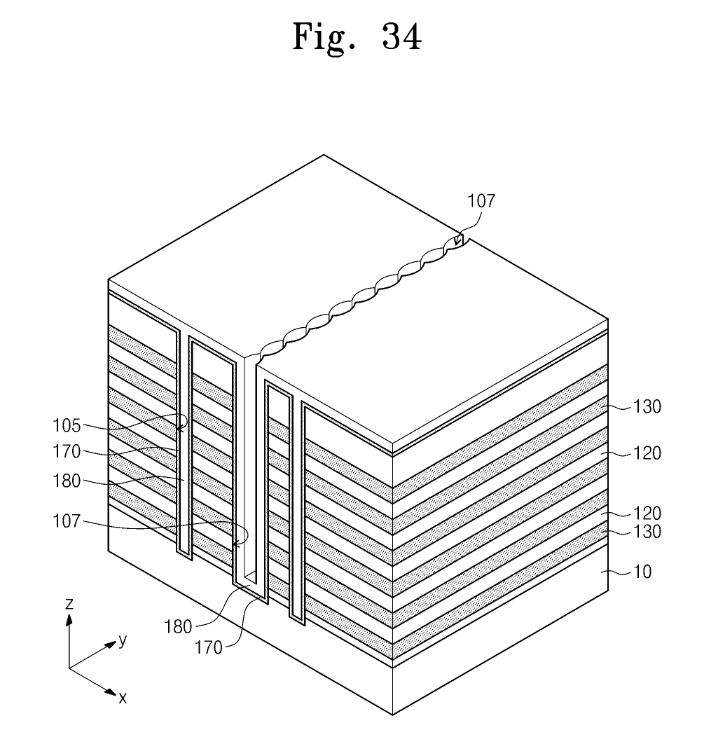

Referring to FIG. 34, a semiconductor layer 170 and a filling layer 180 may be sequentially formed on the resultant where channel holes 105 and isolation trench 107 are formed. Semiconductor layer 170 may be conformally formed in channel holes 105 and in isolation trench 107, and filling layer 180 may be formed to fill channel holes 105 but not to fill isolation trench 107. That is, if isolation trench 107 is formed to have a relatively wider width than channel holes 105, channel holes 105 may be completely filled with filling layer 180 while isolation trench 107 may not be completely filled with filling layer 180, as illustrated in FIG. 34. In other embodiment, filling layer 180 may be formed to completely fill isolation trench 107 and channel holes 105.

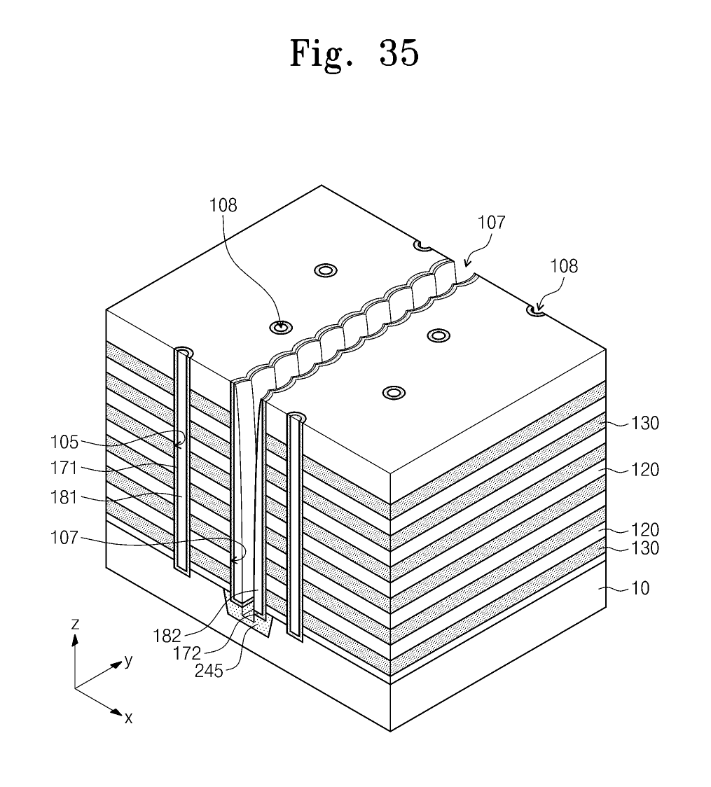

Referring to FIG. 35, filling layer 180 and semiconductor layer 170 may be anisotropically etched to form a spacer 182 in isolation trench 107 and to expose substrate 10 under isolation trench 107. In addition, while the spacer 182 is formed, a semiconductor pattern 171 and a filling pattern 181 may be formed from semiconductor layer 170 and the filling layer 170 in each of channel holes 105. A first conductive pattern 172 may be formed in isolation trench 107 from semiconductor layer 170. During the anisotropic etching process of forming the spacer 182, substrate 10 may be recessed.

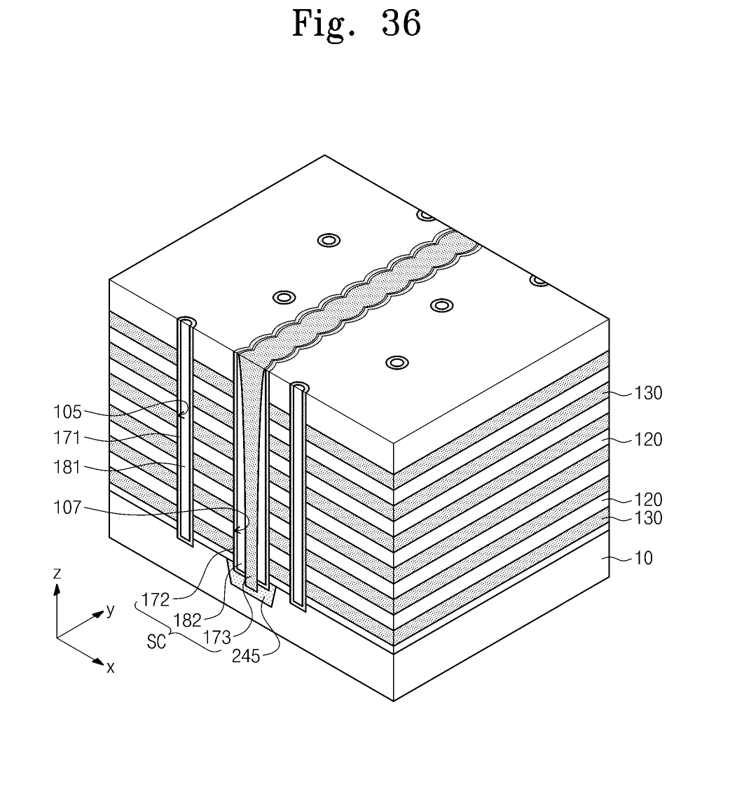

Referring to FIG. 36, after formation of the spacer 182, a second conductive pattern 173 may be formed to fill isolation trench 107 surrounded by the spacer 182. The second conductive pattern 173 may be formed of at least one of a doped silicon material, a metal material, a metal nitride material and a metal silicide material. Second conductive pattern 173 may be electrically connected to first impurity region 245. Second conductive pattern 173 may be formed using a planarization process. The first conductive pattern 172, spacer 182 and second conductive pattern 173 may constitute a first structure SC.

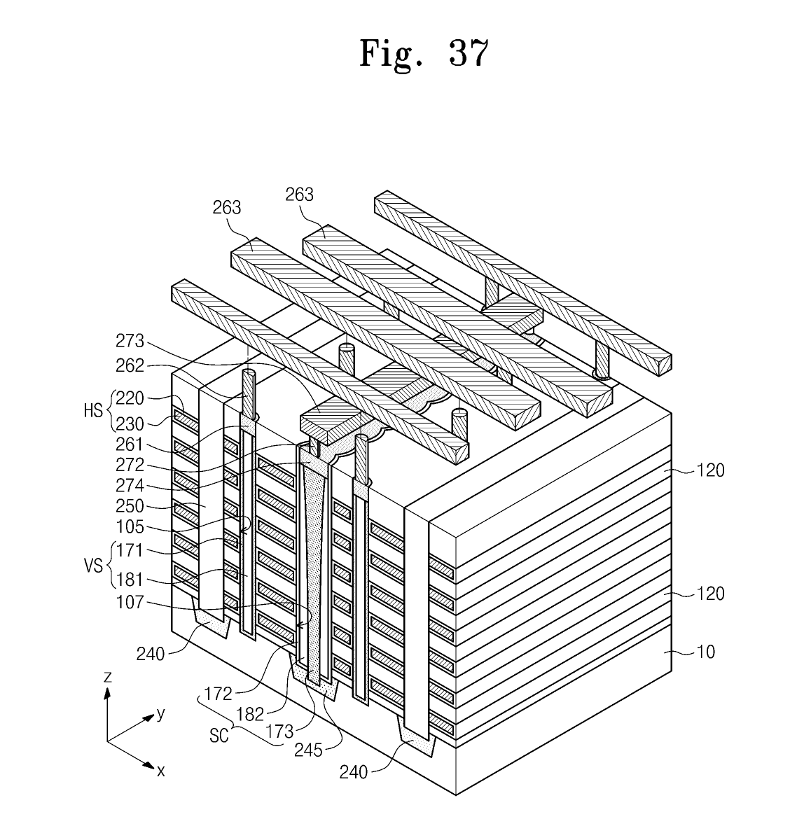

Referring to FIG. 37, the processes described with reference to FIGS. 31 and 32 may be applied to the substrate including the second conductive pattern 173. As result, fourth impurity region 274 may be formed in an upper portion of first structure SC, and third impurity regions 261 may be formed in respective ones of upper portions of the channel structures VS. The fourth impurity region 274 may be formed to have the same conductivity type as that of substrate 10, and the third impurity regions 261 may be formed to have a different conductivity type from that of substrate 10. First and second upper interconnections 263 and 273, as well as first and second upper plugs 262 and 272, may be formed on the resultant where the third and fourth impurity regions 261 and 274 are formed.

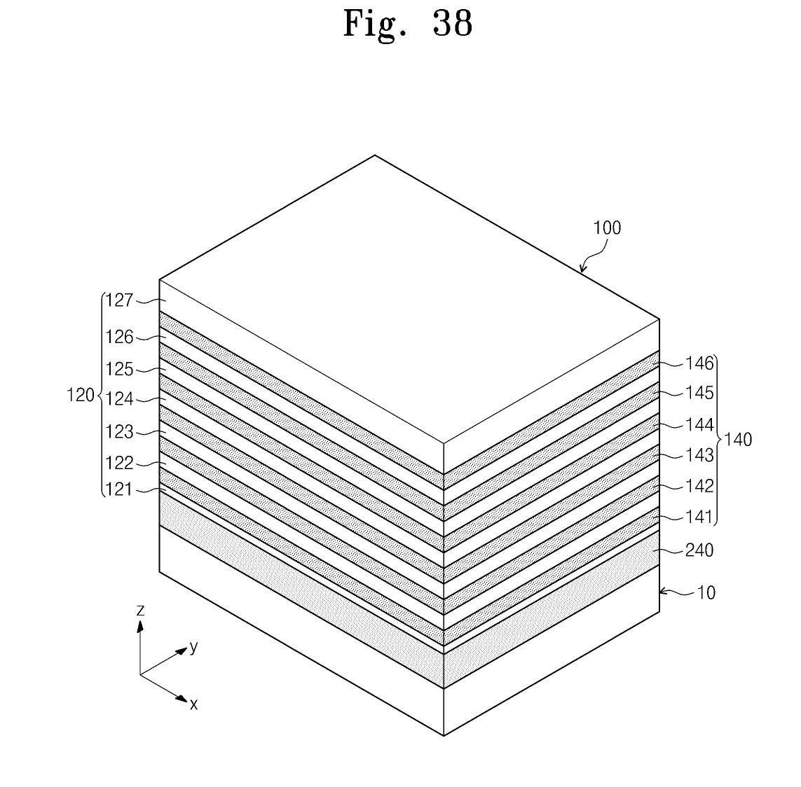

FIGS. 38 to 43 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 38, a stack structure 100 may be formed on a substrate 10. Stack structure 100 may be formed by alternately and repeatedly stacking first layers and second layers. The first layers may correspond to insulation layers 120 (121, 122, 123, 124, 125, 126 and 127), and the second layers may correspond to electrode layers 140 (141, 142, 143, 144, 145 and 146). The electrode layers 140 may be formed of a doped polysilicon material or a metallic material, for example. The insulation layers 120 may be formed of a silicon oxide layer or a silicon nitride layer, for example.

A second impurity region 240 may be formed in substrate 10. The second impurity region 240 may be formed prior to formation of stack structure 100. The second impurity region 240 may be formed to have a predetermined depth from a top surface of substrate 10 and to have a different conductivity type from substrate 10.

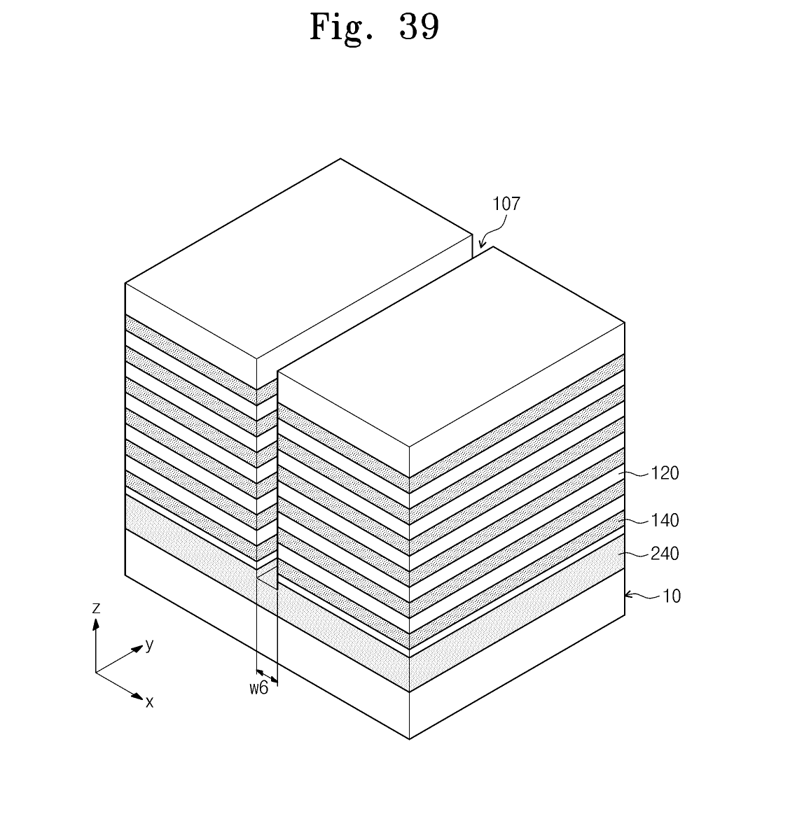

Referring to FIG. 39, stack structure 100 may be patterned to form at least one isolation trench 107. Isolation trench 107 may extend in a y-axis direction. Isolation trench 107 may have a predetermined width w6 along an x-axis direction. Isolation trench 107 may be formed to expose substrate 10.

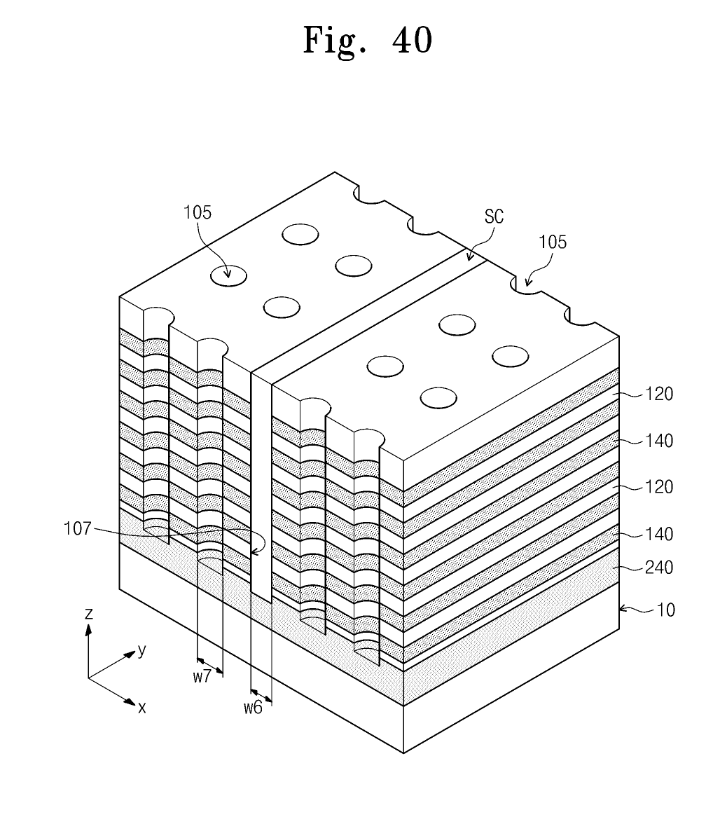

Referring to FIG. 40, a first structure SC may be formed in isolation trench 107. First structure SC may include an insulation layer. In an exemplary embodiment in accordance with principles of inventive concepts, first structure SC may be formed to include a silicon oxide layer or a silicon oxynitride layer. Channel holes 105 may be formed to penetrate first structure SC. A diameter w7 of channel holes 105 may be greater than the width w6 of isolation trench 107. In an exemplary embodiment in accordance with principles of inventive concepts, channel holes 105 may be formed after formation of first structure SC.

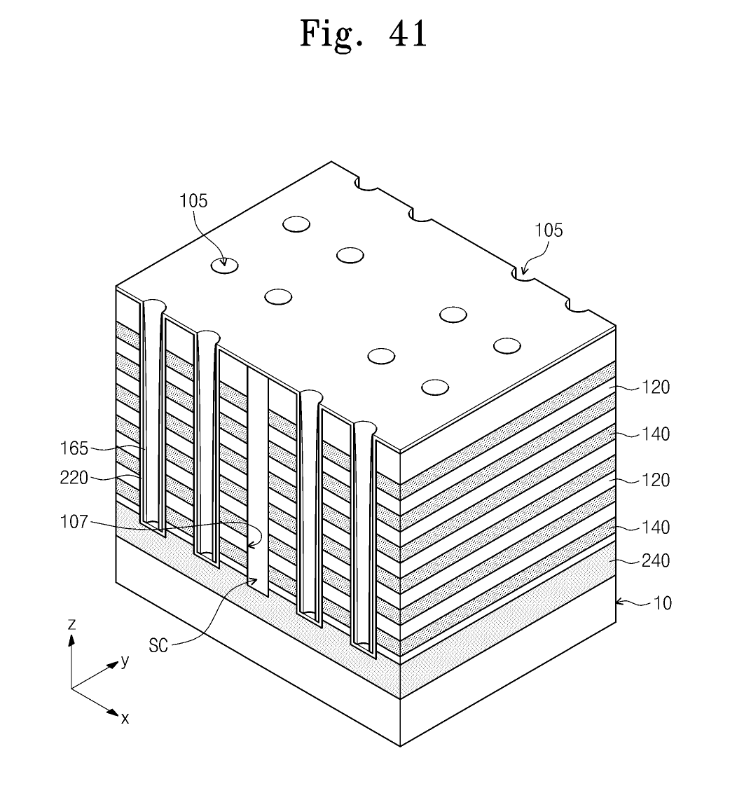

Referring to FIG. 41, a data storage layer 220 may be conformally formed in channel holes 105 and on stack structure 100. Spacers 165 may be formed on inner walls of data storage layer 220 in channel holes 105. Spacers 165 may be formed by conformally forming a semiconductor layer on data storage layer 220 and anisotropically etching the semiconductor layer. After formation of spacers 165, data storage layer 220 on bottom surfaces of channel holes 105 may be exposed.

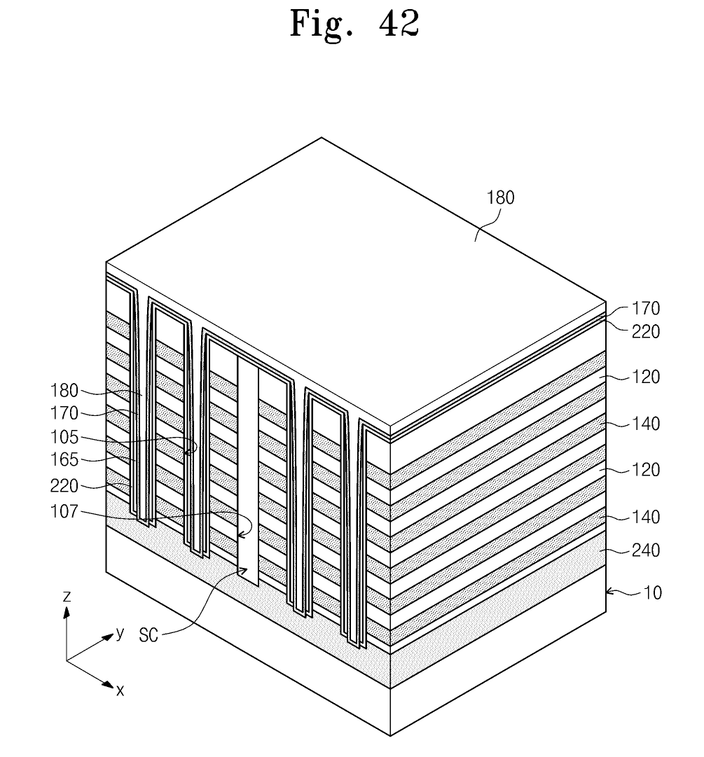

Referring to FIG. 42, data storage layer 220 on the bottom surfaces of channel holes 105 may be etched using spacers 165 as etch masks, thereby exposing substrate 10 under channel holes 105. A semiconductor layer 170 and a filling layer 180 may be sequentially formed on the resultant where substrate 10 under channel holes 105 is exposed. In an exemplary embodiment in accordance with principles of inventive concepts, semiconductor layer 170 may be conformally formed in channel holes 105, and filling layer 180 may be formed to fill channel holes 105 surrounded by semiconductor layer 170. Alternatively, semiconductor layer 170 may be formed to fill channel holes 105. In this case, the process of forming filling layer 180 may be omitted. Semiconductor layer 170 may be electrically connected to the second impurity region 240 through channel holes 105.

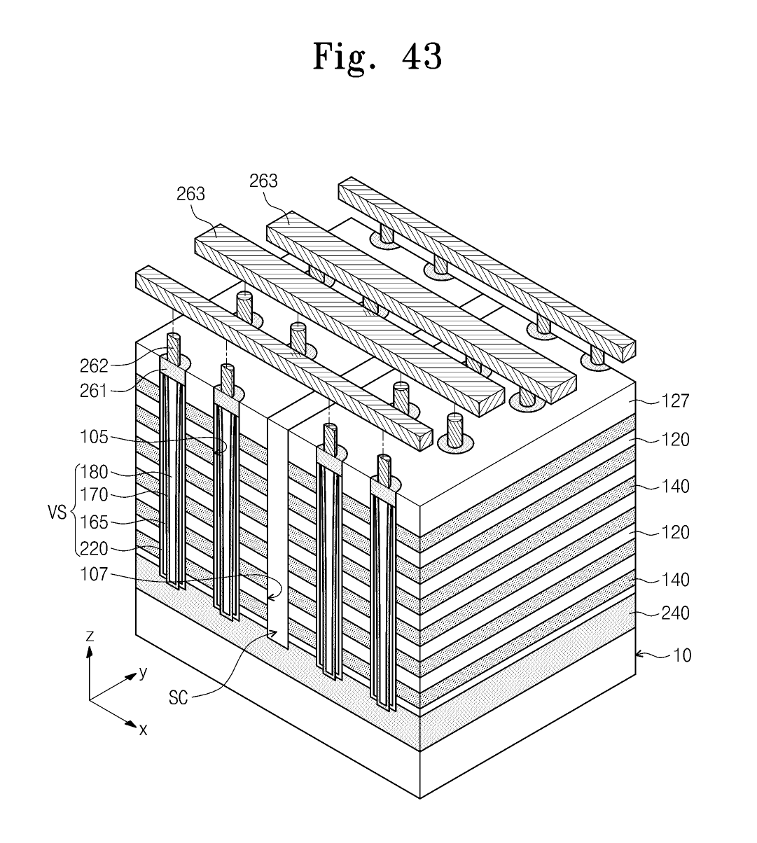

Referring to FIG. 43, the filing layer 180 and semiconductor layer 170 may be planarized to expose the uppermost insulation layer 127 and first structure SC. That is, the planarization process may split data storage layer 220 into a plurality of fragments in respective ones of channel holes 105 and may split semiconductor layer 170 into a plurality of fragments in respective ones of channel holes 105. Similarly, the planarization process may also split the filing layer 180 into a plurality of fragments in respective ones of channel holes 105. As a result, a plurality of channel structures VS may be formed in respective ones of channel holes 105, and each of the channel structures VS may include data storage layer 220, semiconductor layer 170 and the filing layer 180 remaining in one of channel holes 105. The channel structures VS may be two-dimensionally arrayed in a plan view.

Third impurity regions 261 may be formed in respective ones of upper portions of the channel structures VS. Third impurity regions 261 may be formed to have the same conductivity type as second impurity region 240. First upper interconnections 263 and first upper plugs 262 may be formed on the substrate including third impurity regions 261. The first upper interconnections 263 may be electrically connected to the third impurity regions 261 through the first upper plugs 262.

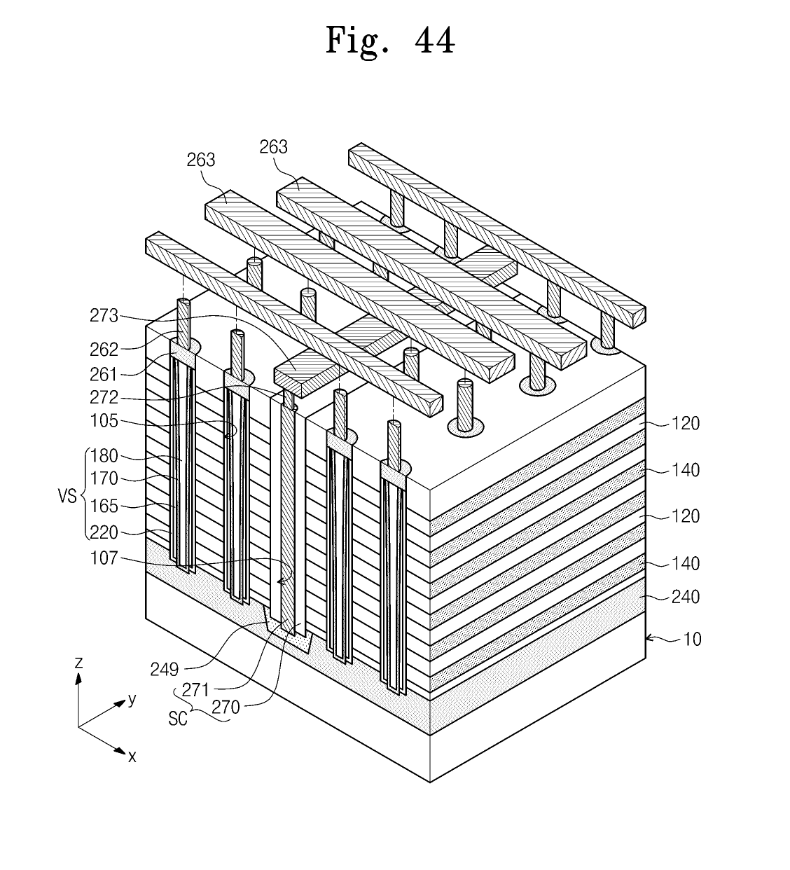

FIG. 44 is a perspective view illustrating a three-dimensional semiconductor device according to an exemplary embodiment in accordance with principles of inventive concepts and a method of fabricating the same. This exemplary embodiment is similar to the previous embodiment illustrated in FIGS. 38 to 43. Thus, differences between the present embodiment and the previous embodiment illustrated in FIGS. 38 to 43 will be mainly described hereinafter.

In the present embodiment, a fifth impurity region 249 may be formed in the second impurity region 240 under first structure SC. Further, contact plugs 271 may be formed to penetrate first insulation pattern 270. Contact plugs 271 may be connected to the fifth impurity region 249. The fifth impurity region 249 may provide an ohmic contact between the second impurity region 240 and contact plugs 271. The fifth impurity region 249 may have the same conductivity type as the second impurity region 240 and may have a different conductivity type from that of substrate 10. An impurity concentration of the fifth impurity region 249 may be greater than that of the second impurity region 240. The process of forming the fifth impurity region 249 may be performed after formation of isolation trench 107 described with reference to FIG. 39.

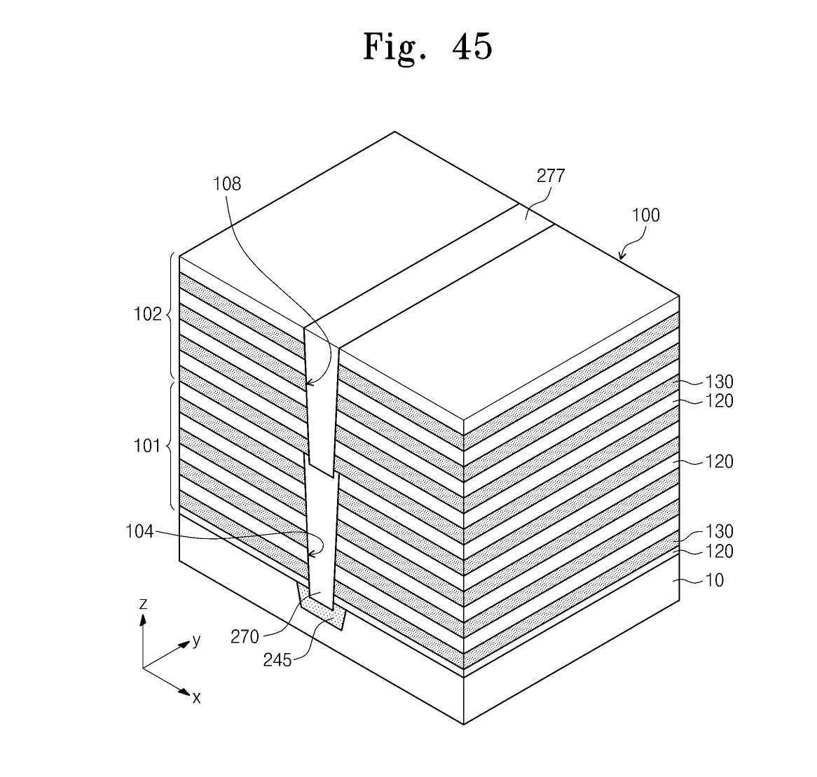

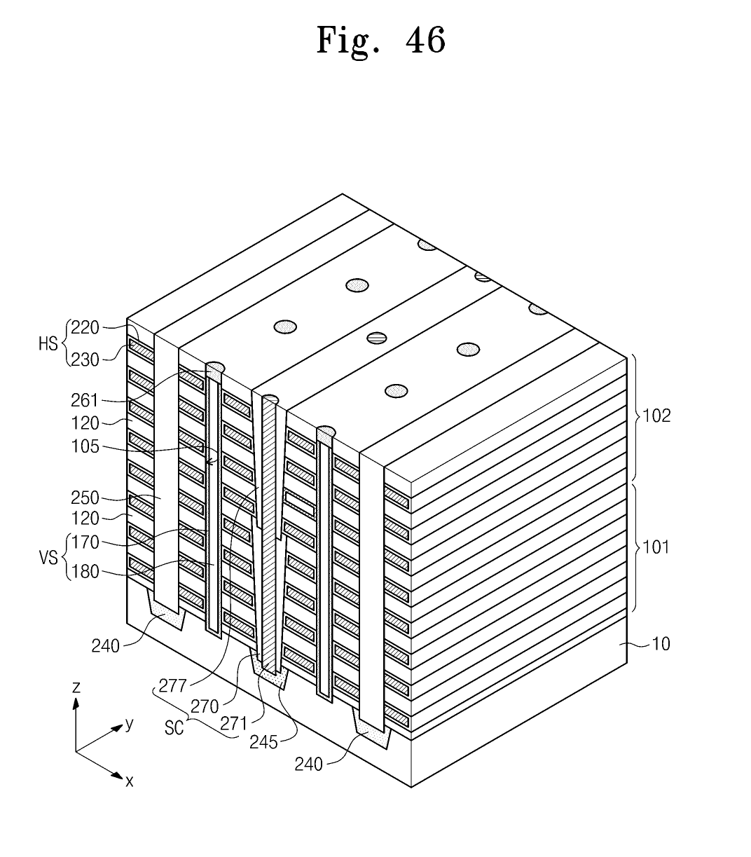

FIGS. 45 and 46 are perspective views illustrating a three-dimensional semiconductor device according to an exemplary embodiment in accordance with principles of inventive concepts and a method of fabricating the same. For the purpose of simplification in explanation, the descriptions to the same components as illustrated in the previous embodiments will be omitted or mentioned briefly.

Referring to FIG. 45, a first stack structure 101 may be formed on a substrate 10. First stack structure 101 may be formed by alternately and repeatedly stacking insulation layers 120 and sacrificial layers 130. First stack structure 101 may be patterned to form a lower isolation trench 104 that penetrates first stack structure 101 to expose substrate 10. A first impurity region 245 may be formed in substrate 10 under the lower isolation trench 104. First impurity region 245 may be formed to have the same conductivity type as that of substrate 10. A first insulation pattern 270 may be formed to fill the lower isolation trench 104.

A second stack structure 102 may be formed on first insulation pattern 270 and first stack structure 101. Second stack structure 102 may also be formed by alternately and repeatedly stacking insulation layers 120 and sacrificial layers 130. Second stack structure 102 may be patterned to form an upper isolation trench 108 that penetrates second stack structure 102 to expose first insulation pattern 270. During formation of the upper isolation trench 108, an upper portion of first insulation pattern 270 may be recessed. A second insulation pattern 277 may be formed to fill the upper isolation trench 108.

Referring to FIG. 46, the processes described with reference to FIGS. 4 to 10 may be applied to the resultant where second insulation pattern 277 is formed. As a result, contact plugs 271, channel structures VS and electrode structures HS may be formed in the first and second stack structures 101 and 102. Each of contact plugs 271 may be formed to penetrate the first and second insulation patterns 270 and 277, and each of the electrode structures HS may be formed between the pair of insulation layers 120 vertically adjacent to each other. In addition, each of the channel structures VS may be foamed to penetrate the first and second stack structures 101 and 102. First insulation pattern 270, second insulation pattern 277 and contact plugs 271 may constitute a first structure SC. Each of the channel structures VS may include a semiconductor layer 170 and a filling layer 180 surrounded by semiconductor layer 170, and each of the electrode structures HS may include a data storage layer 220 and an electrode pattern 230 surrounded by data storage layer 220.

According to an exemplary embodiment, channel holes 105 may be formed by successively etching the first and second stack structures 101 and 102 after formation of second insulation pattern 277, and the channel structures VS may be formed in respective ones of channel holes 105. Alternatively, first semiconductor layers (not shown) may be formed to penetrate first stack structure 101 after formation of first insulation pattern 270, and second semiconductor layers (not shown) connected to the first semiconductor layers may be formed to penetrate second stack structure 102 after formation of second insulation pattern 277.

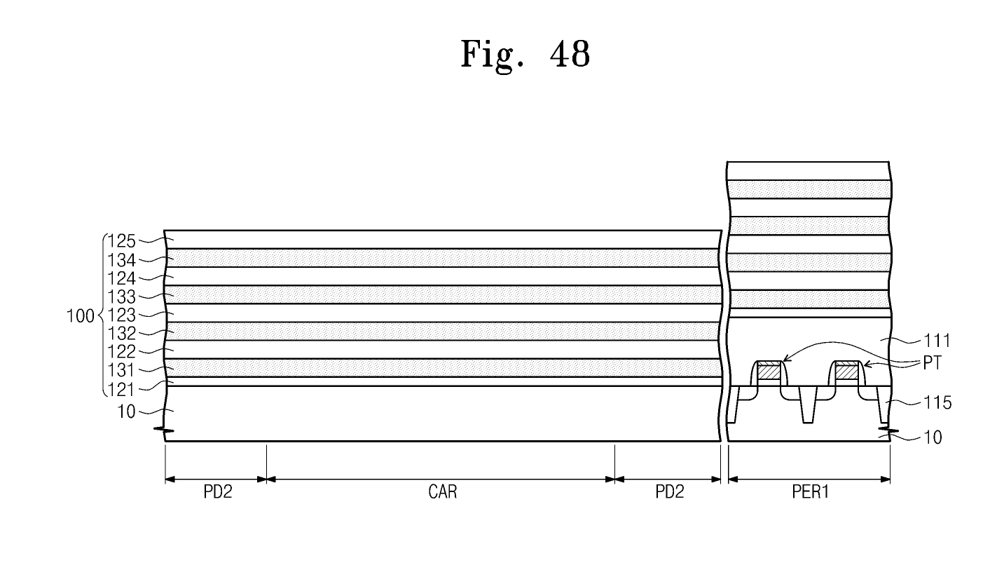

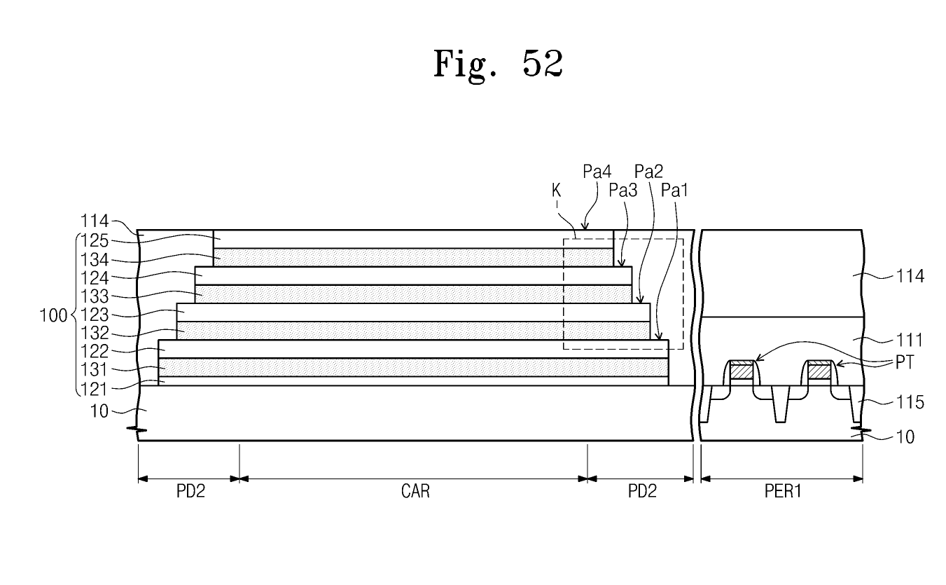

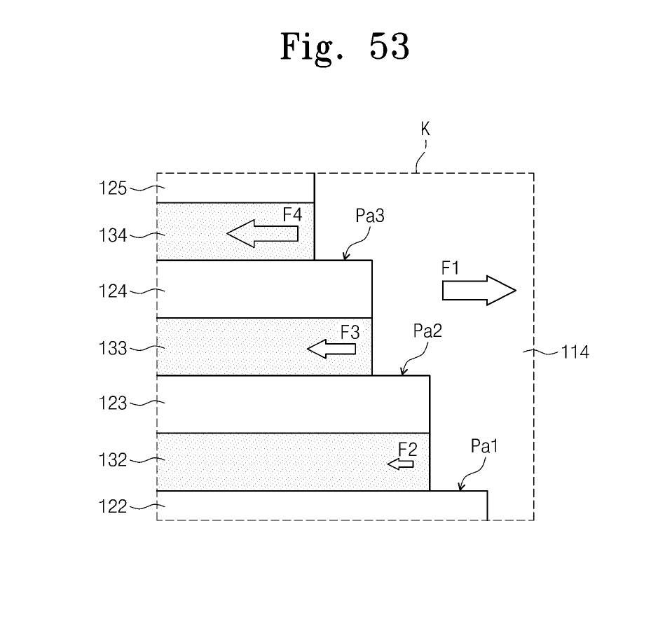

FIGS. 47 to 63 are plan and cross sectional views illustrating a three-dimensional semiconductor device according to an exemplary embodiment in accordance with principles of inventive concepts and a method of fabricating the same. FIGS. 47, 49, 51, 54, 56, 58, 60 and 62 are plan views, and FIGS. 48, 50, 52, 55, 57, 59, 61 and 63 are merged cross sectional views taken along lines A-A′ and B-B′ of FIGS. 47, 49, 51, 54, 56, 58, 60 and 62, respectively. Further, FIG. 53 is an enlarged view illustrating a portion ‘K’ of FIG. 52. For the purpose of simplification in explanation, the descriptions to the same components as illustrated in the previous embodiments will be omitted or mentioned briefly.

Referring to FIGS. 47 and 48, a substrate 10 may be provided. Substrate 10 may include a cell array region CAR, a first peripheral circuit region PER1 and a second peripheral circuit region PER2. Cell array region CAR may correspond to a region in which a plurality of channel structures are formed in subsequent processes. First and second pad regions PD1 and PD2 may be disposed around cell array region CAR in a plan view. First pad region PD1 may be located at top and bottom sides of cell array region CAR on the plan view of FIG. 47, and the second pad region PD2 may be located at left and right sides of cell array region CAR on the plan view of FIG. 47. That is, first pad region PD1 and cell array region CAR may be arrayed in a y-axis direction, and the second pad region PD2 and cell array region CAR may be arrayed in an x-axis direction. First peripheral circuit region PER1 may be disposed to be spaced apart from cell array region CAR in the x-axis direction, and second peripheral circuit region PER2 may be disposed to be spaced apart from cell array region CAR in the y-axis direction. For example, first peripheral circuit region PER1 may be disposed at a right side of cell array region CAR on the plan view of FIG. 47, and second peripheral circuit region PER2 may be disposed at a bottom side of cell array region CAR on the plan view of FIG. 47.

Peripheral transistors PT may be provided on and in substrate 10 in first peripheral circuit region PER1. Peripheral transistors PT may be formed on and in active regions defined by an isolation layer 115. Peripheral transistors PT may constitute a column decoder, a sense amplifier or other control circuits, for example. A protecting insulation layer 111 may be provided to cover peripheral transistors PT. The protecting insulation layer 111 may be formed to include at least one of a silicon oxide layer and a silicon oxynitride layer. Second peripheral circuit region PER2 may include a row decoder and other control circuits.

A stack structure 100 may be formed on substrate 10 including peripheral transistors PT and the protecting insulation layer 111 covering peripheral transistors PT. Stack structure 100 may be formed by alternately and repeatedly stacking insulation layers 121-125 and sacrificial layers 131-134. Stack structure 100 may be formed to cover cell array region CAR, the pad regions PD1 and PD2, and the peripheral circuit regions PER1 and PER2.

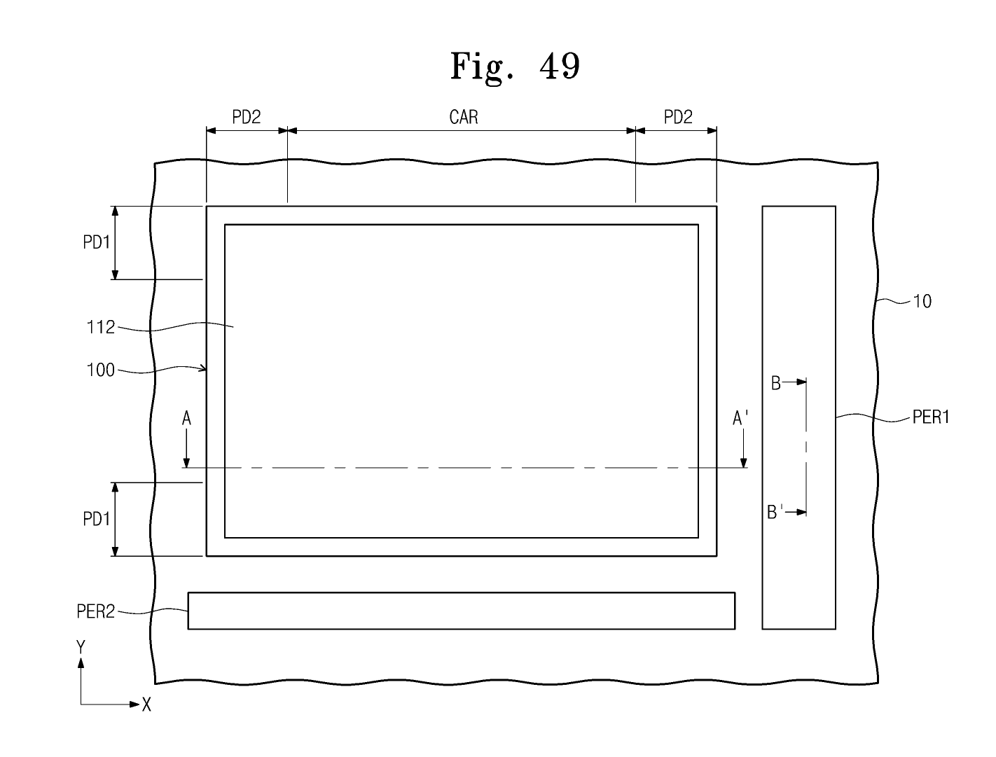

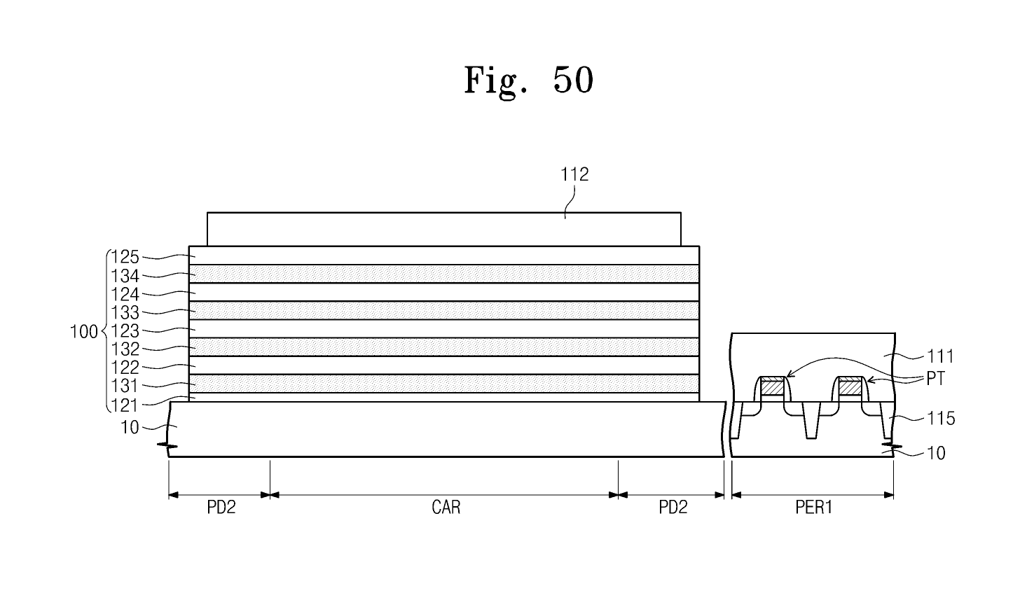

Referring to FIGS. 49 and 50, stack structure 100 may be patterned to remove a portion of stack structure 100, which is located in the peripheral circuit regions PER1 and PER2. After stack structure 100 is patterned, sidewalls of the remaining stack structure 100 may be located on the pad regions PD1 and PD2. While stack structure 100 is patterned, the protecting insulation layer 111 may prevent peripheral transistors PT from being damaged.

A pad mask pattern 112 may be formed on the patterned stack structure 100. A width of pad mask pattern 112 in the x-axis direction may be less than a width of the patterned stack structure 100 in the x-axis direction. Further, a width of pad mask pattern 112 in the y-axis direction may be less than a width of the patterned stack structure 100 in the y-axis direction. Thus, even after pad mask pattern 112 is formed, a top surface of an edge of the patterned stack structure 100 may be still exposed. Pad mask pattern 112 may be formed to include at least one of a silicon nitride layer, a silicon oxynitride layer and a silicon oxide layer, for example.

In an exemplary embodiment in accordance with principles of inventive concepts, pad mask pattern 112 may be formed on stack structure 100 before patterning stack structure 100, and stack structure 100 may be patterned using pad mask pattern 112 as an etch mask to remove a portion of stack structure 100, which is located in the peripheral circuit regions PER1 and PER2. In this case, pad mask pattern 112 may be isotropically etched to form a shrunk mask pattern. A width of the shrunk pad mask pattern 112 in the x-axis direction may be less than a width of the patterned stack structure 100 in the x-axis direction, and a width of the shrunk pad mask pattern 112 in the y-axis direction may also be less than a width of the patterned stack structure 100 in the y-axis direction.

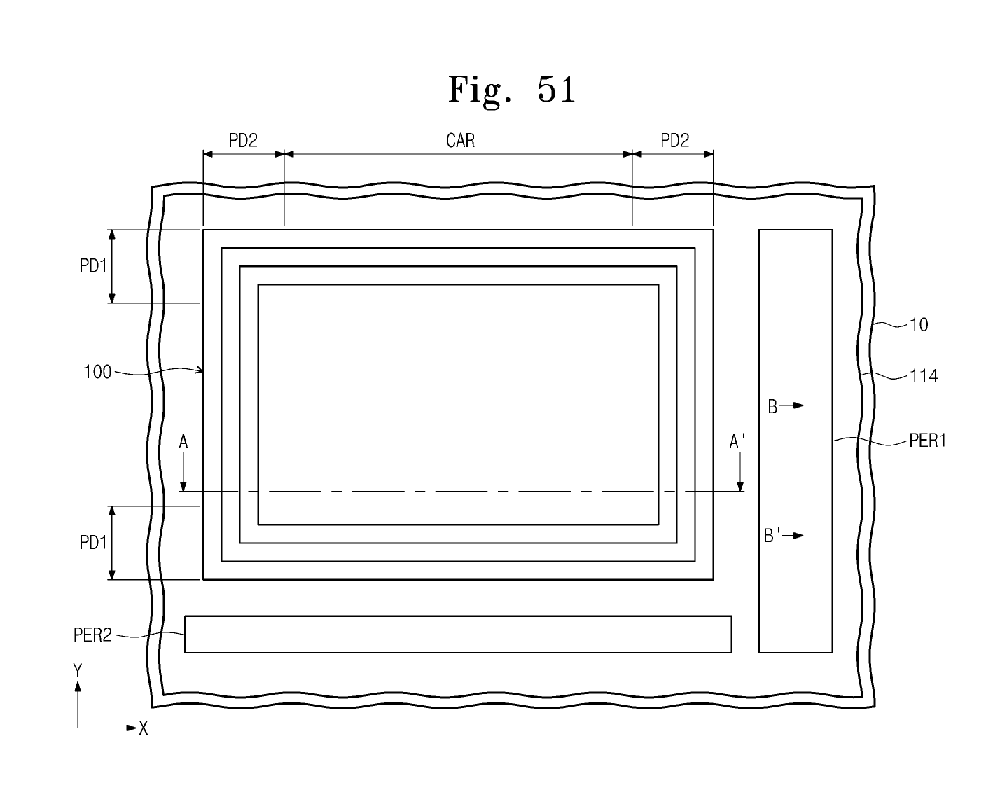

Referring to FIGS. 51 and 52, pads Pa1-Pa4 constituting a step structure may be formed at each of edges of the patterned stack structure 100. The step structural pads Pa1-Pa4 may be formed by alternately and repeatedly shrinking pad mask pattern 112 with an isotropic etching process and etching some of the insulation layers and the sacrificial layers using the shrunk pad mask pattern 112, for example. In an exemplary embodiment in accordance with principles of inventive concepts, the shrunk pad mask pattern 112 illustrated in FIGS. 49 and 50 may define the first pad Pa1. That is, the insulation layers 123-125 and the sacrificial layers 132-134 may be etched using the shrunk pad mask pattern 112 as an etch mask, thereby exposing edges of the insulation layer 122 and forming the first pad Pa1.

After formation of the first pad Pa1, the shrunk pad mask pattern 112 may be isotropically etched again to form a second shrunk pad mask pattern 112. Using the second shrunk pad mask pattern 112 as an etch mask, the insulation layers 124-125 and the sacrificial layers 134-134 may be etched to expose edges of the insulation layer 123 and form the second pad Pa2. Thus, the isotropic etching process for shrink of pad mask pattern 112 and the anisotropic etching process of some of the insulation layers and the sacrificial layers may be alternately and repeatedly performed to form the step structural pads Pa1-Pa4. That is, the step structural pads Pa1-Pa4 may be formed using pad mask pattern 112 as a consumption mask. The pads Pa1-Pa4 may be formed on the pad regions PD1 and PD2. The shrunk pad mask pattern 112 may be removed after formation of the pads Pa1-Pa4.

After formation of the pads Pa1-Pa4 and removal of the shrunk pad mask pattern 112, a first interlayer insulation layer 114 may be formed to cover stack structure 100 having the step structural pads Pa1-Pa4. First interlayer insulation layer 114 may cover the peripheral circuit regions PER1 and PER2 as well as stack structure 100. First interlayer insulation layer 114 may expose the uppermost insulation layer (e.g., the fifth insulation layer 125). In an exemplary embodiment in accordance with principles of inventive concepts, forming first interlayer insulation layer 114 may include forming an insulation layer (not shown) on an entire surface of the substrate having the pads Pa1-Pa4 and planarizing first interlayer insulation layer 114 until a top surface of the fifth insulation layer 125 is exposed. First interlayer insulation layer 114 may be formed of at least one of an undoped silicate glass (USG) material, a tetra-ethyl-ortho-silicate (TEOS) material, a boro-silicate-glass (BSG) material and a boro-phospho-silicate-glass (BPSG) material, for example.

FIG. 53 is an enlarged view illustrating a portion ‘K’ of FIG. 52 to show local stresses applied to stack structure 100. Referring to FIG. 53, first interlayer insulation layer 114 may be densified to shrink in a subsequent high temperature process. If first interlayer insulation layer 114 is shrunk, a first tensile stress F1 generated by the shrink of first interlayer insulation layer 114 may be applied to the edges of stack structure 100, which are adjacent to first interlayer insulation layer 114. Since first peripheral circuit region PER1 is covered with first interlayer insulation layer 114, a relatively high stress may be applied to the second pad region PD2 adjacent first peripheral circuit region PER1. The sacrificial layers 131-134 may also be shrunk in the subsequent high temperature process. The stresses generated by the shrink of the sacrificial layers 131-134 may be different from each other according to horizontal positions of the sacrificial layers 131-134. For example, the stress generated from the edges of stack structure 100 in the pad regions PD1 and PD2 may be relatively greater than that generated from stack structure 100 in cell array region CAR. Further, the stresses generated by the shrink of the sacrificial layers 131-134 may be different from each other according to vertical positions of the sacrificial layers 131-134. For example, as illustrated in FIG. 53, a fourth stress F4 generated by shrink of the fourth sacrificial layer 134 may be greater than a third stress F3 generated by shrink of the third sacrificial layer 133, and a second stress F2 generated by shrink of the second sacrificial layer 132 may be less than the third stress F3 generated by shrink of the third sacrificial layer 133. That is, the stresses generated from the sacrificial layers 131-134 may be gradually increased as they become farther from substrate 10. As described above, the stresses generated in stack structure 100 and in first interlayer insulation layer 114 may be non-uniformly distributed. The non-uniformly distributed stresses may deform semiconductor layers, which penetrate stack structure 100 to act as channel bodies of MOS transistors, to be formed in subsequent processes. The deformation of the semiconductor layers may degrade electrical characteristics of the semiconductor device.

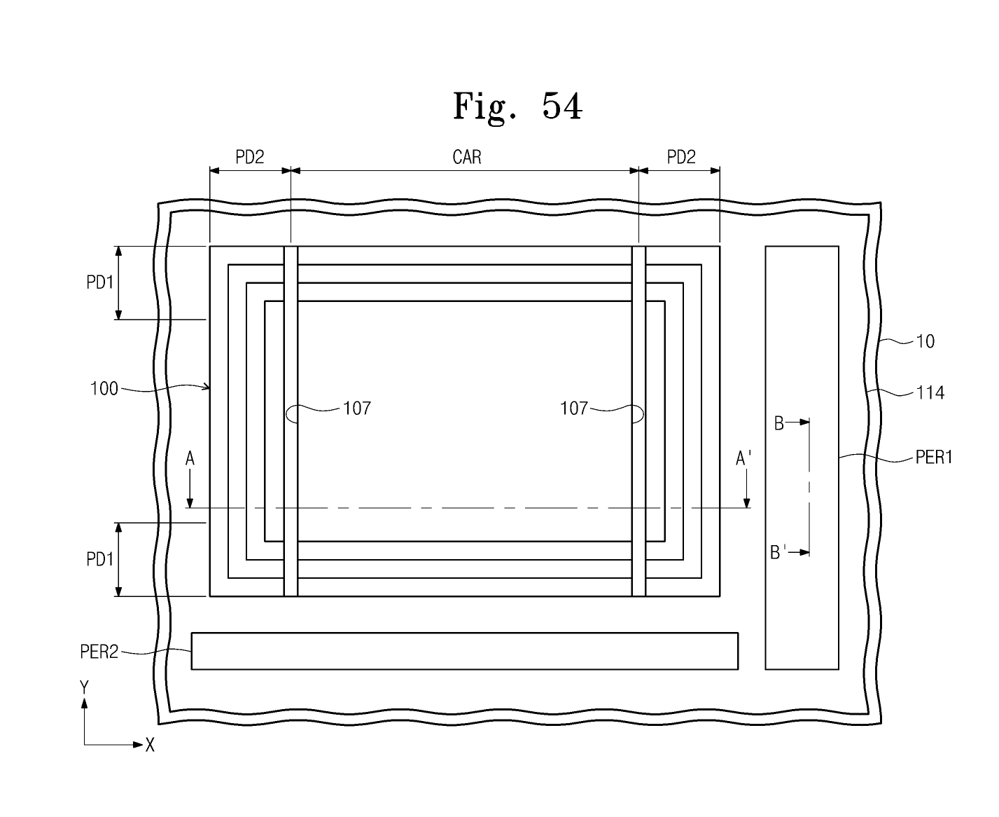

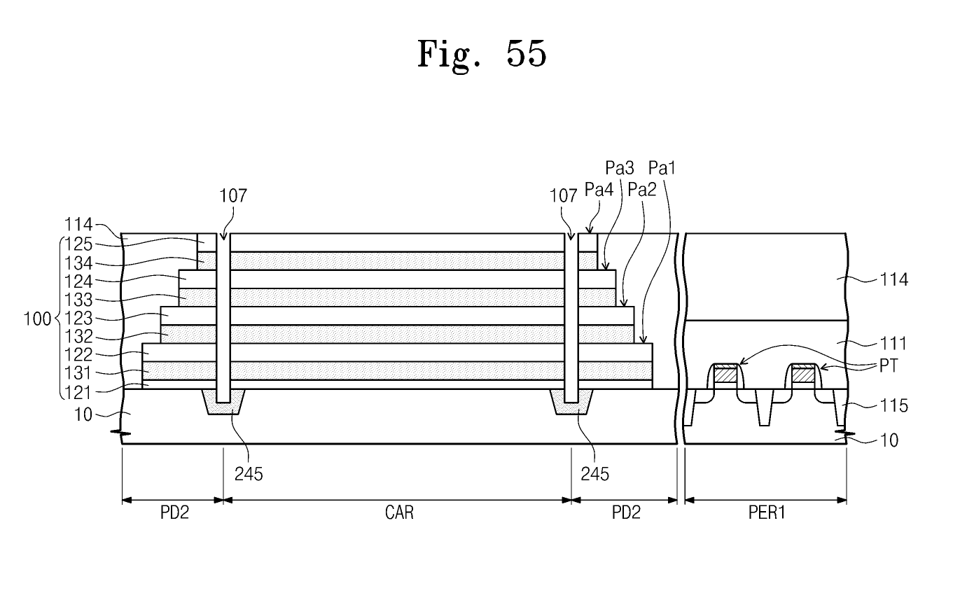

Referring to FIGS. 54 and 55, stack structure 100 may be patterned to form at least one isolation trench 107. The at least one isolation trench 107 may be formed to expose substrate 10. The at least one isolation trench 107 may be formed between cell array region CAR and first peripheral circuit region PER1. In an exemplary embodiment in accordance with principles of inventive concepts, the at least one isolation trench 107 may include a pair of isolation trenches 107. As illustrated in FIGS. 54 and 55, the pair of isolation trenches 107 may be disposed between cell array region CAR and the pair of second pad regions PD2 located at both sides of cell array region CAR, respectively. In other embodiment, the at least one isolation trench 107 may be formed to be adjacent to only one edge of stack structure 100.

In the present embodiment, the at least one isolation trench 107 may prevent stack structure 100 from being deformed due to the non-uniform distribution of the stresses applied to the edges of stack structure 100. That is, the at least one isolation trench 107 may relieve and/or alleviate the non-uniform stresses generated by shrink of first interlayer insulation layer 114 and the sacrificial layers 131-134 during the subsequent high temperature processes.

First impurity regions 245 may be formed in substrate 10 under the isolation trenches 107. In an exemplary embodiment in accordance with principles of inventive concepts, first impurity regions 245 may have the same conductivity type as substrate 10 and may have a higher impurity concentration than substrate 10. In another embodiment, first impurity regions 245 may have a different conductivity type from substrate 10. In still another embodiment, the process of forming first impurity regions 245 may be omitted.

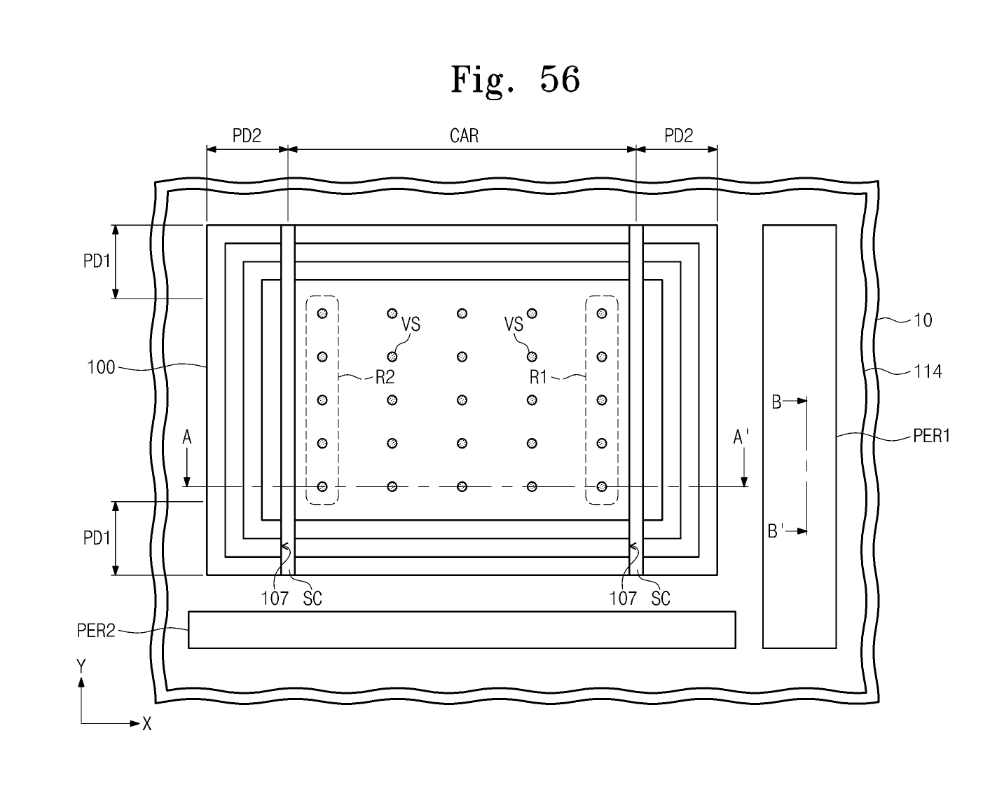

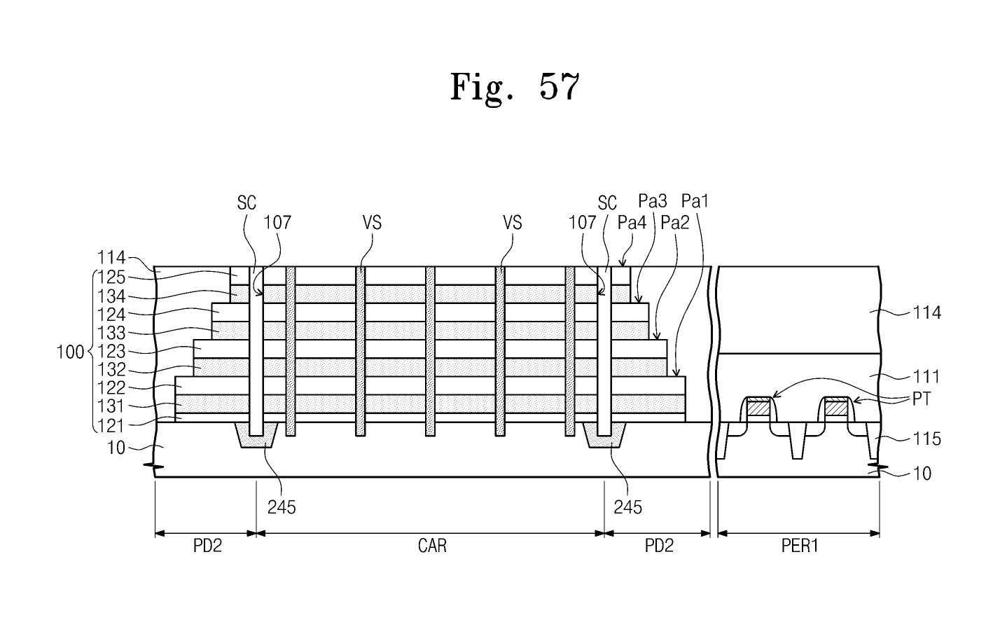

Referring to FIGS. 56 and 57, first structures SC may be foamed in respective ones of the isolation trenches 107. Channel structures VS may be formed to penetrate stack structure 100 in cell array region CAR. The channel structures VS may be connected to substrate 10. Each of the channel structures VS may be formed to include a semiconductor layer. First structures SC and the channel structures VS may be formed using any methods described in the previous embodiments. Thus, detailed descriptions to the methods of forming first structures SC and the channel structures VS will be omitted in the present embodiment. The channel structures VS may be two-dimensionally arrayed along the x-axis direction and the y-axis direction in a plan view. In an exemplary embodiment in accordance with principles of inventive concepts, the channel structures VS may be disposed in a plurality of rows which are parallel with the y-axis direction, and each of the pair of first structures SC may be formed between one of the pair of outermost rows R1 and R2 and one of the second pad regions PD2 adjacent thereto . In the present application, while the channel structures VS (not shown) formed in the pad regions PD1 and PD2 correspond to dummy channel structures, the channel structures VS arrayed in the outermost rows R1 and R2 may correspond to main channel structures VS electrically connected to bit lines to be described hereinafter.

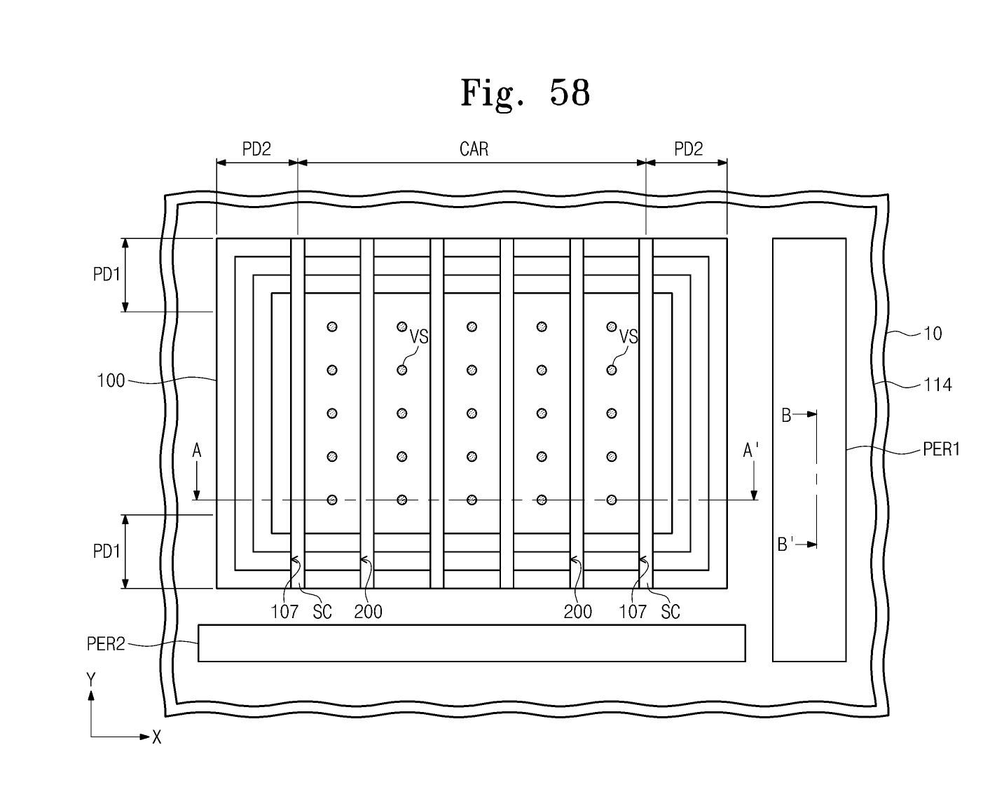

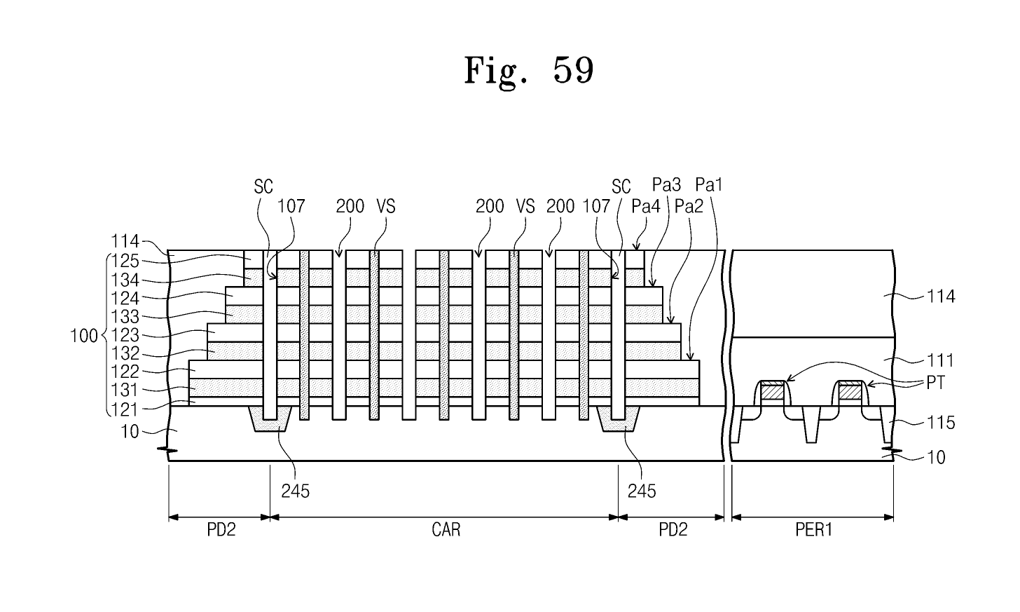

Referring to FIGS. 58 and 59, stack structure 100 may be patterned to form first trenches 200 exposing substrate 10. First trenches 200 may be disposed between the rows in which the channel structures VS are arrayed, and may extend in the y-axis direction. First trenches 200 may be formed by anisotropically etching stack structure 100 until substrate 10 is exposed. First trenches 200 may be substantially parallel with first structures SC. First trenches 200 may extend into the edges of stack structure 100, which are located in first pad regions PD1.

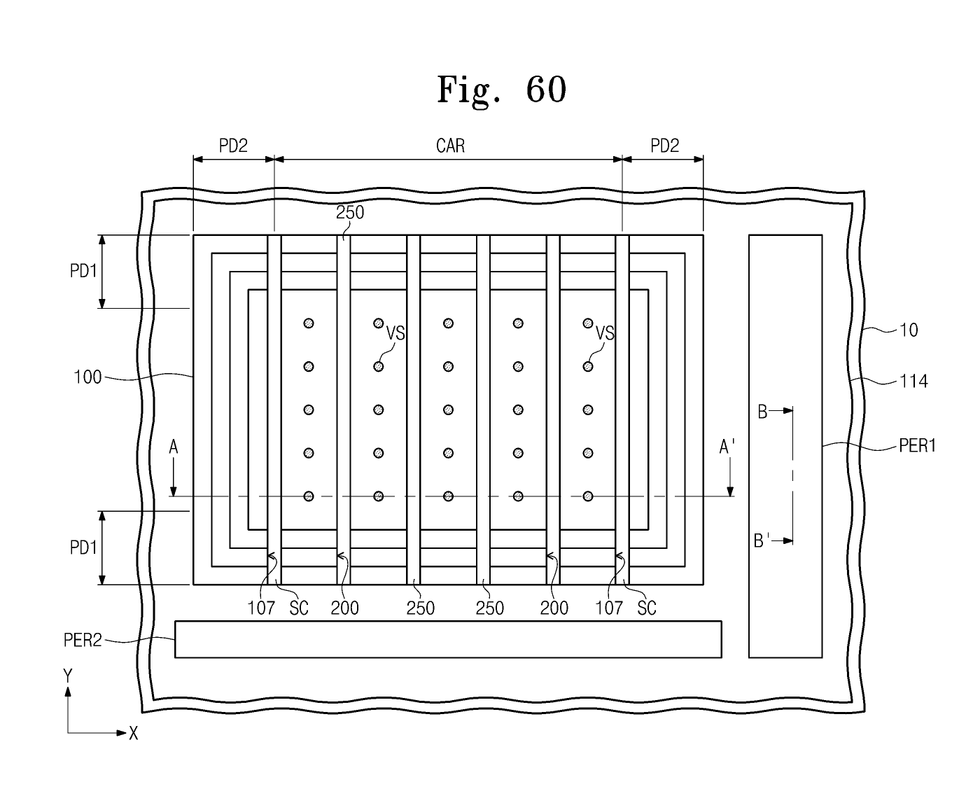

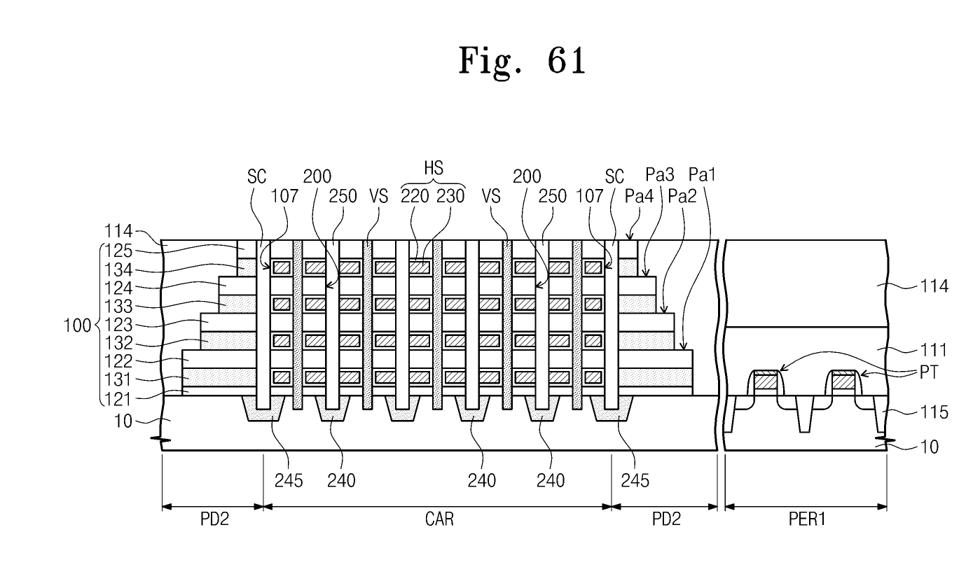

Referring to FIGS. 60 and 61, sacrificial layers 130 exposed by first trenches 200 may be replaced with electrode structures HS. In more detail, sacrificial layers 130 may be selectively removed to form recessed regions between the insulation layers 120 vertically stacked, and the recessed regions may be filled with the electrode structures HS. In an exemplary embodiment in accordance with principles of inventive concepts, while sacrificial layers 130 are removed to from the recessed regions, the etchant supplied into first trenches 200 may not reach sacrificial layers 130 in the second pad regions PD2 because of the presence of first structures SC. Thus, even after the electrode structures HS are formed, sacrificial layers 130 in the second pad regions PD2 may still remain. In another embodiment, if first structures SC are formed to partially cross stack structure 100 in the y-axis direction, at least portions of sacrificial layers 130 in the second pad regions PD2 may be removed during formation of the recessed regions. In still another embodiment, additional processes may be performed to remove sacrificial layers 130 in the second pad regions PD2 before or after formation of the recessed regions.

Each of the electrode structures HS may include a data storage layer 220 conformally covering an inner surface of the recessed region and an electrode pattern 230 filling the recessed region surrounded by data storage layer 220. Detailed configurations of data storage layer 220 will be described hereinafter with reference to FIGS. 73 to 75. After formation of the electrode patterns 230, second impurity regions 240 may be formed in substrate 10 under first trenches 200. The second impurity regions 240 may be formed to have a different conductivity type from substrate 10.

Buried insulation layers 250 may be formed in respective ones of first trenches 200. Buried insulation layers 250 may be formed of at least one of a silicon oxide layer, a silicon nitride layer and a silicon oxynitride layer.

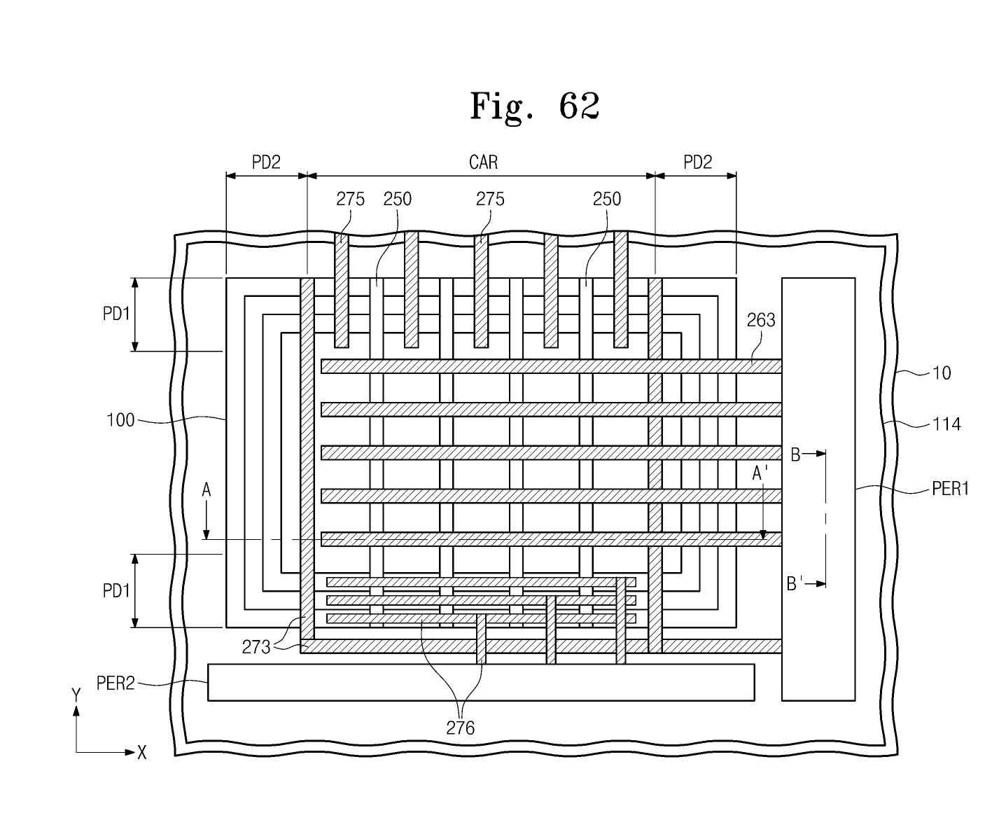

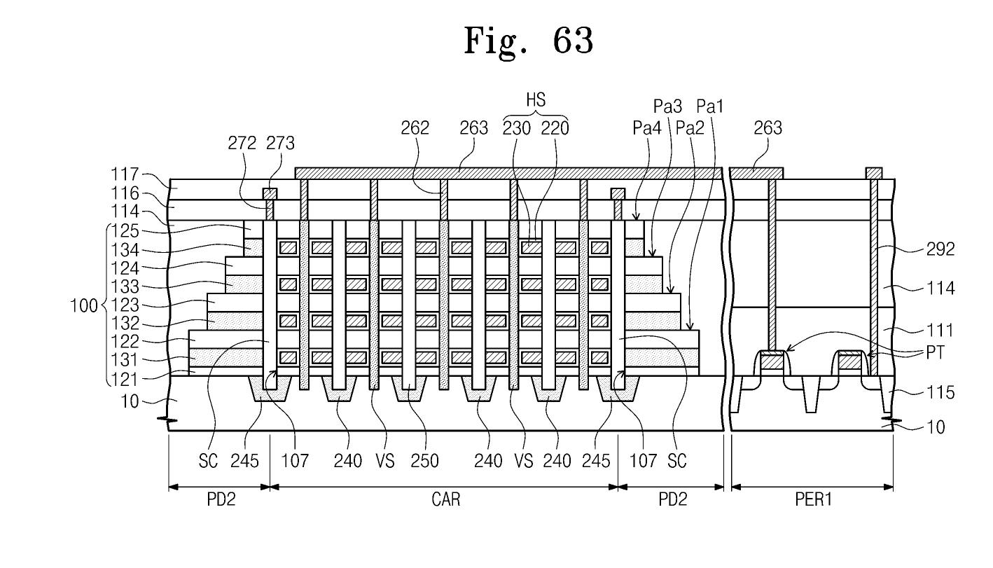

Referring to FIGS. 62 and 63, conductive lines may be formed on the substrate including buried insulation layers 250. For example, first upper interconnection lines 263 may be formed on the substrate including buried insulation layers 250. Each of first upper interconnection lines 263 may electrically connect the channel structures VS arrayed in one of a plurality of columns parallel with the x-axis direction to each other. First upper interconnection lines 263 may be electrically connected to the channel structures VS through first upper plugs 262 that penetrate second and third interlayer insulation layers 116 and 117. The second and third interlayer insulation layers 116 and 117 may be formed of a silicon oxide layer or a silicon oxynitride layer, for example. First upper interconnection lines 263 may extend onto first peripheral circuit region PER1 and may be electrically connected to peripheral transistors PT through peripheral contact plugs 292.

Further, second upper interconnection lines 273 may be formed between the second and third interlayer insulation layers 116 and 117. Second upper interconnection lines 273 may be formed on first structures SC and may be formed to extend in the y-axis direction. That is, second upper interconnection lines 273 may extend to cross first upper interconnection lines 263. In the event that first impurity regions 245 are formed, some additional structures may be provided to electrically connect second upper interconnection lines 273 to first impurity regions 245. The additional structures for electrically connecting second upper interconnection lines 273 to first impurity regions 245 may correspond to contact plugs 271 illustrated in FIGS. 11, 15, 18, 44 and 46, or the conductive patterns 286 or 172 illustrated in FIG. 22, 26, 28, 32 or 37. Contact plugs 271 or the conductive patterns 286 or 172 may be electrically connected to second upper interconnection lines 273 through second upper plugs 272. If the number of first structures SC is two or more, the number of second upper interconnection lines 273 may also be two or more and second upper interconnection lines 273 may extend onto first peripheral circuit region PER1.

Each of the electrode structures HS, which are vertically stacked, may be electrically connected to any one of third upper interconnection lines 276 extending along the x-axis direction in first pad regions PD1. Third upper interconnection lines 276 may be electrically connected to the electrode structures HS through the pads and contact plugs (not shown) formed in first pad regions PD1. Third upper interconnection lines 276 may extend onto second peripheral circuit region PER2. In the event that the uppermost electrode structure HS correspond to string selection lines SSL, the string selection lines SSL separated from each other along the x-axis direction by buried insulation layers 250 may be electrically connected to respective ones of fourth upper interconnection lines 275.

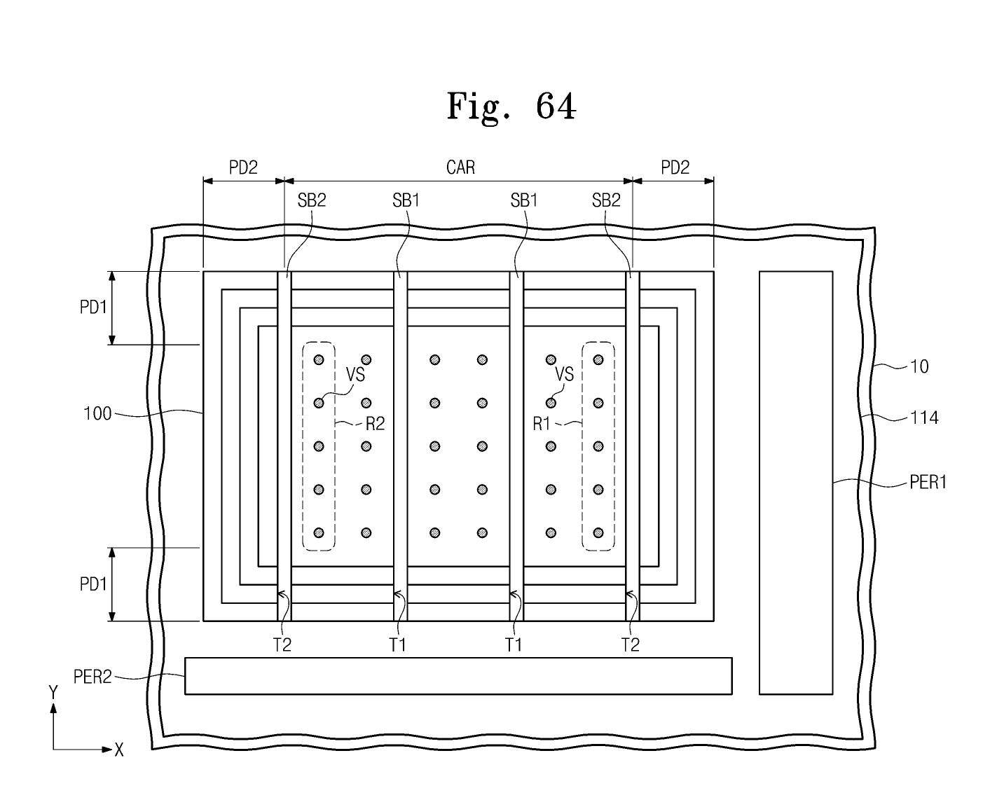

Referring to FIGS. 64 to 67 are plan views illustrating three-dimensional semiconductor devices according to some exemplary embodiment in accordance with principles of inventive concepts. FIGS. 64 to 67 illustrate various configurations of first structures and the channel structures described with reference to FIGS. 56 and 57.

FIG. 64 illustrates an example of layout schemes of the channel structures VS and first structures. Referring to FIG. 64, channel structures VS may be arrayed in a plurality of rows, first structures may include first sub-structures SB1 that are disposed between the rows to extend in the y-axis direction. The number of the first sub-structures SB1 may be two or more. The first sub-structures SB1 may be formed in respective ones of first isolation trenches T1 disposed between the rows.

First structures may further include second sub-structures SB2 provided between the outermost rows R1 and R2 and the second pad regions PD2. In an exemplary embodiment in accordance with principles of inventive concepts, the second sub-structures SB2 may be substantially parallel with the first sub-structures SB1. Second sub-structures SB2 may be disposed between cell array region CAR and second pad regions PD2. Second sub-structures SB2 may be formed in respective ones of second isolation trenches T2 that at least partially cross stack structure 100. First and second isolation trenches T1 and T2 may be simultaneously formed, and first and second sub-structures SB1 and SB2 may also be simultaneously formed.

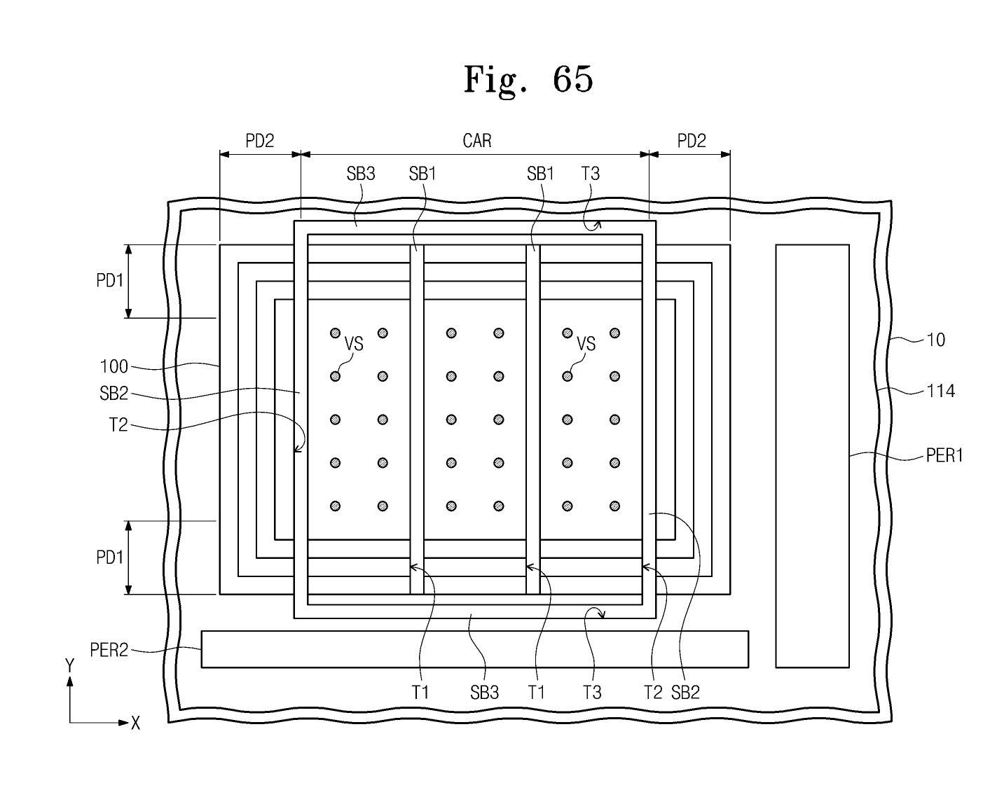

FIG. 65 illustrates another example of layout schemes of the channel structures VS and first structures. Referring to FIG. 65, a first structure according to the present embodiment may further include at least one third sub-structure SB3 in addition to the first and second sub-structures SB1 and SB2 illustrated in FIG. 64. The third sub-structure SB3 may penetrate first interlayer insulation layer 114 and may extend in the x-axis direction. The third sub-structure SB3 may be spaced apart from stack structure 100 along the y-axis direction. For example, the third sub-structure SB3 may be disposed between stack structure 100 and second peripheral circuit region PER2. The third sub-structure SB3 may be provided in a third isolation trench T3 which is foamed at one side or at both sides of stack structure 100. Third sub-structure SB3 may alleviate or relive a stress applied to stack structure 100 in the y-axis direction.

In an exemplary embodiment in accordance with principles of inventive concepts, the at least one third sub-structure SB3 may include a pair of third sub-structures SB3. In this case, one of the third sub-structure SB3 may be connected to first ends of the second sub-structures SB2, and the other of the third sub-structure SB3 may be connected to second ends of the second sub-structures SB2. Thus, the second and third sub-structures SB2 and SB3 may constitute a closed loop to surround stack structure 100. The second and third sub-structures SB2 and SB3 may be simultaneously formed. According to the present embodiment, the third sub-structures SB3 may be spaced apart from the first sub-structures SB1.

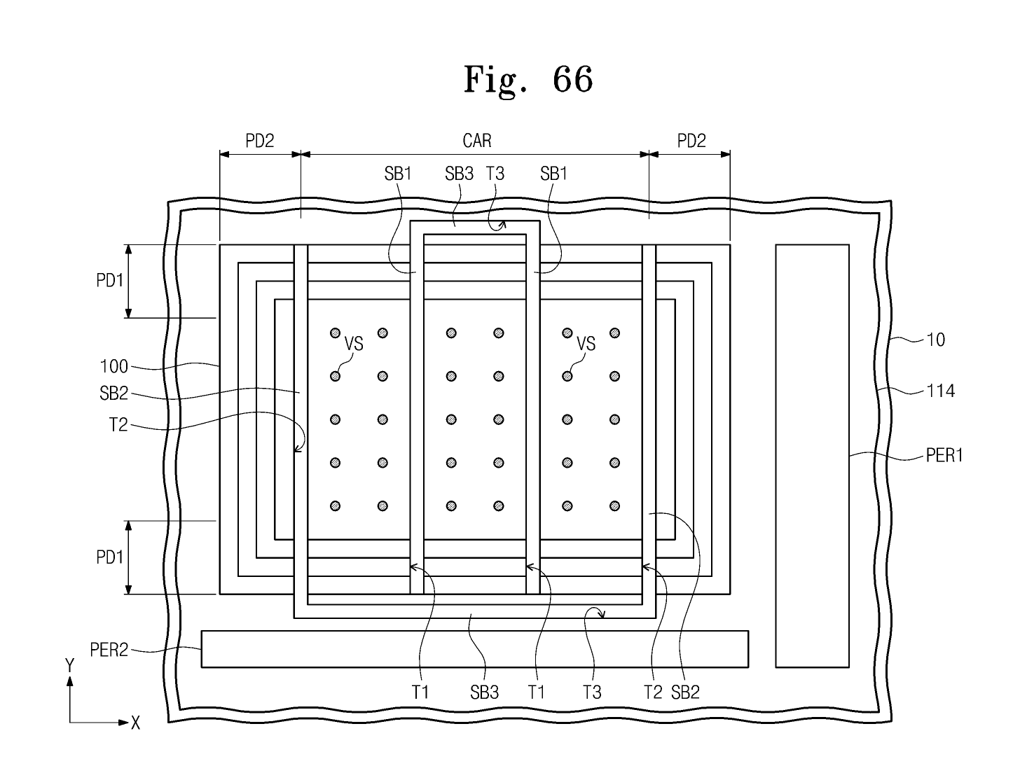

FIG. 66 illustrates still another example of layout schemes of the channel structures VS and first structures. According to the present embodiment, a pair of third sub-structures SB3 may also be provided. The pair of third sub-structures SB3 may be disposed at both sides of stack structure 100, respectively. One of the third sub-structures SB3 may be connected to the first sub-structures SB1, and the other of the third sub-structures SB3 may be connected to the second sub-structures SB2. For example, one of the third sub-structures SB3 may be disposed between stack structure 100 and second peripheral circuit region PER2, thereby connecting the second sub-structures SB2 to each other. The other of the third sub-structures SB3 may be disposed to be adjacent to stack structure 100 opposite second peripheral circuit region PER2, thereby connecting the first sub-structures SB1 to each other. The third sub-structures SB3 may also be formed in third isolation trenches T3.

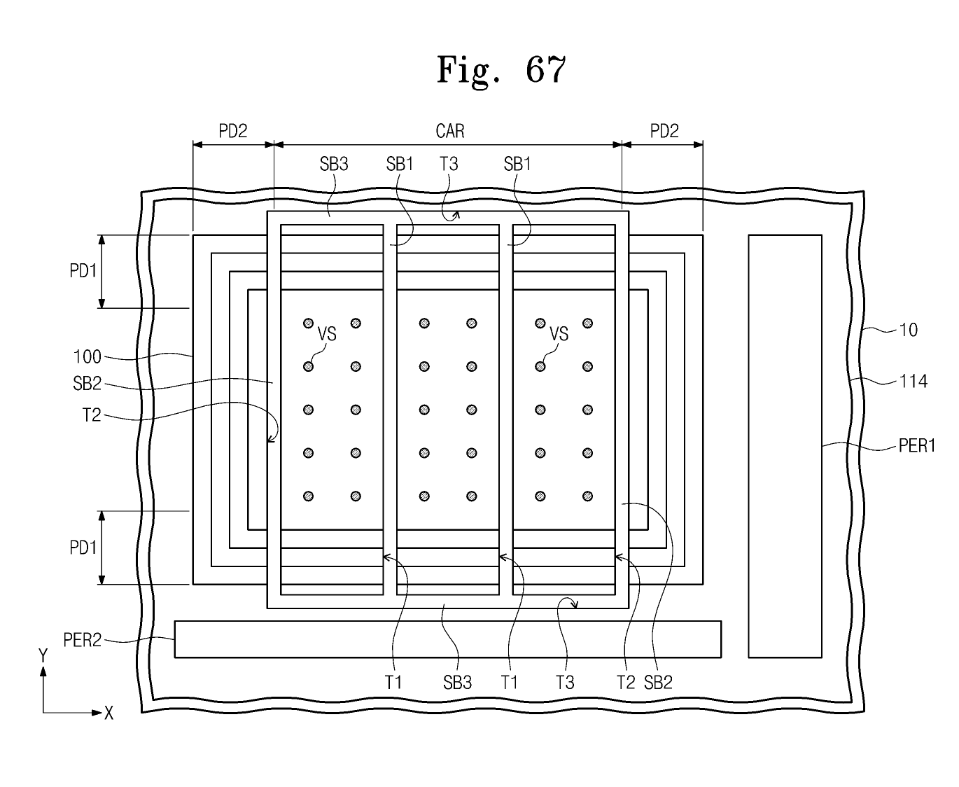

Referring to FIG. 67, a pair of third sub-structures SB3 may also be provided. One of the third sub-structures SB3 may be disposed between stack structure 100 and second peripheral circuit region PER2, thereby connecting the first and second sub-structures SB1 and SB2 to each other. The other of the third sub-structures SB3 may be disposed to be adjacent to stack structure 100 opposite second peripheral circuit region PER2, thereby connecting the first and second sub-structures SB1 and SB2 to each other. The first to third sub-structures SB1, SB2 and SB3 may be simultaneously formed.

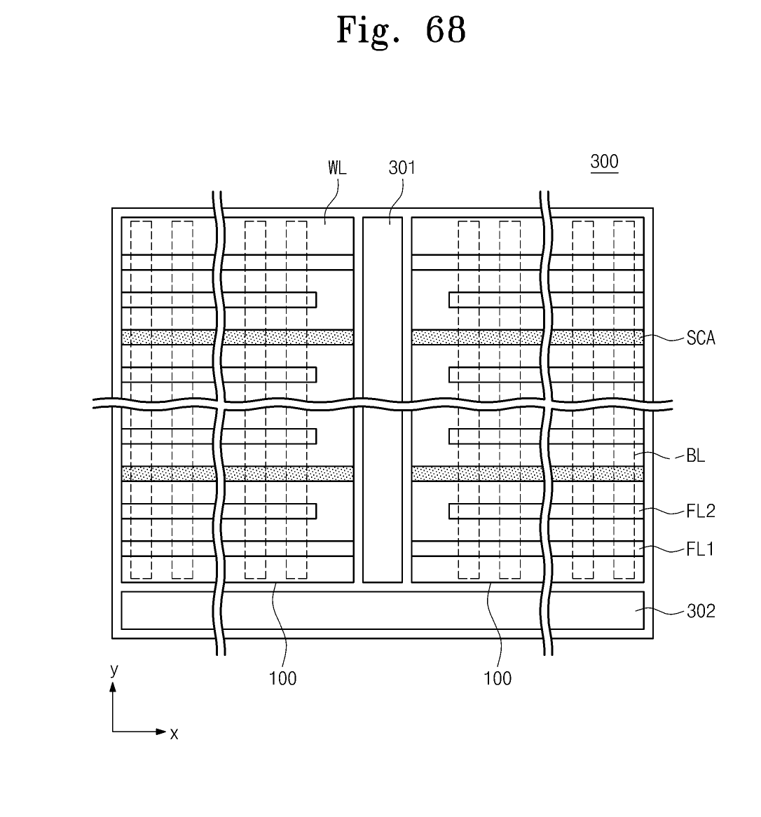

FIGS. 68 to 72 are layout diagrams illustrating various memory chip arrays 300 of three-dimensional semiconductor devices according to some exemplary embodiment in accordance with principles of inventive concepts. In FIGS. 68 to 72, the memory chip array 300 is illustrated to include only two stack structures 100 for simplification of explanation. However, the memory chip array 300 is not limited to the configurations illustrated in FIGS. 68 to 72. For example, the memory chip array 300 may include three or more stack structures 100. Further, in the drawings of FIGS. 68 to 72, the sizes and relative sizes of layers and regions may be exaggerated for clarity.

Referring to FIGS. 68 to 72, the memory chip array 300 may include a plurality of stack structures 100, for example, a pair of stack structures 100. The memory chip array 300 may further include a first peripheral circuit region 302 and a second peripheral circuit region 301. In an exemplary embodiment in accordance with principles of inventive concepts, second peripheral circuit region 301 may be disposed between the pair of stack structures 100 to extend in the y-axis direction. First peripheral circuit region 302 may be disposed at one side of the pair of stack structures 100 to extend in the x-axis direction.

Each of the stack structures 100 may include word lines WL, buried insulation layers FL1 and FL2 (hereinafter, referred to as FL) crossing the word lines WL, and bit lines BL crossing the word lines WL. The buried insulation layers FL may intersect at least portions of the word lines WL. The buried insulation layers FL may have the same configuration as disclosed in any one of the exemplary embodiment in accordance with principles of inventive concepts described with reference to FIGS. 2 to 67. Each of the stack structures 100 may include first structures SCA, SCB or SCC (hereinafter, referred to as SC) crossing the bit lines BL. First structures SC may have the same configuration as disclosed in any one of the exemplary embodiment in accordance with principles of inventive concepts described with reference to FIGS. 2 to 67.

In an exemplary embodiment, buried insulation layers FL may include first buried insulation layers FL1 extending in the x-axis direction to completely intersect the word lines WL and/or second buried insulation layers FL2 extending in the x-axis direction to partially intersect the word lines WL. Even though not shown in the drawings, channel structures may be disposed between the buried insulation layers FL.

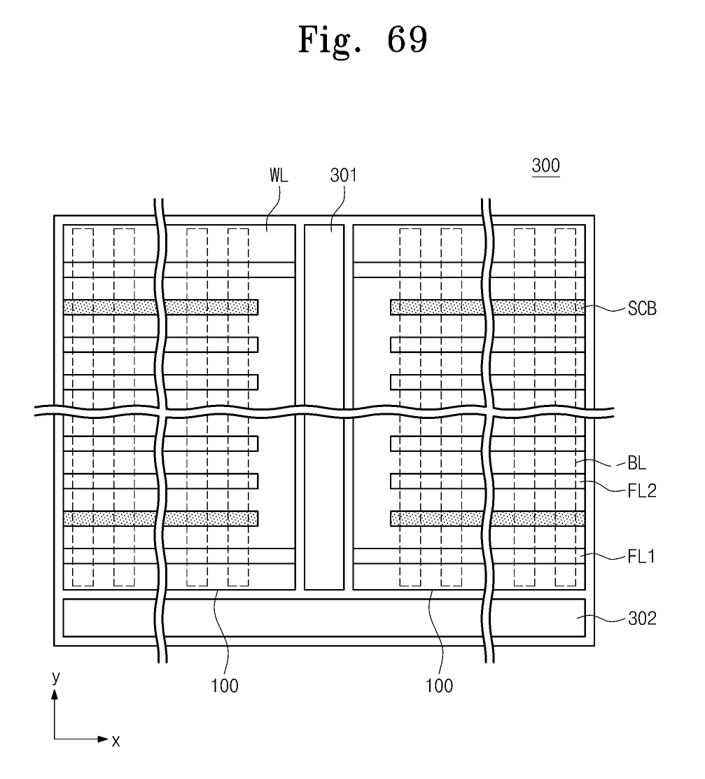

First structures SC may be disposed between buried insulation layers FL. First structures SC may include a first group of structures SCA completely crossing the word lines WL, as illustrated in FIG. 68. Alternatively, first structures SC may include a second group of structures SCB partially crossing the word lines WL, as illustrated in FIG. 69. In an exemplary embodiment in accordance with principles of inventive concepts, a length of the second group of structures SCB in the x-axis direction may be equal to or greater than that of the second buried insulation layers FL2.

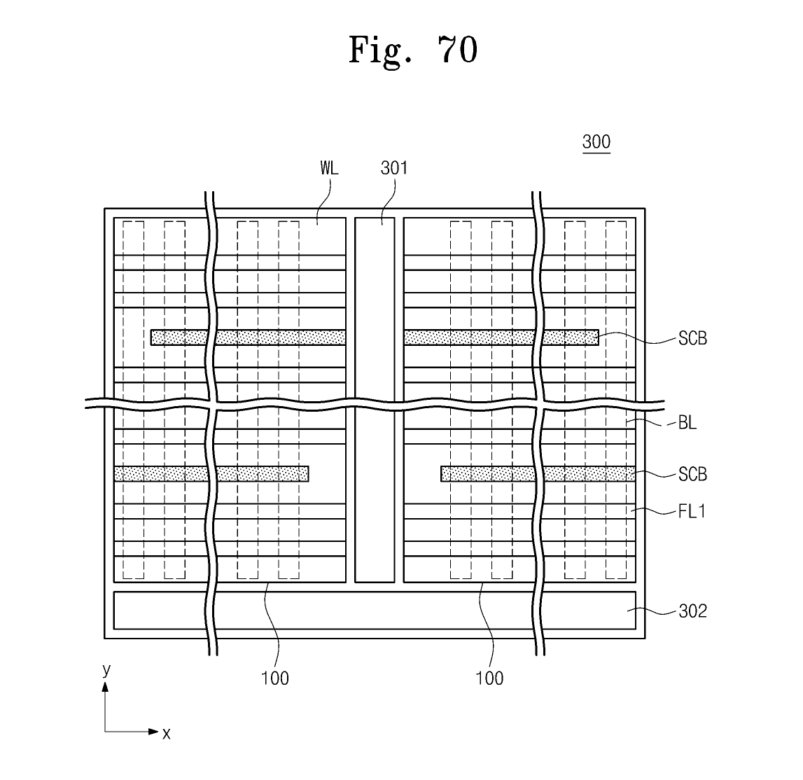

In each of the stack structures 100, first structures SC may be disposed to have the same configuration or different configurations from each other. For example, as illustrated in FIG. 70, one of first structures SC may extend from a first end of stack structure 100 and the other of first structures SC may extend from a second end of stack structure 100 opposite the first end.

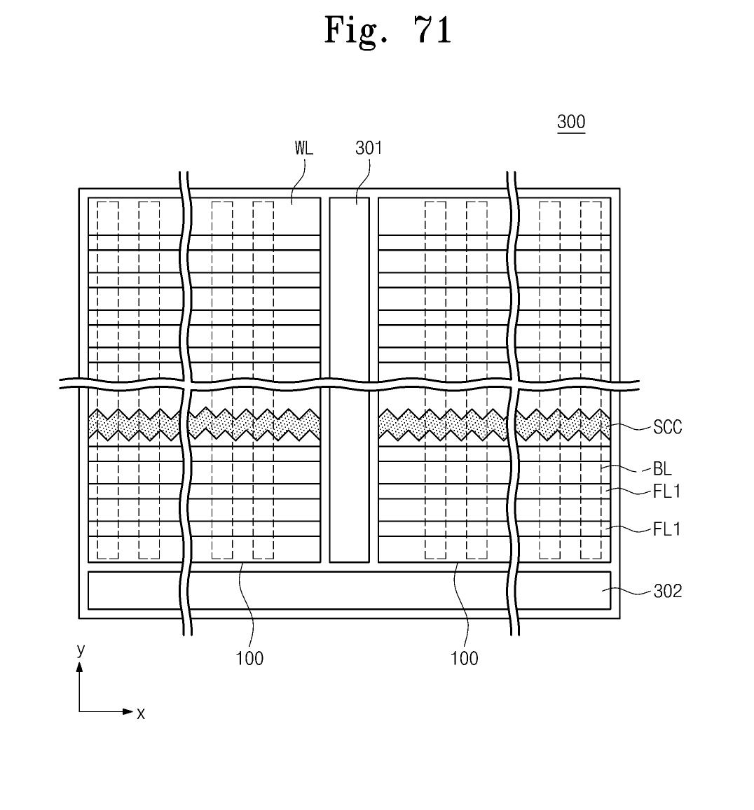

The shape of first structures SC may not be limited to a straight line. That is, first structures SC may have a different shape from the straight line, such as a sawtooth-shaped configuration in a plan view and may extend in the x-axis direction, as illustrated in FIG. 71.

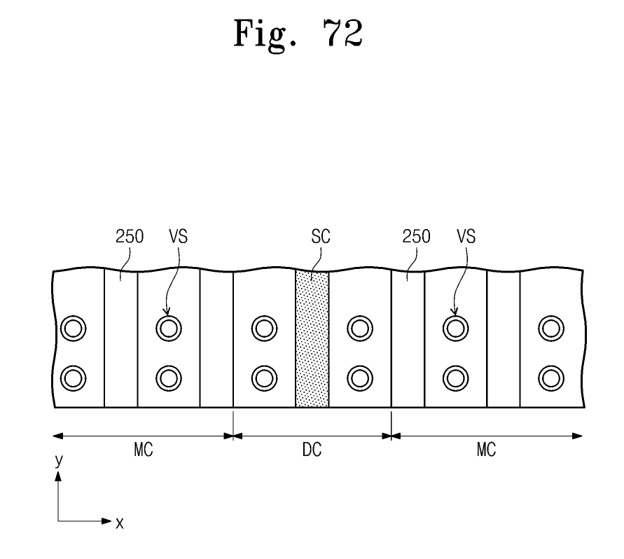

FIG. 72 is a plan view illustrating a portion of memory cell array region of a three-dimensional semiconductor device according to an exemplary embodiment in accordance with principles of inventive concepts. Referring to FIG. 72, buried insulation layers 250 or first structure SC may be disposed between the channel structures VS arrayed in the x-axis direction, and the memory cell array region may include main memory cell array regions MC and a dummy memory cell array region DC between the main memory cell array regions MC. Each of the main memory cell array regions MC may include buried insulation layers 250 and channel structures VS disposed between buried insulation layers 250. The dummy memory cell array region DC may include first structure SC and the channel structures VS arrayed to be adjacent to first structure SC. The channel structures VS in the dummy memory cell array region DC may be used as channel regions of dummy memory cells. Alternatively, the channel structures VS arrayed to be adjacent to first structure SC may be used as channel regions of main memory cells. In this case, the main memory cell array regions MC may include the channel structures VS arrayed to be adjacent to first structure SC. That is, the dummy memory cell array region DC may include only first structure SC.

FIGS. 73 to 75 are perspective views illustrating data storage layers of three-dimensional semiconductor devices according to some exemplary embodiments in accordance with principles of inventive concepts.

FIG. 73 is a partial perspective view illustrating a data storage layer 220 of a three-dimensional semiconductor device according to an exemplary embodiment in accordance with principles of inventive concepts. In more detail, data storage layer 220 illustrated in FIG. 73 may correspond to the data storage layer disclosed in any one of the embodiments described with reference to FIGS. 2 to 11, 29 to 32, 33 to 37, 45 and 46, and 47 to 63.

Referring to FIG. 73, a filling pattern DP and a semiconductor pattern SP surrounding the filling pattern DP may be provided in a channel hole 105 penetrating insulation layers 120 vertically stacked, and some portions of an outer sidewall of the semiconductor pattern SP may be exposed by recessed regions 210 between the insulation layers 120. Data storage layer 220 may be conformally formed on an inner surface of each of recessed regions 210, and the recessed region 210 surrounded by data storage layer 220 may be filled with an electrode pattern 230. Data storage layer 220 may include a tunnel insulation layer TIL, a charge storage layer CL and a blocking insulation layer BLL which are sequentially stacked on the inner surface of the recessed region 210. The layers TIL, CL and BLL constituting data storage layer 220 may be formed using a deposition process which is capable of providing an excellent step coverage. For example, the layers TIL, CL and BLL may be formed using a chemical vapor deposition (CVD) process or an atomic layer deposition (ALD) process.

The charge storage layer CL may be one of insulation layers including a substantial number of trap sites or a substantial number of nano-particles and may be formed using a chemical vapor deposition (CVD) process or an atomic layer deposition (ALD) process. For example, the charge storage layer CL may be formed of an insulation layer including the trap sites, a floating gate or conductive nano-dots. In an exemplary embodiment in accordance with principles of inventive concepts, the charge storage layer CL may be formed to include at least one of a silicon nitride layer, a silicon oxynitride layer, a silicon rich nitride layer, a nano-crystalline silicon layer and a laminated trap layer.

Tunnel insulation layer TIL may be formed to include one of material layers having a relatively wider band gap than the charge storage layer CL and may be formed using a chemical vapor deposition (CVD) process or an atomic layer deposition (ALD) process. For example, tunnel insulation layer TIL may be formed of a silicon oxide layer using a chemical vapor deposition (CVD) process or an atomic layer deposition (ALD) process. Further, tunnel insulation layer TIL may be subject to a predetermined annealing process prior to deposition of the charge storage layer CL. The annealing process may correspond to a normal annealing process employing at least one of a nitrogen gas and an oxygen gas as an ambient gas or a rapid thermal nitridation (RTN) process.

Blocking insulation layer BLL may be a single layered insulation layer. Alternatively, blocking insulation layer BLL may include a multi-layered insulation layer, for example, a first blocking insulation layer and a second blocking insulation layer. First blocking insulation layer may be formed of a different material layer from second blocking insulation layer. One of the first and second blocking insulation layers may be formed of a material having an energy band gap which is less than an energy band gap of the tunnel insulation layer TIL and is greater than an energy band gap of the charge storage layer CL. The first and second blocking insulation layers may be formed using a chemical vapor deposition (CVD) process or an atomic layer deposition (ALD) process. In an exemplary embodiment in accordance with principles of inventive concepts, first blocking insulation layer may be formed of a high-k dielectric layer such as an aluminum oxide layer or a hafnium oxide layer, and second blocking insulation layer may be formed of a material layer having a dielectric constant which is less than that of first blocking insulation layer. Alternatively, second blocking insulation layer may be formed of a high-k dielectric layer, and first blocking insulation layer may be formed of a material layer having a dielectric constant which is less than that of second blocking insulation layer.

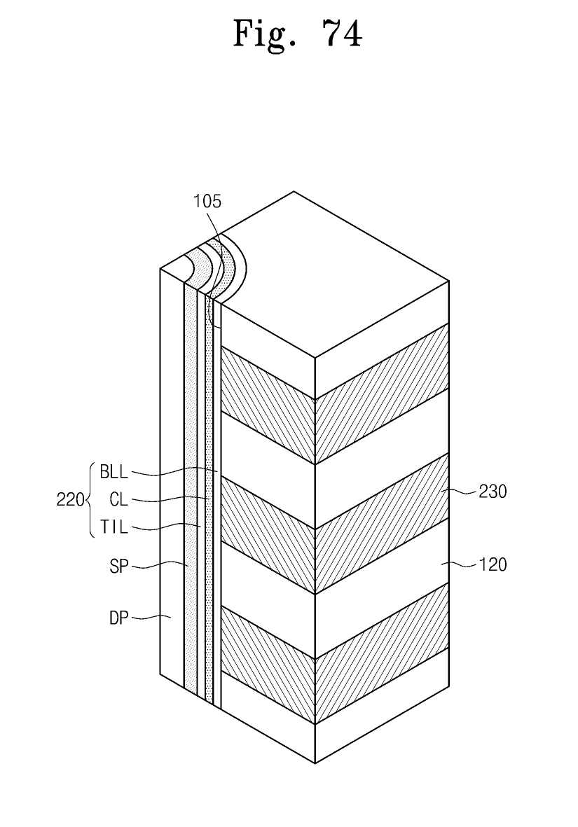

FIG. 74 is a partial perspective view illustrating a data storage layer of a three-dimensional semiconductor device according to an exemplary embodiment in accordance with principles of inventive concepts. In more detail, data storage layer 220 illustrated in FIG. 74 may correspond to the data storage layer disclosed in the embodiment described with reference to FIGS. 38 to 43.

Referring to FIG. 74, a data storage layer 220, a semiconductor pattern SP and a filling pattern DP may be sequentially formed on an inner surface of a channel hole 105 that penetrates a stack structure including insulation layers 120. Data storage layer 220 may be formed prior to formation of the semiconductor pattern SP. Data storage layer 220 may be formed by sequentially stacking a blocking insulation layer BLL, a charge storage layer CL and a tunnel insulation layer TIL on an inner sidewall of the channel hole 105. The semiconductor pattern SP and the filling pattern DP may be formed on data storage layer 220.

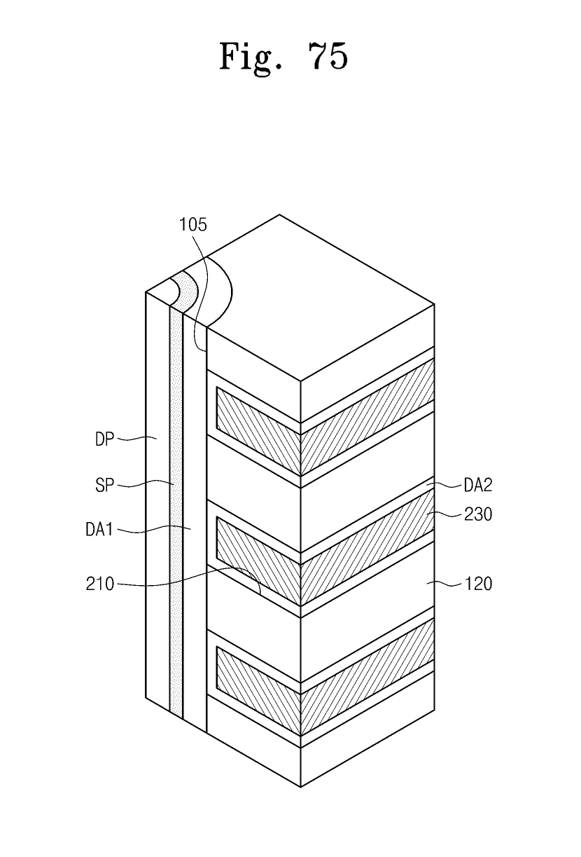

FIG. 75 is a partial perspective view illustrating a data storage layer of a three-dimensional semiconductor device according to an exemplary embodiment in accordance with principles of inventive concepts. In more detail, the data storage layer illustrated in FIG. 75 may correspond to the data storage layer disclosed in the embodiment described with reference to FIGS. 21 to 26.

Referring to FIG. 75, the data storage layer according to the present exemplary embodiment may include a first data storage layer DA1 and a second data storage layer DA2. First data storage layer DA1 may be formed in a channel hole 105 penetrating insulation layers 120 vertically stacked, and second data storage layer DA2 may be formed in each of recessed regions defined by an empty space between the insulation layers 120. At least one of the first and second data storage layers DA1 and DA2 may include a tunnel insulation layer TIL, a charge storage layer CL and a blocking insulation layer BLL.

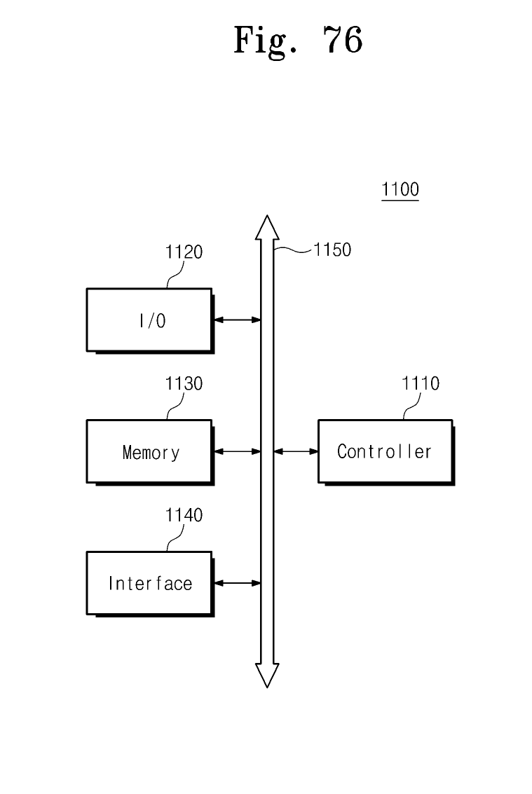

FIG. 76 is a schematic block diagram illustrating an example of electronic systems including semiconductor devices according to some exemplary embodiments in accordance with principles of inventive concepts.

Referring to FIG. 76, an electronic system 1100 may be applied to a personal digital assistant (PDA), a portable computer, a web tablet, a wireless phone, a mobile phone, a digital music player or a memory card. The electronic system 1100 may also be applied to another electronic product that receives or transmits information data by wireless.

The electronic system 1100 may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. That is, the data bus 1150 may correspond to a path through which electrical signals are transmitted.

The controller 1110 may include at least one of a microprocessor, a digital signal processor (DSP), a microcontroller or the like. The memory device 1130 may store commands executed by the controller 1110. The I/O unit 1120 may receive data or signals from an external device or may transmit data or signals to the external device. The I/O unit 1120 may include a keypad, a keyboard or a display unit.

The memory device 1130 may include at least one of the semiconductor devices according to the exemplary embodiments in accordance with principles of inventive concepts described above. The memory device 1130 may further include another type of semiconductor memory devices which are different from the semiconductor devices described in the above embodiments. For example, the memory device 1130 may further include a magnetic memory device, a phase change memory device, a dynamic random access memory (DRAM) device and/or a static random access memory (SRAM) device. The interface unit 1140 may transmit electrical data to a communication network or may receive electrical data from the communication network.

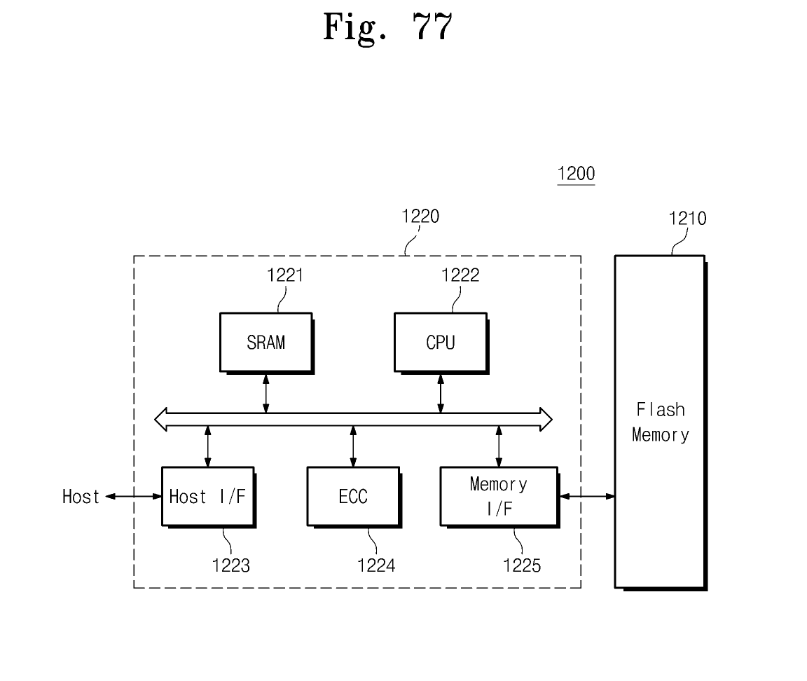

FIG. 77 is a schematic block diagram illustrating an example of memory cards including the semiconductor devices according to exemplary embodiments in accordance with principles of inventive concepts.

Referring to FIG. 77, a memory card 1200 may include a flash memory device 1210 having at least one of the semiconductor memory devices according to exemplary embodiments in accordance with principles of inventive concepts described above. The memory card 1200 may be used as a data storage media for storing a large capacity of data. The memory card 1200 may further include a memory controller 1220 that controls data communication between a host and the flash memory device 1210.

The memory controller 1220 may include a static random access memory (SRAM) device 1221, a central processing unit (CPU) 1222, a host interface unit 1223, an error check and correction (ECC) block 1224 and a memory interface unit 1225. The SRAM device 1221 may be used as an operation memory of the CPU 1222. The host interface unit 1223 may be configured to include a data communication protocol between the memory card 1200 and the host. The ECC block 1224 may detect and correct errors of data which are read out from the flash memory device 1210. The memory interface unit 1225 may connect the memory controller 1220 to the memory device 1210. The central processing unit (CPU) 1222 may control overall operations for data communication of the memory controller 1220. Even though not shown in the drawings, the memory card 1200 may further include a read only memory (ROM) device that stores code data to interface with the host.

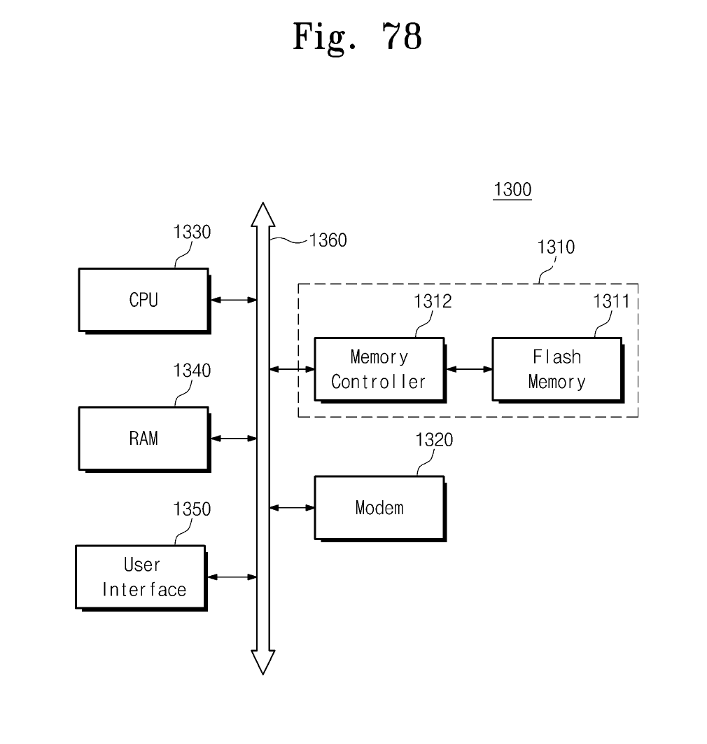

FIG. 78 is a block diagram illustrating an example of information processing systems including the semiconductor devices according to exemplary embodiments in accordance with principles of inventive concepts.

Referring to FIG. 78, an information processing system 1300 may be a mobile system, a desk top computer or the like. The information processing system 1300 may include a flash memory unit 1310 having at least one of the flash memory devices according to exemplary embodiments in accordance with principles of inventive concepts described above. The information processing system 400 may further include a modulator-demodulator (MODEM) 1320, a central processing unit (CPU) 1330, a random access memory (RAM) device 1340 and a user interface unit 1350. At least two of the flash memory unit 1310, the MODEM 1320, the CPU 1330, the RAM device 1340 and a user interface unit 1350 may communicate with each other through a data bus 1360. The flash memory unit 1310 may have substantially the same configuration as the electronic system 1100 illustrated in FIG. 76 or the memory card 1200 illustrated in FIG. 77. That is, the flash memory unit 1310 may include a flash memory device 1311 and a memory controller 1312 that controls overall operations of the flash memory device 1311.

The flash memory unit 1310 may store data processed by the CPU 1330 or data transmitted from an external system. The flash memory unit 1310 may be configured to include a solid state disk. In this case, the flash memory unit 1310 constituting the information processing system 1300 may stably and reliably store a large capacity of data. If the reliability of the flash memory unit 1310 is improved, the information processing system 1300 may save sources that are required to check and correct data. As a result, the information processing system 1300 may provide fast data communication. Even though not shown in the drawings, the information processing system 1300 may further include a camera image processor, an application chipset and/or an input/output unit.

The semiconductor devices according to exemplary embodiments in accordance with principles of inventive concepts described above may be encapsulated using various packaging techniques. For example, the semiconductor devices according to the aforementioned exemplary embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a system in package (SIP) technique, a multi chip package (MCP) technique, a wafer-level fabricated package (WFP) technique and a wafer-level processed stack package (WSP) technique.

According to the embodiments set forth above, a stack structure may be formed by alternately and repeatedly stacking at least two different material layers, and the stack structure may be covered with an interlayer insulation layer having a different stress from the stack structure. Thus, physical stresses may be generated in the stack structure and interlayer insulation layer, and the physical stresses may be applied to channel structures which are formed to penetrate the stack structure. As a result, the channel structures may be deformed by the physical stresses, thereby degrading electrical characteristics and reliability of a semiconductor device including the channel structures. However, according to the embodiments, the stack structure may be patterned to form at least one isolation trench in the stack structure and to form an insulation pattern in the isolation trench, prior to formation of the channel structures. Thus, the physical stresses in the stack structure may be significantly relieved or alleviated because of the presence of the insulation pattern that partially or completely splits the stack structure into a plurality of sub-stack structures. Accordingly, the insulation pattern can prevent the channel structures from being deformed.

Furthermore, at least one first impurity region may be formed in the substrate under the isolation trench, and the first impurity region may act as a substrate pick-up region.

While the inventive concept has been described with reference to exemplary embodiments in accordance with principles of inventive concepts, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A method of fabricating a three-dimensional semiconductor device, the method comprising:
forming a stack structure including first layers and second layers alternately stacked on a substrate;
patterning the stack structure to form at least one isolation trench;
forming channel structures penetrating the stack structure and being spaced apart from the isolation trench; and
forming upper interconnection lines on the stack structure to connect the channel structures to each other,
wherein the isolation trench is formed prior to formation of the channel structures.

2. The method of claim 1, wherein each of the channel structures includes a semiconductor layer, and wherein the isolation trench is formed prior to formation of the semiconductor layer.

3. The method of claim 1, wherein the isolation trench is formed to penetrate the stack structure and to expose the substrate.

4. The method of claim 1, wherein the isolation trench is formed to split the stack structure into a plurality of sub-stack structures that are spaced apart from each other in a horizontal direction parallel with a top surface of the substrate.

5. The method of claim 1, wherein the isolation trench is formed to expose the substrate, and wherein the method further comprises forming a first impurity region in the substrate under the isolation trench.

6. The method of claim 1, further comprising forming a first structure in the isolation trench,
wherein the first structure extends along the isolation trench.

7. The method of claim 6, wherein forming the first structure includes forming a first insulation pattern in the isolation trench, and
wherein the first isolation pattern is formed of a material having an etch selectivity with respect to the second layers.

8. The method of claim 6, wherein forming the first structure includes forming a first conductive pattern in the isolation trench.

9. The method of claim 1, wherein forming the channel structures includes:
forming channel holes penetrating the stack structure; and
forming a semiconductor layer in the channel holes,
wherein the isolation trench and the channel holes are simultaneously formed using the same etching process.

10-20. (canceled)
